(19) United States
(12) Patent Application Publication
(10) Pub. No.: US 2026/0026151 A1
(43) Pub. Date: Jan. 22, 2026

(54) DISPLAY DEVICE AND ELECTRONIC DEVICE INCLUDING THE SAME

(71) Applicant: Samsung Display Co., Ltd., Yongin-Si (KR)

(72) Inventors: SUNHO KIM, Yongin-si (KR); YOOMIN KO, Yongin-si (KR); KYUNGHO KIM, Yongin-si (KR); JUCHAN PARK, Yongin-si (KR); CHUNG SOCK CHOI, Yongin-si (KR)

(21) Appl. No.: 19/246,682

(22) Filed: Jun. 24, 2025

(30) Foreign Application Priority Data
Jul. 16, 2024 (KR) 10-2024-0093846

(51) Int. Cl. H10H 29/32; H10H 29/37; H10H 29/49; H10K 59/121; H10K 59/122; H10K 59/131

(52) U.S. Cl. CPC H10H 29/32; H10H 29/37; H10H 29/49; H10K 59/1213; H10K 59/122; H10K 59/131

(57) ABSTRACT

A display device includes: a pixel driving circuit part including a transistor, a connection electrode located on the pixel driving circuit part and electrically connected to the transistor of the pixel driving circuit part, a first electrode layer located on the connection electrode, the first electrode layer receiving a power supply voltage and including a plurality of first electrodes, a transmission line group located in a different layer from the first electrode layer, electrically connected to the first electrode layer, and forming a mesh structure with the first electrode layer in plan view, a separator located on the first electrode layer, and a second electrode layer located on the first electrode layer and separated into a plurality of second electrodes by the separator.

### CROSS-REFERENCE TO RELATED APPLICATION

This application claims priority to and benefit, under 35 U.S.C. § 119, of Korean Patent Application No. 10-2024-0093846 filed on Jul. 16, 2024 in the Korean Intellectual Property Office (KIPO), the entire content of which is hereby incorporated by reference.

### BACKGROUND

### 1. Technical Field

Embodiments provide generally to a display device. More particularly, embodiments relate to a display device that provides visual information.

### 2. Description of Related Art

As information technology develops, display devices that connect users to information are playing an increasingly important role in the daily lives of people. Display devices include a light-emitting element and a pixel driving circuit part for driving the light-emitting element. The light-emitting element is driven by the pixel driving circuit part and emits light. In order to improve the reliability of the display device, research on the connection between the light-emitting element and the pixel driving circuit part continues.

### SUMMARY

Embodiments provide a display device with improved display quality.

Embodiments provide an electronic device including the display device.

Additional features of the inventive concepts will be set forth in the description which follows, and in part will be apparent from the description, or may be learned by practice of the inventive concepts.

A display device according to the present disclosure includes a pixel driving circuit part including a transistor, a connection electrode located on the pixel driving circuit part and electrically connected to the transistor of the pixel driving circuit part, a first electrode layer located on the connection electrode, the first electrode layer receiving a power supply voltage and including a plurality of first electrodes, a transmission line group located in a different layer from the first electrode layer, electrically connected to the first electrode layer, and forming a mesh structure with the first electrode layer in plan view, a separator located on the first electrode layer, and a second electrode layer located on the first electrode layer and separated into a plurality of second electrodes by the separator.

In an embodiment, the first electrode layer may be connected to receive the power supply voltage through the transmission line group.

In an embodiment, the first electrode layer may have a mesh pattern in which the first electrodes that extend in different directions are integrally connected.

In an embodiment, the transmission line group may include transmission lines extending in one direction and arranged in a crossing direction crossing that is non-parallel to the one direction.

In an embodiment, the transistor may include an active pattern including a semiconductor material, a gate electrode located on the active pattern, and a contact electrode located on the gate electrode and contacting the active pattern. The transmission lines may be located in a same layer as the contact electrode.

In an embodiment, the transmission lines may be located in a same layer as the connection electrode.

In an embodiment, the transmission line group may include first transmission lines extending in one direction and arranged in a crossing direction that is non-parallel to the one direction and second transmission lines extending in the crossing direction and arranged in the one direction.

In an embodiment, the transistor may include an active pattern including a semiconductor material, a gate electrode located on the active pattern, and a contact electrode located on the gate electrode and contacting the active pattern. The first transmission lines may be located in a same layer as the contact electrode. The second transmission lines may be located in a same layer as the connection electrode.

In an embodiment, the first electrode layer may include electrode lines extending in one direction and arranged in a crossing direction that is non-parallel to the one direction, the electrode lines may be physically separated from each other, and each of the electrode lines has a structure in which some of the first electrodes that extend in different directions may be integrally connected.

In an embodiment, the first electrode layer may include electrode patterns arranged in one direction and a crossing direction that is non-parallel to the one direction, the electrode patterns may be physically separated from each other, and each of the electrode patterns may have a structure in which some of the first electrodes are integrally connected.

In an embodiment, the transmission line group may include first transmission lines extending in the one direction and arranged in the crossing direction, and second transmission lines extending in the crossing direction and arranged in the one direction.

In an embodiment, the first transmission lines and the second transmission lines may be connected to at least one of the electrode patterns. The first transmission lines, the second transmission lines, and the electrode patterns may form the mesh structure.

In an embodiment, the electrode patterns may be electrically connected to each other through the first transmission lines and the second transmission lines.

In an embodiment, the transistor may include an active pattern including a semiconductor material, a gate electrode located on the active pattern and a contact electrode located on the gate electrode and contacting the active pattern. The first transmission lines may be located in a same layer as the contact electrode. The second transmission lines may be located in a same layer as the connection electrode.

In an embodiment, the first electrodes may be arranged in one direction and a crossing direction that is non-parallel to the one direction, and the first electrodes may be physically separated from each other.

In an embodiment, the display device may further include an intermediate layer located between the first electrode layer and the second electrode layer, and including a light-emitting material.

In an embodiment, at least one of the second electrodes may be electrically connected to the connection electrode, and may be electrically connected to the transistor of the pixel driving circuit part through the connection electrode.

A display device according to the present disclosure includes a pixel driving circuit part including a transistor, a connection electrode located on the pixel driving circuit part and electrically connected to the transistor of the pixel driving circuit part, a first electrode layer located on the connection electrode, the first electrode layer receiving a power supply voltage and including a plurality of first electrodes, a transmission line group located in a different layer from the first electrode layer, electrically connected to the first electrode layer, and forming a mesh structure with the first electrode layer in plan view, a pixel defining layer located on the first electrode layer and defining a light-emitting area, a connection pattern electrically connected to the connection electrode and surrounding the light-emitting area in a plan view, a separator located on the pixel defining layer and the connection pattern, and covering at least a portion of the connection pattern, and a second electrode layer located on the first electrode layer and separated into a plurality of second electrodes by the separator.

In an embodiment, at least one of the second electrodes may contact the connection pattern at a position adjacent to or overlapping the separator, and may be electrically connected to the transistor of the pixel driving circuit part through the connection electrode and the connection pattern.

An electronic device of the present disclosure includes a display device including: a pixel driving circuit part including a transistor, a connection electrode located on the pixel driving circuit part and electrically connected to the transistor of the pixel driving circuit part, a first electrode layer located on the connection electrode, the first electrode layer receiving a power supply voltage and including a plurality of first electrodes, a transmission line group located in a different layer from the first electrode layer, electrically connected to the first electrode layer, and forming a mesh structure with the first electrode layer in plan view, a separator located on the first electrode layer, and a second electrode layer located on the first electrode layer and separated into a plurality of second electrodes by the separator, and a power module which supplies the power supply voltage to the display device.

In a display device according to embodiments of the present disclosure, a cathode located on an anode may be connected to a pixel driving circuit part. Specifically, the cathode located on the anode may be connected to a drain of a driving transistor of the pixel driving circuit part. Accordingly, a gate-source voltage (Vgs) of the driving transistor may not change even when a light-emitting element deteriorates. Accordingly, the amount of change in driving current due to deterioration of the light-emitting element may be reduced. Accordingly, the after-image defect of the display device depending on an increase in the time of use may be reduced, and the lifespan of the display device may be improved.

In addition, according to embodiments of the present disclosure, the display device may include transmission lines located in a different layer from the anode to which a power supply voltage is applied and which receive the power supply voltage. The transmission lines may be connected to the anode. Accordingly, the transmission lines may provide the power supply voltage to the anode, and the anode and the transmission lines may define a mesh structure in a plan view. For example, if the anode itself has a mesh pattern, the mesh characteristics of the transmission path of the power supply voltage may be further strengthened by the mesh structure defined by the anode and the transmission lines. In addition, even if the anode itself does not have a mesh pattern, the mesh characteristics of the transmission path of the power supply voltage may be implemented by the mesh structure defined by the anode and the transmission lines. Accordingly, the voltage drop of the power supply voltage may be reduced. Accordingly, power consumption of the display device may be improved and luminance uniformity may be improved. Accordingly, the display quality of the display device may be improved.

However, the effects of the present disclosure are not limited to the above-mentioned effects, and can be variously extended within the spirit and scope of the present disclosure.

### BRIEF DESCRIPTION OF THE DRAWINGS

Illustrative, non-limiting embodiments will be more clearly understood from the following detailed description in conjunction with the accompanying drawings.

FIG. 1A is a plan view showing a display device according to an embodiment of the present disclosure.

FIG. 1B is a plan view showing a display device according to an embodiment of the present disclosure.

FIG. 2A is a circuit diagram illustrating an example of a circuit structure of a pixel included in the display device of FIGS. 1A and 1B.

FIG. 2B is a circuit diagram showing an example of a circuit structure of a pixel included in the display device of FIGS. 1A and 1B.

FIG. 2C is a circuit diagram showing still an example of a circuit structure of a pixel included in the display device of FIGS. 1A and 1B.

FIG. 3 is a plan view schematically showing an example of a partial area of the display device of FIGS. 1A and 1B.

FIG. 4 is an enlarged view of one unit light-emitting areas among unit light-emitting areas of FIG. 3.

FIG. 5 is a cross-sectional view taken along line I-I′ of FIG. 4.

FIG. 6 is a plan view schematically showing a first embodiment of the arrangement relationship between a first electrode layer and a transmission line group disposed (or located) in a display area of FIGS. 1A and 1B.

FIG. 7 is an enlarged view showing area AA of FIG. 6.

FIG. 8A is a cross-sectional view showing an example taken along line II-II′ of FIG. 7.

FIG. 8B is a cross-sectional view showing an example taken along line II-II′ of FIG. 7.

FIG. 9 is a plan view schematically showing a second embodiment of the arrangement relationship between a first electrode layer and a transmission line group disposed in a display area of FIGS. 1A and 1B.

FIG. 10 is an enlarged view showing area BB of FIG. 9.

FIG. 11A is a cross-sectional view showing an example taken along line III-III′ of FIG. 10.

FIG. 11B is a cross-sectional view showing an example taken along line III-III′ of FIG. 10.

FIG. 12 is a plan view schematically showing a third embodiment of the arrangement relationship between a first electrode layer and a transmission line group disposed in a display area of FIGS. 1A and 1B.

FIG. 13 is an enlarged view showing area CC of FIG. 12.

FIG. 14A is a cross-sectional view showing an example taken along line IV-IV′ of FIG. 13.

FIG. 14B is a cross-sectional view showing an example taken along line IV-IV′ of FIG. 13.

FIG. 15 is a plan view schematically showing a fourth embodiment of the arrangement relationship between a first electrode layer and a transmission line group disposed in a display area of FIGS. 1A and 1B.

FIG. 16 is an enlarged view showing area DD of FIG. 15.

FIG. 17A is a cross-sectional view showing an example taken along line V-V′ of FIG. 16.

FIG. 17B is a cross-sectional view showing an example taken along line V-V′ of FIG. 16.

FIG. 18 is a plan view schematically showing a fifth embodiment of the arrangement relationship between a first electrode layer and a transmission line group disposed in a display area of FIGS. 1A and 1B.

FIG. 19 is an enlarged view showing area EE of FIG. 18.

FIG. 20A is a cross-sectional view showing an example taken along line VI-VI′ of FIG. 19.

FIG. 20B is a cross-sectional view showing an example taken along line VI-VI′ of FIG. 19.

FIG. 21 is a plan view schematically showing a sixth embodiment of the arrangement relationship between a first electrode layer and a transmission line group disposed in a display area of FIGS. 1A and 1B.

FIG. 22 is an enlarged view showing area FF of FIG. 21.

FIG. 23A is a cross-sectional view showing an example taken along line VII-VII′ of

FIG. 22.

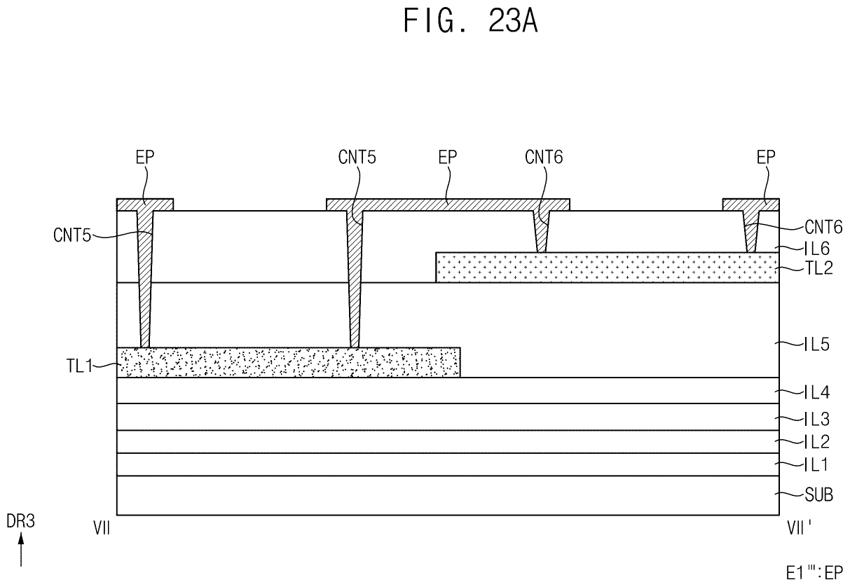

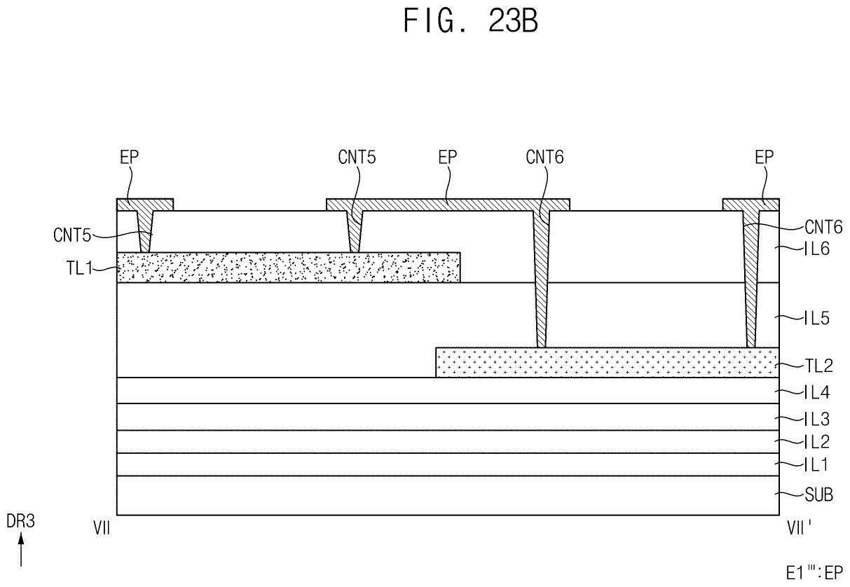

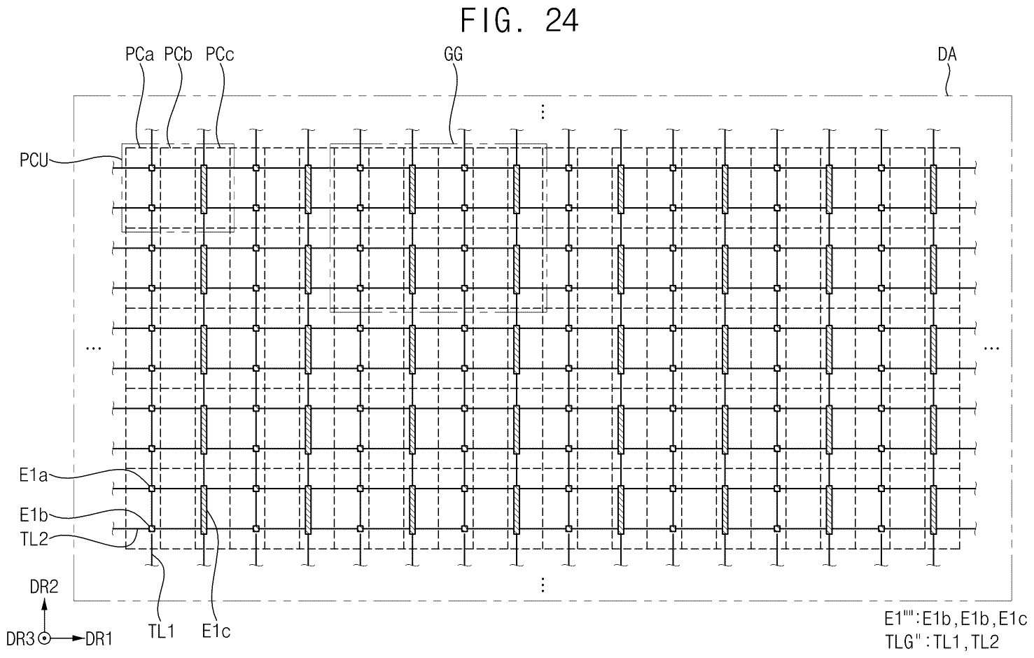

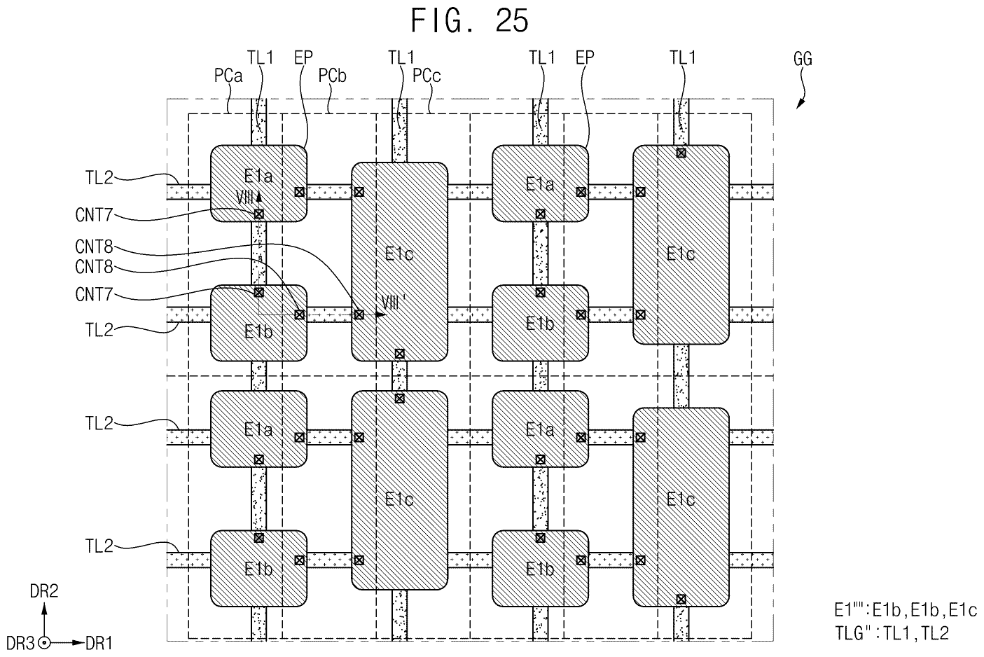

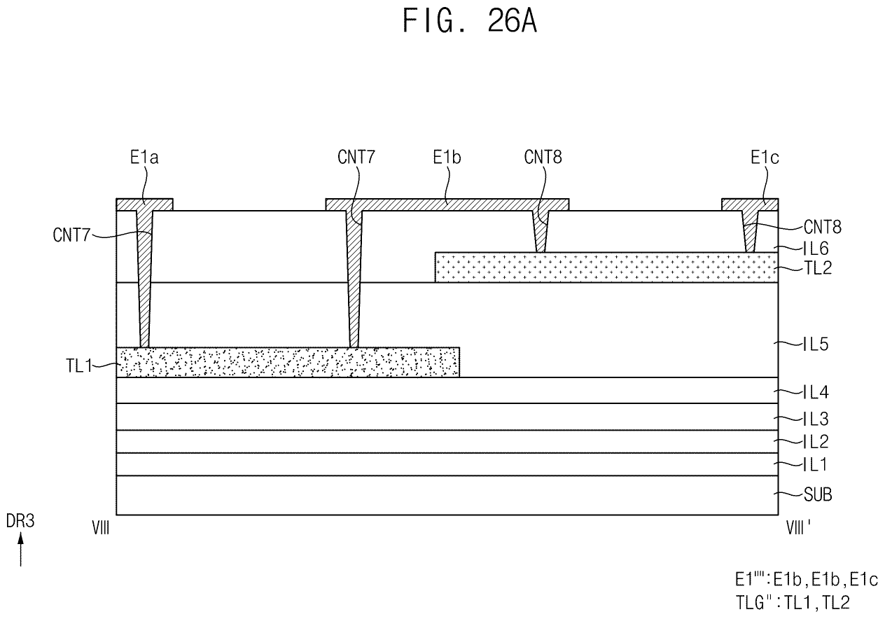

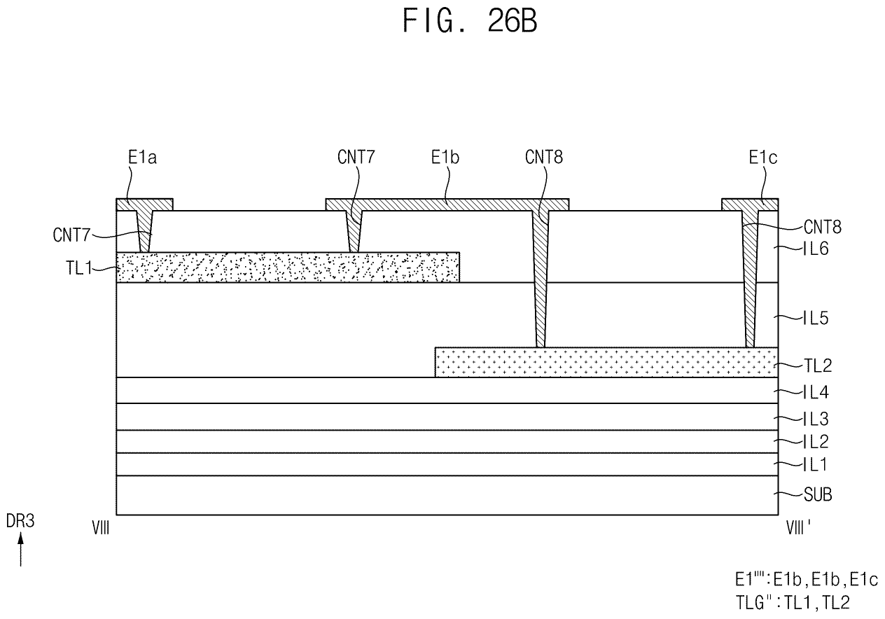

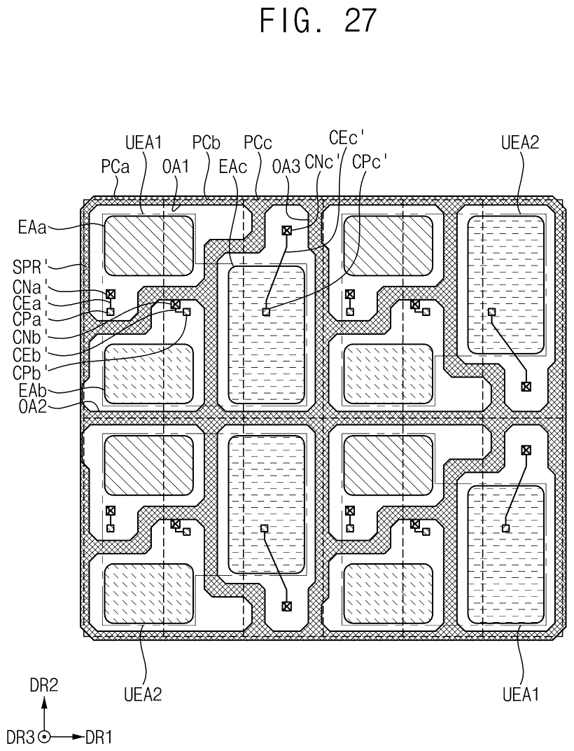

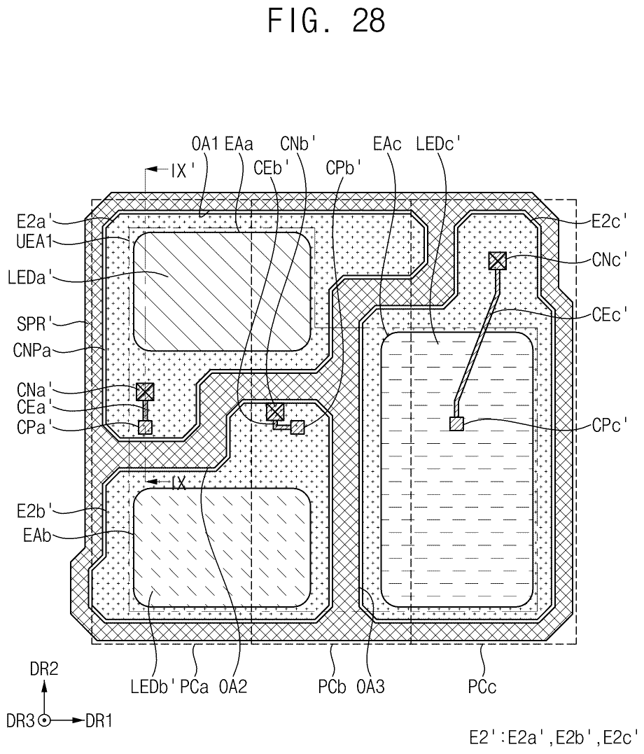

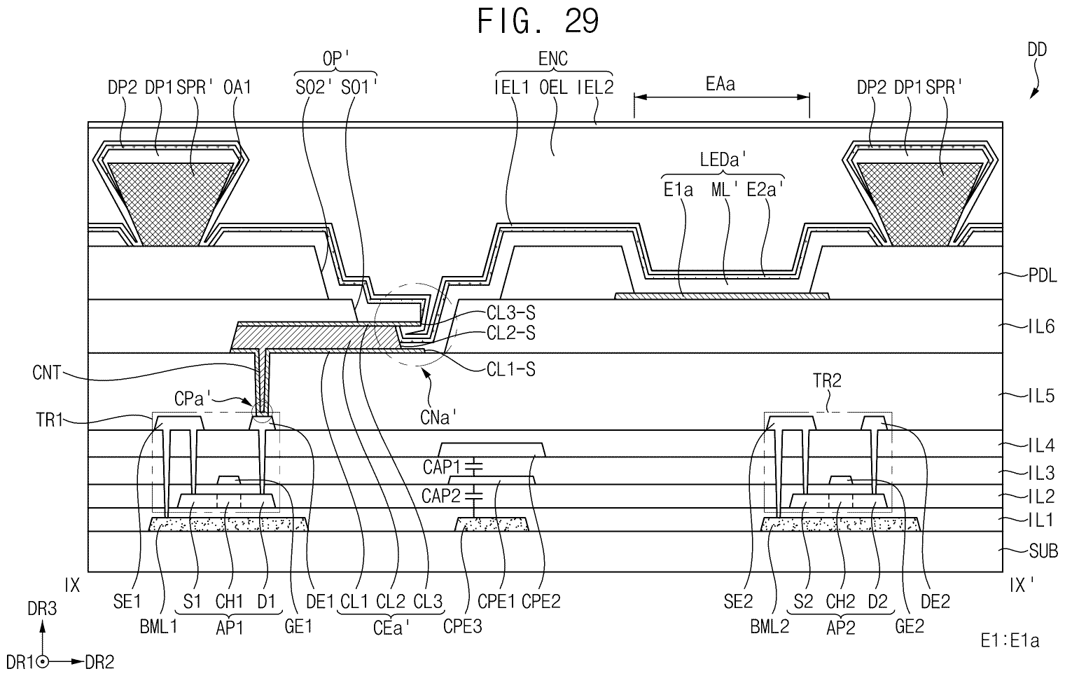

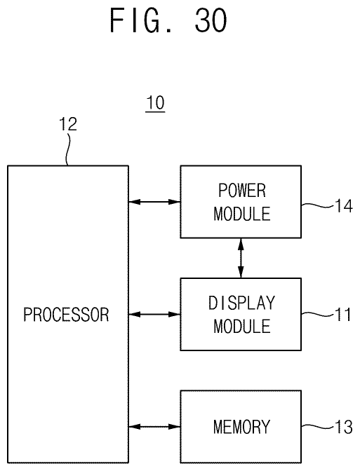

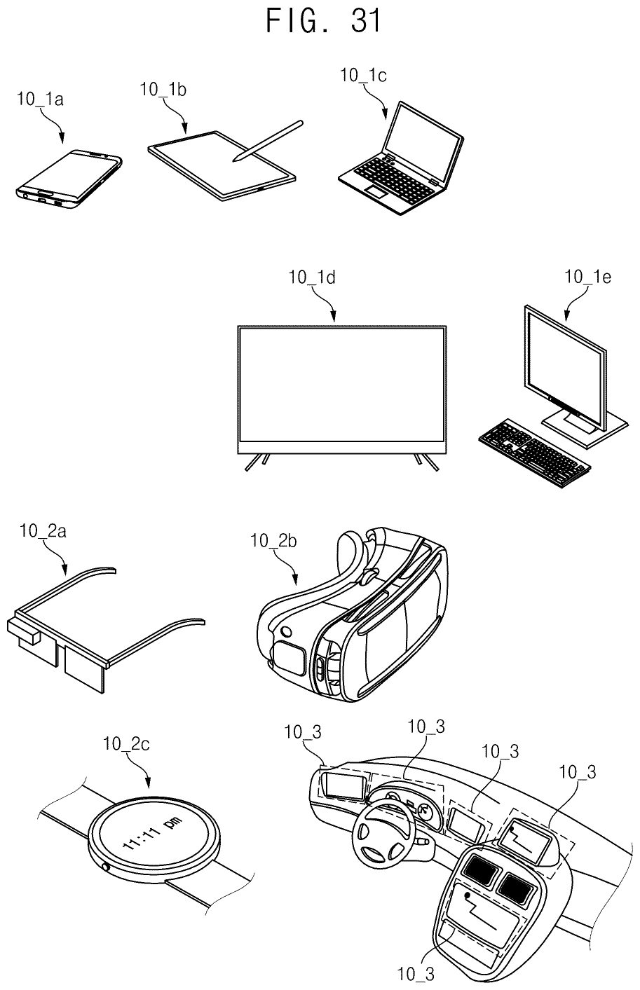

FIG. 23B is a cross-sectional view showing an example taken along line VII-VII′ of FIG. 22.

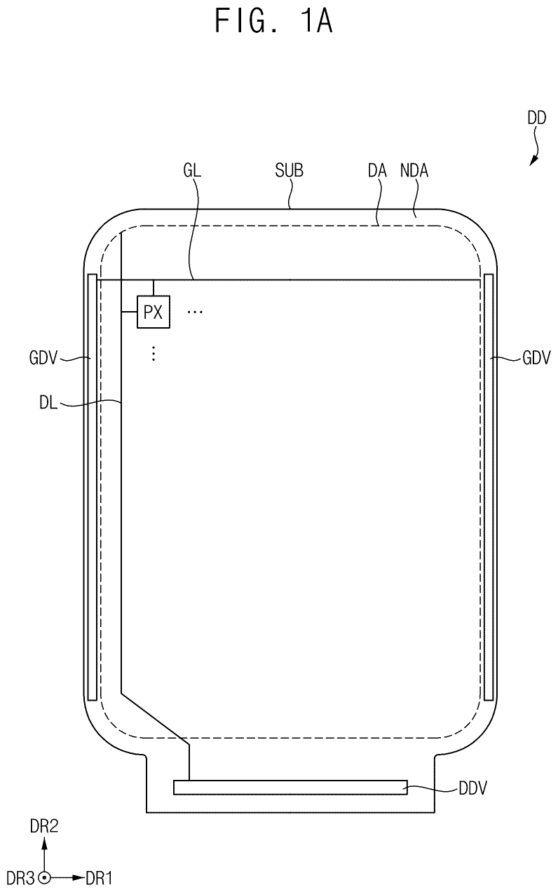

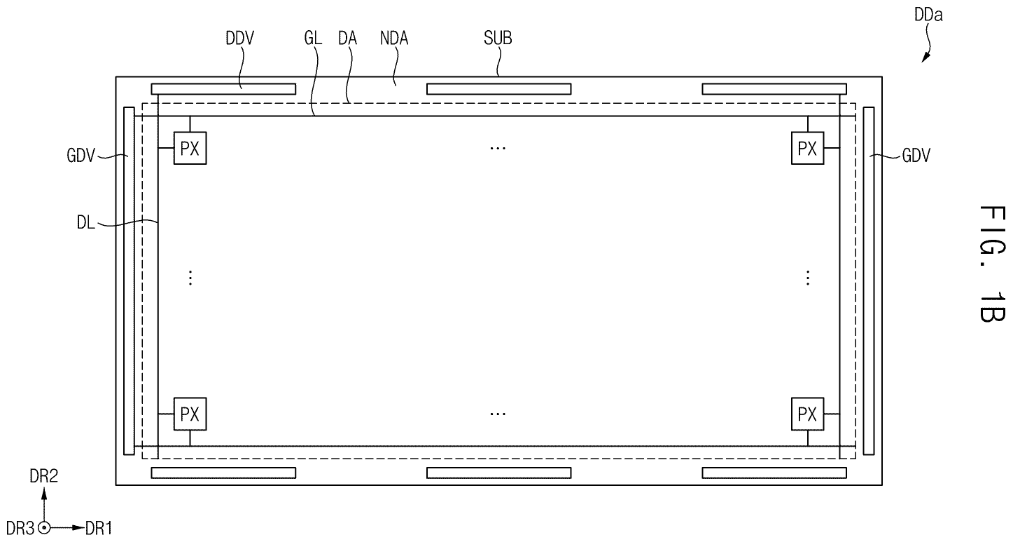

FIG. 24 is a plan view schematically showing a seventh embodiment of the arrangement relationship between a first electrode layer and a transmission line group disposed in a display area of FIGS. 1A and 1B.

FIG. 25 is an enlarged view showing area GG of FIG. 24.

FIG. 26A is a cross-sectional view showing an example taken along line VIII-VIII′ of FIG. 25.

FIG. 26B is a cross-sectional view showing an example taken along line VIII-VIII′ of FIG. 25.

FIG. 27 is a plan view schematically showing an example of a partial area of the display device of FIGS. 1A and 1B.

FIG. 28 is an enlarged view of one unit light-emitting areas among unit light-emitting areas of FIG. 27.

FIG. 29 is a cross-sectional view taken along line IX-IX′ of FIG. 28.

FIG. 30 is a block diagram showing an electronic device according to embodiments of the present disclosure.

FIG. 31 is a schematic diagram showing an electronic device according to various embodiments.

### DETAILED DESCRIPTION OF EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this disclosure will be thorough and complete, and will fully convey the scope of the present inventive concept to those skilled in the art. In the drawings, the sizes and relative sizes of layers and regions may be exaggerated for clarity.

In the disclosure, various modifications can be made, various forms can be used, and specific embodiments will be illustrated in the drawings and described in detail in the text. However, this is not intended to limit the disclosure to a specific form disclosed, and it will be understood that all changes, equivalents, or substitutes which fall in the spirit and technical scope of the disclosure should be included.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that an element being “connected” or “coupled” to another element is intended to mean both the element being directly connected or coupled to the other element or intervening element(s) being present. In contrast, when an element is referred to as being “directly connected” or “directly coupled” to another element, there is no intervening element present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. The same reference numerals are used for the same components in the drawings, and redundant descriptions of the same components will be omitted.

FIG. 1A is a plan view showing a display device according to an embodiment of the present disclosure. FIG. 1B is a plan view showing a display device according to an embodiment of the present disclosure.

Referring to FIGS. 1A and 1B, a display device DD (or DDa) may be a device activated according to an electrical signal. For example, the display device DD may be a small-sized display device used in a small-sized electronic device such as a smart phone, a mobile phone, a smart watch, a game console, a camera, or the like. In addition, the display device DDa may be a medium and large-sized display device used in medium and large-sized electronic devices such as a notebook computer, a tablet PC, a television, a computer monitor, a vehicle monitor, an external billboard, or the like. FIG. 1A illustrates the display device DD as an example of the small-sized display device, and FIG. 1B illustrates the display device DDa as an example of the medium and large-sized display device.

The display device DD (or DDa) may include a display area DA and a peripheral area NDA. The display area DA may be an area that displays an image by generating light or controlling a transmittance of light provided from an external light source. The peripheral area NDA may be located around the display area DA. For example, the peripheral area NDA may surround at least a portion of the display area DA. In an embodiment, the peripheral area NDA may be an area that does not display an image. However, embodiments are not limited thereto, and an image may be displayed in at least a portion of the peripheral area NDA. For example, a light-emitting element which emits light may be disposed in at least a portion of the peripheral area NDA.

The display device DD (or DDa) may include a substrate SUB, pixels PX, gate lines GL, data lines DL, a data driver DDV, and a gate driver GDV.

The substrate SUB may serve as a base of the display device DD (or DDa). In an embodiment, examples of materials that may be used as the substrate SUB may include glass, quartz, silicon, polymers, or the like. These may be used alone or in combination with each other. In addition, the substrate SUB may have a single-layer structure or a multi-layer structure in which a plurality of layers including different materials are stacked.

The pixels PX may be disposed in the display area DA on the substrate SUB. The pixels PX may be electrically connected to the gate lines GL and the data lines DL. For example, the pixels PX may be disposed in a matrix form in a first direction DR1 and a second direction DR2. The first direction DR1 and the second direction DR2 may be perpendicular to each other and define a plane. The image may be displayed in a third direction DR3, which is a normal direction of the plane. That is, the third direction DR3 may be perpendicular to both the first direction DR1 and the second direction DR2. Each of the pixels PX may include a pixel driving circuit part and a light-emitting element. The light-emitting element may emit light. The light emitting element may be an organic light-emitting diode or an inorganic light-emitting diode.

Each of the gate lines GL and each of the data lines DL may cross each other. For example, each of the gate lines GL may generally extend in the first direction DR1, and the gate lines GL may be arranged in the second direction DR2. Each of the data lines DL may generally extend in the second direction DR2, and the data lines DL may be arranged in the first direction DR1. However, the embodiments are not limited thereto.

The data driver DDV may be disposed in the peripheral area NDA on the substrate SUB. The data driver DDV may generate data voltages. The data driver DDV may output the data voltages to the data lines DL. The data voltages may be applied to the pixels PX through the data lines DL.

In an embodiment, the data driver DDV may be mounted on the substrate SUB. However, embodiments are not limited thereto, and the data driver DDV may be disposed on a flexible film coupled to the substrate SUB. That is, the display device DD (or DDa) may have a chip on film (COF) structure.

In an embodiment, the display device DDa of FIG. 1B may include a plurality of data drivers DDVs. For example, the data drivers DDVs may be disposed on both sides of the display area DA in the second direction DR2. For example, the data drivers DDVs may be disposed along each of long sides of the display device DDa. However, embodiments are not limited thereto.

The gate driver GDV may be disposed in the peripheral area NDA on the substrate SUB. The gate driver GDV may generate gate signals. The gate driver GDV may output the gate signals to the gate lines GL. The gate signals may be applied to the pixels PX through the gate lines GL. In an embodiment, gate drivers GDV may be disposed on both sides of the display area DA in the first direction DR1. However, embodiments are not limited thereto.

In an embodiment, an emission driver that generates emission control signals may be further disposed in the peripheral area NDA. The emission control signals may be applied to the pixels PX through emission control lines.

Meanwhile, the number or arrangement relationship of the data drivers DDVs and the number or arrangement relationship of the gate drivers GDVs illustrated in FIGS. 1A and 1B are merely examples, and embodiments are not limited thereto.

In addition, although FIG. 1A illustrates that the display device DD has a substantially rectangular planar shape having short sides each extending in the first direction DR1 and long sides each extending in the second direction DR2, embodiments are not limited thereto. In addition, although FIG. 1B illustrates that the display device DDa has a substantially rectangular planar shape having long sides each extending in the first direction DR1 and short sides each extending in the second direction DR2, embodiments are not limited thereto. That is, the planar shape of each of the display devices DD and DDa may be variously changed according to embodiments.

Meanwhile, descriptions below may be applied to the display device DD of FIG. 1A and the display device DDa of FIG. 1B. Therefore, for the convenience of description, the display devices DD and DDa are both referred to as the display device DD below.

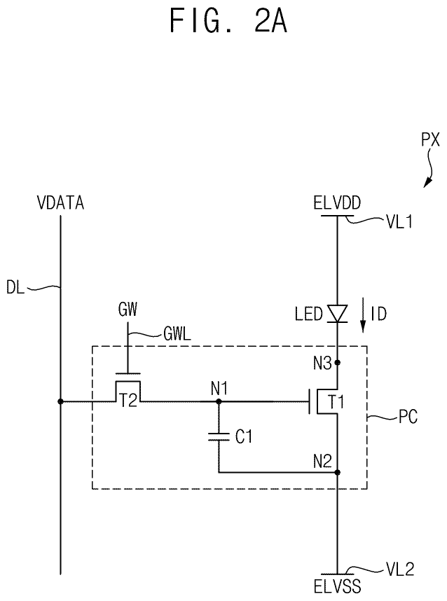

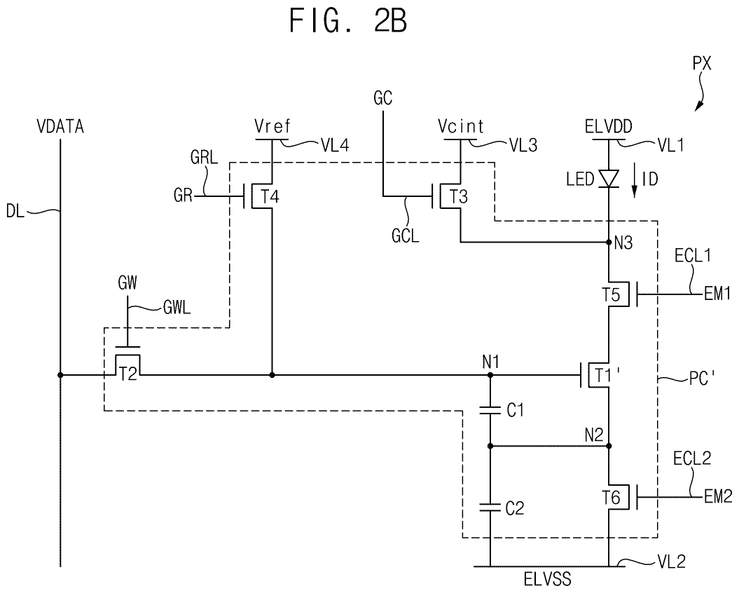

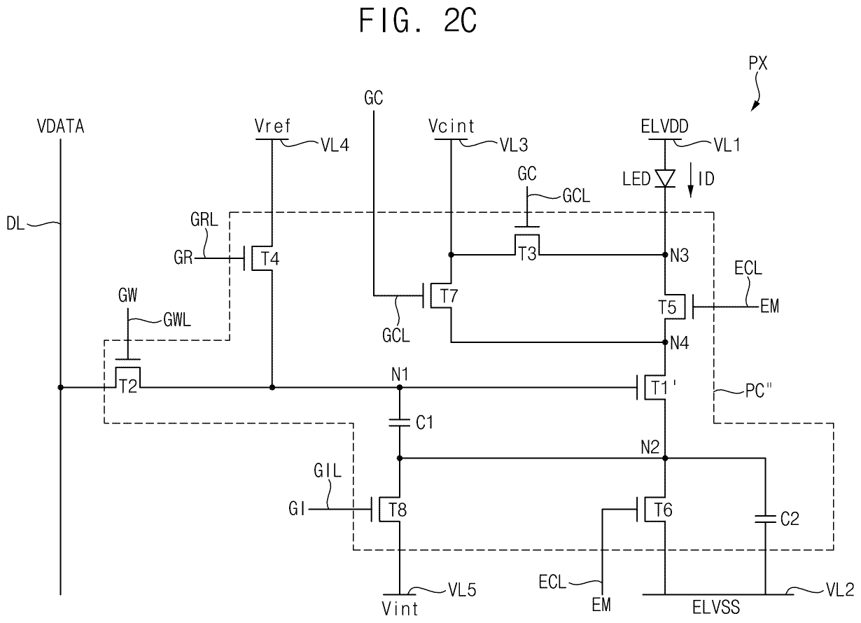

FIG. 2A is a circuit diagram illustrating an example of a circuit structure of a pixel included in the display device of FIGS. 1A and 1B.

Referring to FIG. 2A, in an embodiment, the pixel PX may include the light-emitting element LED and the pixel driving circuit part PC connected to the light-emitting element LED. In an embodiment, the pixel driving circuit part PC may include a first transistor T1, a second transistor T2, and a first capacitor C1. In FIG. 2A, both the first transistor T1 and the second transistor T2 are illustrated as n-type transistors. However, embodiments are not limited thereto, some of the first transistor T1 and the second transistor T2 may be n-type transistors, and others may be p-type transistors. For example, the first transistor T1 may be the n-type transistor, and the second transistor T2 may be the p-type transistor.

If the pixel PX includes the n-type transistor and the p-type transistor, an active pattern of the n-type transistor may include an oxide semiconductor material, and an active pattern of the p-type transistor may include a silicon semiconductor material. However, embodiments are not limited thereto, and both the active pattern of the n-type transistor and the active pattern of the p-type transistor may include a silicon semiconductor material.

The pixel driving circuit part PC may be connected to a first gate line GWL, a data line DL, a first voltage line VL1, and a second voltage line VL2. The first gate line GWL may transfer a first gate signal GW. The data line DL may transfer a data voltage VDATA. The first voltage line VL1 may transfer a first power supply voltage ELVDD having a relatively high voltage level. The second voltage line VL2 may transfer a second power supply voltage ELVSS having a relatively low voltage level.

The first transistor T1 may include a gate terminal, a first terminal, and a second terminal. In an embodiment, the first terminal of the first transistor T1 may be a source, and the second terminal of the first transistor T1 may be a drain. The gate terminal of the first transistor T1 may be connected to a first node N1. The first terminal of the first transistor T1 may be connected to a second node N2. The second terminal of the first transistor T1 may be connected to a third node N3. The second terminal of the first transistor T1 may be connected to the light-emitting element LED. The first transistor T1 may provide a driving current ID to the light-emitting element LED.

The second transistor T2 may include a gate terminal, a first terminal, and a second terminal. In an embodiment, the first terminal of the second transistor T2 may be a source, and the second terminal of the second transistor T2 may be a drain. However, embodiments are not limited thereto, the first terminal of the second transistor T2 may be a drain, and the second terminal of the second transistor T2 may be a source. The gate terminal of the second transistor T2 may be connected to the first gate line GWL. The first terminal of the second transistor T2 may be connected to the data line DL. The second terminal of the second transistor T2 may be connected to the first node N1.

The gate terminal of the second transistor T2 may receive the first gate signal GW through the first gate line GWL. The second transistor T2 may be turned on or off in response to the first gate signal GW. For example, if the second transistor T2 is an n-type transistor, the second transistor T2 may be turned off in response to the first gate signal GW having a negative voltage level, and the second transistor T2 may be turned on in response to the first gate signal GW having a positive voltage level. In addition, if the second transistor T2 is a p-type transistor, the second transistor T2 may be turned off in response to the first gate signal GW having a positive voltage level, and the second transistor T2 may be turned on in response to the first gate signal GW having a negative voltage level. The first terminal of the second transistor T2 may receive the data voltage VDATA through the data line DL. The second terminal of the second transistor T2 may provide the data voltage VDATA to the first node N1 while the second transistor T2 is turned on. Accordingly, the second transistor T2 may drive the first transistor T1.

The first capacitor C1 may include a first terminal and a second terminal. The first terminal of the first capacitor C1 may be connected to the first node N1. The second terminal of the first capacitor C1 may be connected to the second node N2. Current may be charged in or discharged from the first capacitor C1 according to the data voltage VDATA transferred to the first node N1.

The light-emitting element LED may include an anode and a cathode. The anode of the light-emitting element LED may be connected to the first voltage line VL1. The cathode of the light-emitting element LED may be connected to the third node N3. Specifically, the cathode of the light-emitting element LED may be connected to the second terminal of the first transistor T1.

FIG. 2B is a circuit diagram showing an example of a circuit structure of a pixel included in the display device of FIGS. 1A and 1B.

Compared to the embodiment of the circuit structure of the pixel PX described with reference to FIG. 2A, a pixel driving circuit part PC′ according to an embodiment of the circuit structure of the pixel PX described below with reference to FIG. 2B may further include third to sixth transistors T3, T4, T5, and T6 and a second capacitor C2. Therefore, redundant descriptions may be omitted or abbreviated.

Referring to FIG. 2B, in an embodiment, the pixel PX may include the light emitting element LED and the pixel driving circuit PC′ connected to the light emitting element LED. In an embodiment, the pixel driving circuit PC′ may include first to sixth transistors T1′, T2, T3, T4, T5, and T6, a first capacitor C1, and a second capacitor C2. In FIG. 2C, all of the first to sixth transistors T1′, T2, T3, T4, T5, and T6 are illustrated as n-type transistors. However, embodiments are not limited thereto, some of the first to sixth transistors T1′, T2, T3, T4, T5, and T6 may be n-type transistors, and others may be p-type transistors. For example, the first transistor T1′ may be the n-type transistor, some of the second to sixth transistors T2, T3, T4, T5, and T6 may be n-type transistors, and others may be p-type transistors.

If the pixel PX includes an n-type transistor and a p-type transistor, an active pattern of the n-type transistor may include an oxide semiconductor material, and an active pattern of the p-type transistor may include a silicon semiconductor material. However, embodiments are not limited thereto, and both the active pattern of the n-type transistor and the active pattern of the p-type transistor may include a silicon semiconductor material.

The pixel driving circuit part PC′ may be connected to first to third gate lines GWL, GCL, and GRL, a data line DL, first to fourth voltage lines VL1, VL2, VL3, and VL4, a first emission control line ECL1, and a second emission control line ECL2. The first gate line GWL may transfer a first gate signal GW. The second gate line GCL may transfer a second gate signal GC. The third gate line GRL may transfer a third gate signal GR. The data line DL may transfer a data voltage VDATA. The first voltage line VL1 may transfer a first power supply voltage ELVDD having a high voltage level. The second voltage line VL2 may transfer a second power supply voltage ELVSS having a low voltage level. The third voltage line VL3 may transfer a first initialization voltage Vcint. The fourth voltage line VL4 may transfer a reference voltage Vref. The reference voltage Vref may have a voltage level lower than a voltage level of the first power supply voltage ELVDD.

The first transistor T1′ of FIG. 2B may be substantially the same as the first transistor T1 described above with reference to FIG. 2A, except that the second terminal is connected to the light-emitting element LED through the fifth transistor T5. Therefore, redundant descriptions may be omitted or abbreviated. That is, the first transistor T1′ of the pixel driving circuit PC′ may be connected to the light-emitting element LED through the fifth transistor T5 and may provide the driving current ID to the light-emitting element LED through the fifth transistor T5.

The second transistor T2 of FIG. 2B may be substantially the same as the second transistor T2 described above with reference to FIG. 2A. Accordingly, the description of the second transistor T2 of FIG. 2A may be applied to the second transistor T2 of FIG. 2B. The second transistor T2 may drive the first transistor T1′ while the second transistor T2 is turned on.

The third transistor T3 may include a gate terminal, a first terminal, and a second terminal. In an embodiment, the first terminal of the third transistor T3 may be a source, and the second terminal of the third transistor T3 may be a drain. However, embodiments are not limited thereto, the first terminal of the third transistor T3 may be a drain, and the second terminal of the third transistor T3 may be a source. The gate terminal of the third transistor T3 may be connected to the second gate line GCL. The first terminal of the third transistor T3 may be connected to the third node N3. The second terminal of the third transistor T3 may be connected to the third voltage line VL3.

The gate terminal of the third transistor T3 may receive the second gate signal GC through the second gate line GCL. The third transistor T3 may be turned on or off in response to the second gate signal GC. For example, if the third transistor T3 is the n-type transistor, the third transistor T3 may be turned off in response to the second gate signal GC having a negative voltage level, and the third transistor T3 may be turned on in response to the second gate signal GC having a positive voltage level. In addition, if the third transistor T3 is the p-type transistor, the third transistor T3 may be turned off in response to the second gate signal GC having a positive voltage level, and the third transistor T3 may be turned on in response to the second gate signal GC having a negative voltage level. While the third transistor T3 is turned on, the third transistor T3 may provide the first initialization voltage Vcint to the third node N3. Specifically, the third transistor T3 may initialize a voltage of the cathode by providing the first initialization voltage Vcint to the cathode of the light-emitting element LED in response to the second gate signal GC.

The fourth transistor T4 may include a gate terminal, a first terminal, and a second terminal. In an embodiment, the first terminal of the fourth transistor T4 may be a source, and the second terminal of the fourth transistor T4 may be a drain. However, embodiments are not limited thereto, the first terminal of the fourth transistor T4 may be a drain, and the second terminal of the fourth transistor T4 may be a source. The gate terminal of the fourth transistor T4 may be connected to the third gate line GRL. The first terminal of the fourth transistor T4 may be connected to the first node N1. The second terminal of the fourth transistor T4 may be connected to the fourth voltage line VL4.

The gate terminal of the fourth transistor T4 may receive the third gate signal GR through the third gate line GRL. The fourth transistor T4 may be turned on or off in response to the third gate signal GR. For example, if the fourth transistor T4 is the n-type transistor, the fourth transistor T4 may be turned off in response to the third gate signal GR having a negative voltage level, and the fourth transistor T4 may be turned on in response to the third gate signal GR having a positive voltage level. In addition, if the fourth transistor T4 is the p-type transistor, the fourth transistor T4 may be turned off in response to the third gate signal GR having a positive voltage level, and the fourth transistor T4 may be turned on in response to the third gate signal GR having a negative voltage level. While the fourth transistor T4 is turned on, the fourth transistor T4 may provide the reference voltage Vref to the first node N1.

The fifth transistor T5 may include a gate terminal, a first terminal, and a second terminal. In an embodiment, the first terminal of the fifth transistor T5 may be a source, and the second terminal of the fifth transistor T5 may be a drain. However, embodiments are not limited thereto, the first terminal of the fifth transistor T5 may be a drain, and the second terminal of the fifth transistor T5 may be a source. The gate terminal of the fifth transistor T5 may be connected to the first emission control line ECL1. The first terminal of the fifth transistor T5 may be connected to the second terminal of the first transistor T1′. The second terminal of the fifth transistor T5 may be connected to the third node N3. The second terminal of the fifth transistor T5 may be connected to the light-emitting element LED.

The gate terminal of the fifth transistor T5 may receive the first emission control signal EM1 through the first emission control line ECL1. The fifth transistor T5 may be turned on or off in response to the first emission control signal EM1. For example, if the fifth transistor T5 is the n-type transistor, the fifth transistor T5 may be turned off in response to the first emission control signal EM1 having a negative voltage level, and the fifth transistor T5 may be turned on in response to the first emission control signal EM1 having a positive voltage level. In addition, if the fifth transistor T5 is the p-type transistor, the fifth transistor T5 may be turned off in response to the first emission control signal EM1 having a positive voltage level, and the fifth transistor T5 may be turned on in response to the first emission control signal EM1 having a negative voltage level. While the fifth transistor T5 is turned on, the fifth transistor T5 may electrically connect the first transistor T1′ and the light-emitting element LED to each other. Specifically, the fifth transistor T5 may electrically connect the second terminal of the first transistor T1′ and the cathode of the light-emitting element LED to each other in response to the first emission control signal EM1.

The sixth transistor T6 may include a gate terminal, a first terminal, and a second terminal. In an embodiment, the first terminal of the sixth transistor T6 may be a source, and the second terminal of the sixth transistor T6 may be a drain. However, embodiments are not limited thereto, the first terminal of the sixth transistor T6 may be a drain, and the second terminal of the sixth transistor T6 may be a source. The gate terminal of the sixth transistor T6 may be connected to the second emission control line ECL2. The first terminal of the sixth transistor T6 may be connected to the second voltage line VL2. The second terminal of the sixth transistor T6 may be connected to the second node N2.

The gate terminal of the sixth transistor T6 may receive the second emission control signal EM2 through the second emission control line ECL2. The sixth transistor T6 may be turned on or off in response to the second emission control signal EM2. For example, if the sixth transistor T6 is the n-type transistor, the sixth transistor T6 may be turned off in response to the second emission control signal EM2 having a negative voltage level, and the sixth transistor T6 may be turned on in response to the second emission control signal EM2 having a positive voltage level. In addition, if the sixth transistor T6 is the p-type transistor, the sixth transistor T6 may be turned off in response to the second emission control signal EM2 having a positive voltage level, and the sixth transistor T6 may be turned on in response to the second emission control signal EM2 having a negative voltage level. While the sixth transistor T6 is turned on, the sixth transistor T6 may provide the second power supply voltage ELVSS to the second node N2.

Although FIG. 2B illustrates that the fifth transistor T5 and the sixth transistor T6 are independently driven by different emission control signals, embodiments are not limited thereto. For example, the first emission control signal EM1 and the second emission control signal EM2 may be provided as a substantially single emission control signal, and the fifth transistor T5 and the sixth transistor T6 may be simultaneously turned on or off. In this case, the first emission control line ECL1 and the second emission control line ECL2 may be provided as a single emission control line.

The first capacitor C1 of FIG. 2B may be substantially the same as the first capacitor C1 described above with reference to FIG. 2A. Accordingly, the description of the first capacitor C1 of FIG. 2A may be applied to the first capacitor C1 of FIG. 2B. That is, current may be charged in or discharged from the first capacitor C1 according to the data voltage VDATA transferred to the first node N1.

The second capacitor C2 may include a first terminal and a second terminal. The first terminal of the second capacitor C2 may be connected to the second node N2. The second terminal of the second capacitor C2 may be connected to the second voltage line VL2. Specifically, the second capacitor C2 may be connected in series to the first capacitor C1. The data voltage VDATA may be transferred to the first node N1 and may be voltage-divided due to the serial connection between the first capacitor C1 and the second capacitor C2 so that the divided data voltage VDATA may be transferred to the second node N2. Since the first transistor T1′ generates the driving current ID based on a voltage of the first node N1 and a voltage of the second node N2, a data range may be extended.

The light-emitting element LED of FIG. 2B may be substantially the same as the light-emitting element LED described above with reference to FIG. 2A, except that the cathode is connected to the second terminal of the first transistor T1′ through the fifth transistor T5. Therefore, redundant descriptions may be omitted or abbreviated. That is, the cathode of the light-emitting element LED may be connected to the second terminal of the first transistor T1′ through the fifth transistor T5. In addition, the cathode of the light-emitting element LED may receive the first initialization voltage Vcint through the third transistor T3.

FIG. 2C is a circuit diagram showing still an example of a circuit structure of a pixel included in the display device of FIGS. 1A and 1B.

Compared to the embodiment of the circuit structure of the pixel PX described with reference to FIG. 2B, a pixel driving circuit part PC″ according to an embodiment of the circuit structure of the pixel PX described below with reference to FIG. 2C may further include seventh and eighth transistors T7 and T8. Therefore, redundant descriptions may be omitted or abbreviated.

Referring to FIG. 2C, in an embodiment, the pixel PX may include the light-emitting element LED and the pixel driving circuit part PC″ connected to the light-emitting element LED. In an embodiment, the pixel driving circuit part PC″ may include first to eighth transistors T1′, T2, T3, T4, T5, T6, T7, and T8, a first capacitor C1, and a second capacitor C2. In FIG. 2C, all of the first to eighth transistors T1′, T2, T3, T4, T5, T6, T7, and T8 are illustrated as n-type transistors. However, embodiments are not limited thereto, some of the first to eighth transistors T1′, T2, T3, T4, T5, T6, T7, and T8 may be n-type transistors, and others may be p-type transistors. For example, the first transistor T1′ may be the n-type transistor, some of the second to eighth transistors T2, T3, T4, T5, T6, T7, and T8 may be the n-type transistors, and others may be the p-type transistors.

If the pixel PX includes a mix of n-type and p-type transistors, an active pattern of an n-type transistor may include an oxide semiconductor material, and an active pattern of a p-type transistor may include a silicon semiconductor material. However, embodiments are not limited thereto, and both the active pattern of the n-type transistor and the active pattern of the p-type transistor may include a silicon semiconductor material.

The pixel driving circuit PC″ may be connected to first to fourth gate lines GWL, GCL, GRL, and GIL, a data line DL, first to fifth voltage lines VL1, VL2, VL3, VL4, and VL5, and an emission control line ECL. The first gate line GWL may transfer a first gate signal GW. The second gate line GCL may transfer a second gate signal GC. The third gate line GRL may transfer a third gate signal GR. The fourth gate line GIL may transfer a fourth gate signal GI. The data line DL may transfer a data voltage VDATA. The first voltage line VL1 may transfer a first power voltage ELVDD having a relatively high voltage level. The second voltage line VL2 may transfer a second power voltage ELVSS having a relatively low voltage level. The third voltage line VL3 may transfer a first initialization voltage Vcint. The fourth voltage line VL4 may transfer a reference voltage Vref. The reference voltage Vref may have a voltage level lower than a voltage level of the first power voltage ELVDD. The fifth voltage line VL5 may transfer a second initialization voltage Vint. The first initialization voltage Vcint and the second initialization voltage Vint may have different voltage levels from each other.

The first to sixth transistors T1′, T2, T3, T4, T5, and T6, the first capacitor C1, and the second capacitor C2 of FIG. 2C may be substantially the same as the first to sixth transistors T1′, T2, T3, T4, T5, and T6, the first capacitor C1, and the second capacitor C2 described above with reference to FIG. 2B, respectively. Accordingly, the descriptions of the first to sixth transistors T1′, T2, T3, T4, T5, and T6, the first capacitor C1, and the second capacitor C2 of FIG. 2B may be applied to the first to sixth transistors T1′, T2, T3, T4, T5, and T6, the first capacitor C1, and the second capacitor C2 of FIG. 2C, respectively. Therefore, redundant descriptions may be omitted.

Meanwhile, although FIG. 2C illustrates that the fifth transistor T5 and the sixth transistor T6 are simultaneously driven by the emission control signal EM, embodiments are not limited thereto. For example, as in FIG. 2B, the fifth transistor T5 and the sixth transistor T6 may be independently driven by different emission control signals (e.g., the first emission control signal EM1 and the second emission control signal EM2 of FIG. 2B). At this time, the emission control line connected to the fifth transistor T5 and the emission control line connected to the sixth transistor T6 may be different emission control lines (e.g., the first emission control line ECL1 and the second emission control line ECL2 of FIG. 2B) that are distinct from each other.

The seventh transistor T7 may include a gate terminal, a first terminal, and a second terminal. In an embodiment, the first terminal of the seventh transistor T7 may be a source, and the second terminal of the seventh transistor T7 may be a drain. However, embodiments are not limited thereto, the first terminal of the seventh transistor T7 may be a drain, and the second terminal of the seventh transistor T7 may be a source. The gate terminal of the seventh transistor T7 may be connected to the second gate line GCL. The first terminal of the seventh transistor T7 may be connected to a fourth node N4. The second terminal of the seventh transistor T7 may be connected to the third voltage line VL3.

The gate terminal of the seventh transistor T7 may receive the second gate signal GC through the second gate line GCL. The seventh transistor T7 may be turned on or off in response to the second gate signal GC. For example, if the seventh transistor T7 is the n-type transistor, the seventh transistor T7 may be turned off in response to the second gate signal GC having a negative voltage level, and the seventh transistor T7 may be turned on in response to the second gate signal GC having a positive voltage level. If the seventh transistor T7 is the p-type transistor, the seventh transistor T7 may be turned off in response to the second gate signal GC having a positive voltage level, and the seventh transistor T7 may be turned on in response to the second gate signal GC having a negative voltage level. While the seventh transistor T7 is turned on, the seventh transistor T7 may provide the first initialization voltage Vcint to the fourth node N4. Specifically, the seventh transistor T7 may compensate for a threshold voltage (Vth) of the first transistor T1′ by providing the first initialization voltage Vcint to the fourth node N4 in response to the second gate signal GC.

Meanwhile, although FIG. 2C illustrates that the gate line connected to the third transistor T3 and the gate line connected to the seventh transistor T7 are provided as a single gate line (i.e., the second gate line GCL), embodiments are not limited thereto. For example, the gate line connected to the third transistor T3 and the gate line connected to the seventh transistor T7 may be different gate lines that are distinct from each other.

In addition, although FIG. 2C illustrates that the third transistor T3 and the seventh transistor T7 are simultaneously driven by the second gate signal GC, embodiments are not limited thereto. For example, the third transistor T3 and the seventh transistor T7 may be independently driven by different gate signals. At this time, the gate line connected to the third transistor T3 and the gate line connected to the seventh transistor T7 may be different gate lines that are distinct from each other.

The eighth transistor T8 may include a gate terminal, a first terminal, and a second terminal. In an embodiment, the first terminal of the eighth transistor T8 may be a source, and the second terminal of the eighth transistor T8 may be a drain. However, embodiments are not limited thereto, the first terminal of the eighth transistor T8 may be a drain, and the second terminal of the eighth transistor T8 may be a source. The gate terminal of the eighth transistor T8 may be connected to the fourth gate line GIL. The first terminal of the eighth transistor T8 may be connected to the second node N2. The second terminal of the eighth transistor T8 may be connected to the fifth voltage line VL5.

The gate terminal of the eighth transistor T8 may receive the fourth gate signal GI through the fourth gate line GIL. The eighth transistor T8 may be turned on or off in response to the fourth gate signal GI. For example, if the eighth transistor T8 is the n-type transistor, the eighth transistor T8 may be turned off in response to the fourth gate signal GI having a negative voltage level, and the eighth transistor T8 may be turned on in response to the fourth gate signal GI having a positive voltage level. If the eighth transistor T8 is the p-type transistor, the eighth transistor T8 may be turned off in response to the fourth gate signal GI having a positive voltage level, and the eighth transistor T8 may be turned on in response to the fourth gate signal GI having a negative voltage level. While the eighth transistor T8 is turned on, the eighth transistor T8 may provide the second initialization voltage Vint to the second node N2.

The light-emitting element LED of FIG. 2C may be substantially the same as the light-emitting element LED described above with reference to FIG. 2B. Accordingly, the description of the light-emitting element LED of FIG. 2B may be applied to the light-emitting element LED of FIG. 2C. Therefore, redundant descriptions may be omitted.

As illustrated in FIGS. 2A to 2C, according to embodiments, the anode of the light-emitting element LED may receive the first power supply voltage ELVDD through the first voltage line VL1, and the cathode of the light-emitting element LED may be connected to the second terminal of the first transistor T1 (or T1′). That is, a potential of the cathode of the light emitting element LED may be controlled by being electrically connected to the first transistor T1 (or T1′).

Since the first voltage line VL1 provides the first power supply voltage ELVDD having a high voltage level and the second voltage line VL2 provides the second power supply voltage ELVSS having a low voltage level, if the first transistor T1 (or T1′) is the n-type transistor, the second terminal of the first transistor T1 (or T1′) may be a drain. That is, according to embodiments, the cathode of the light-emitting element LED may be connected to the drain of the first transistor T1 (or T1′).

If the first transistor T1 (or T1′) is an n-type transistor, if the anode of the light emitting element LED is connected to the source of first transistor T1 (or T1′), a source voltage of the first transistor T1 (or T1′) may shift due to deterioration of the light-emitting element LED so that a gate-source voltage (Vgs) of the first transistor T1 (or T1′) may change. As a result, fluctuation of the driving current ID may increase, an after-image defect may occur, and a lifespan of the display device may be reduced.

According to embodiments, the anode of the light-emitting element LED may receive the first power voltage ELVDD, and the cathode of the light-emitting element LED may be connected to the drain of the first transistor T1 (or T1′). Accordingly, even when the light-emitting element LED deteriorates, the gate-source voltage (Vgs) of the first transistor T1 (or T1′) may not change. Accordingly, the range of change in the driving current ID due to the deterioration of the light-emitting element LED may be reduced. Therefore, the after-image defect of the display device DD depending on an increase in the time of use may be reduced, and the lifespan of the display device DD may be improved.

Meanwhile, the circuit structures of the pixels (e.g., the number or arrangement relationship of the transistors, the number or arrangement relationship of the capacitors) illustrated in FIGS. 2A to 2C are only examples and may be variously changed according to embodiments.

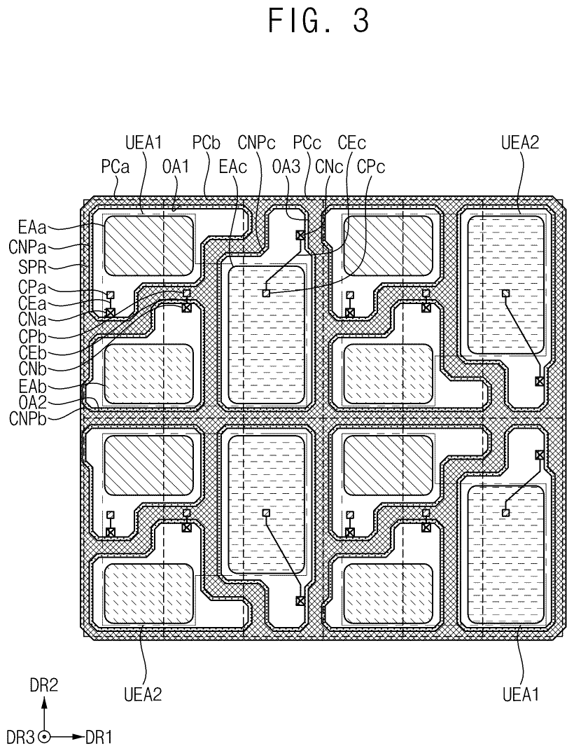

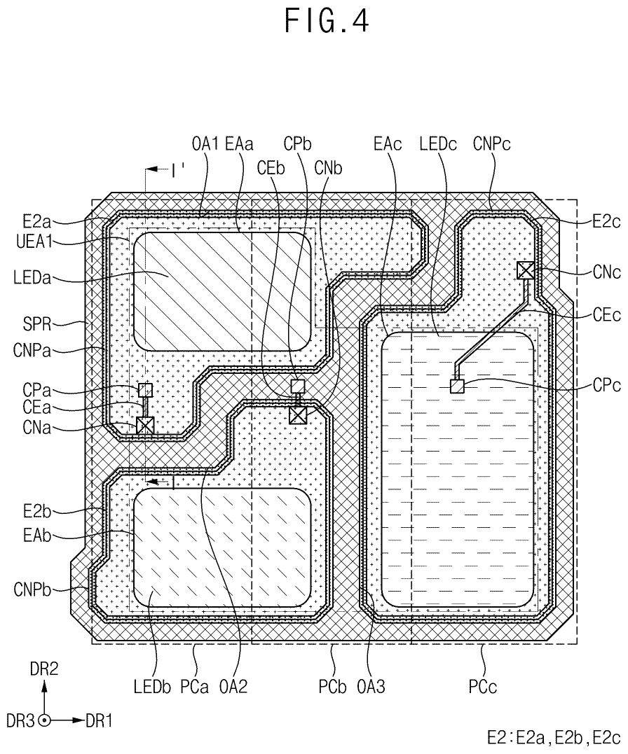

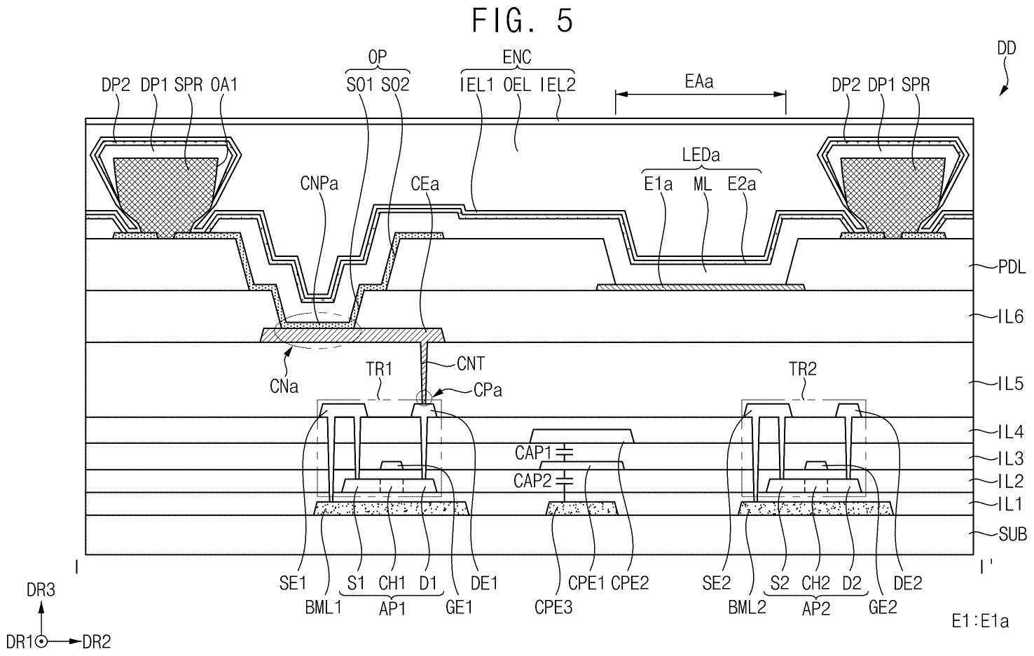

FIG. 3 is a plan view schematically showing an example of a partial area of the display device of FIGS. 1A and 1B. FIG. 4 is an enlarged view of one unit light-emitting areas among unit light-emitting areas of FIG. 3. FIG. 5 is a cross-sectional view taken along line I-I′ of FIG. 4.

Specifically, FIG. 3 depicts four areas arranged in a matrix of 2 rows and 2 columns, with two of the areas being unit light-emitting areas UEA1 positioned diagonally with respect to each other, and the other two areas being unit light-emitting areas UEA2 positioned diagonally with respect to each other as shown. FIG. 4 depicts one first unit light-emitting area UEA1 of the unit light-emitting areas UEA1 and UEA2 in FIG. 3. FIG. 5 depicts a cross-sectional view taken along the line I-I′ shown in FIG. 4. For convenience of explanation, some of the components shown in FIG. 5 are omitted or emphasized in FIGS. 3 and 4. In addition, second electrodes E2a, E2b, and E2c are shown in FIG. 4 but omitted in FIG. 3 for clarity of illustration.

Referring to FIGS. 3 and 4, the display device DD may include first to third pixel driving circuit parts PCa, PCb, and PCc, first to third light-emitting elements LEDa, LEDb, and LEDc, first to third connection electrodes CEa, CEb, and CEc, first to third connection patterns CNPa, CNPb, and CNPc, and a separator SPR.

Each of the first to third pixel driving circuit parts PCa, PCb, and PCc may correspond to at least one of the pixel driving circuit parts PC, PC′, and PC″ described with reference to FIGS. 2A to 2C. That is, each of the first to third pixel driving circuit parts PCa, PCb, and PCc may include at least one transistor and at least one capacitor. For example, each of the first to third pixel driving circuit parts PCa, PCb, and PCc may include a first transistor TR1, a second transistor TR2, a first capacitor CAP1, and a second capacitor CAP2 shown in FIG. 5.

At this time, the first transistor TR1 of FIG. 5 may be a transistor connected to the light-emitting element through a connection electrode and a connection pattern. For example, if the first to third pixel driving circuit parts PCa, PCb, and PCc are the pixel driving circuit part PC of FIG. 2A, the first transistor TR1 may be the first transistor T1 of FIG. 2A and the second transistor TR2 may be the second transistor T2 of FIG. 2A. In addition, if the first to third pixel driving circuit parts PCa, PCb, and PCc are the pixel driving circuit parts PC′ of FIG. 2B, the first transistor TR1 may be the fifth transistor T5 of FIG. 2B and the second transistor TR2 may be any one of the first to fourth transistors T1′, T2, T3, and T4 and the sixth transistor T6 of FIG. 2B. In addition, if the first to third pixel driving circuit unit parts PCa, PCb, and PCc are the pixel driving circuit unit part PC″ of FIG. 2C, the first transistor TR1 may be the fifth transistor T5 of FIG. 2C and the second transistor TR2 may be any one of the first to fourth transistors T1′, T2, T3, and T4 and the sixth to eight transistor T6, T7, and T8 of FIG. 2C. However, embodiments of the present disclosure are not necessarily limited thereto.

In an embodiment, the first capacitor CAP1 of FIG. 5 may correspond to the first capacitor C1 of FIGS. 2A to 2C, and the second capacitor CAP2 of FIG. 5 may correspond to the first capacitor C2 of FIGS. 2B and 2C. That is, if the first to third pixel driving circuit unit parts PCa, PCb, and PCc are the pixel driving circuit unit part PC of FIG. 2A, the second capacitor CAP2 may be omitted. However, the present disclosure is not necessarily limited thereto, and in an embodiment, the first capacitor CAP1 of FIG. 5 may correspond to the second capacitor C2 of FIGS. 2A to 2C, and the second capacitor CAP2 of FIG. 5 may correspond to the first capacitor C1 of FIGS. 2B and 2C. In this case, if the first to third pixel driving circuit unit parts PCa, PCb, and PCc are the pixel driving circuit unit part PC of FIG. 2A, the first capacitor CAP1 may be omitted.

The components of the first transistor TR1, the second transistor TR2, the first capacitor CAP1, and the second capacitor CAP2 will be described in more detail later with reference to FIG. 5.

Meanwhile, in FIGS. 3 and 4, the first to third pixel driving circuit parts PCa, PCb, and PCc are shown as being sequentially arranged along the first direction DR1 in a rectangular shape. However, the present disclosure is not necessarily limited to this, and the shape and arrangement of the first to third pixel driving circuit unit parts PCa, PCb, and PCc may vary depending on the embodiments.

Each of the first to third light-emitting elements LEDa, LEDb, and LEDc may correspond to the light-emitting element LED described with reference to FIGS. 2A to 2C. For example, the first to third light-emitting elements LEDa, LEDb, and LEDc include a first electrode layer (e.g., a first electrode layer E1 of FIG. 5), which will be described later, an intermediate layer (e.g., an intermediate layer ML of FIG. 5) disposed on the first electrode layer, and a second electrode layer E2 disposed on the intermediate layer. In an embodiment, the first electrode layer may function as the anode of FIGS. 2A to 2C, and the second electrode layer E2 may function as the cathode of FIGS. 2A to 2C.

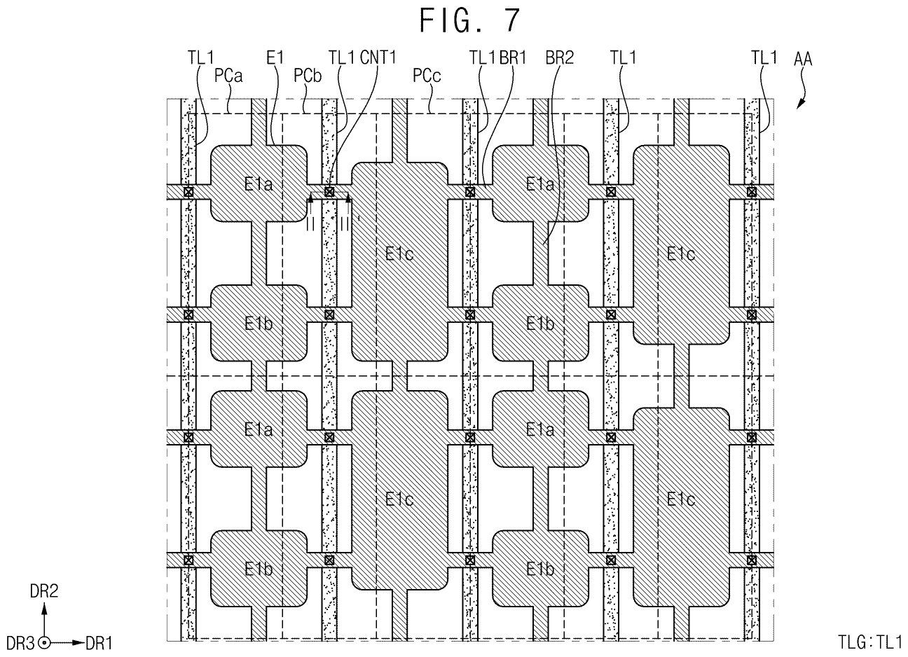

In an embodiment, the first electrode layer E1 may include first electrodes E1a, E1b, and E1c (see FIG. 7), which will be described later. Specifically, the first electrode layer E1 may include the first electrode E1a of the first light-emitting element LEDa, the first electrode E1b of the second light-emitting element LEDb, and the first electrode E1c of the third light-emitting element LEDc. This will be described in more detail later with reference to FIG. 7.

In an embodiment, the second electrode layer E2 may be separated (or disconnected) into second electrodes E2a, E2b, and E2c by the separator SPR. Specifically, the second electrode layer E2 may be separated (or disconnected) by the second electrode E2a of the first light-emitting element LEDa, the second electrode E2b of the second light-emitting element LEDb, and the second electrode E2c of the third light-emitting element LEDc, and the second electrodes E2a, E2b, and E2c may be electrically independent from each other. This will be described in more detail later.

That is, the first light-emitting element LEDa may include the first electrode E1a (see FIG. 7) functioning as the anode and the second electrode E2a functioning as the cathode, the second light-emitting element LEDb may include the first electrode E1b (see FIG. 7) functioning as the anode and the second electrode E2b functioning as the cathode, and the third light-emitting element LEDc may include the first electrode E1c (see FIG. 7) functioning as the anode and the second electrode E2c functioning as the cathode.

The first to third light-emitting elements LEDa, LEDb, and LEDc may emit light of different colors. For example, the first light-emitting element LEDa may emit red light, the second light-emitting element LEDb may emit green light, and the third light-emitting element LEDc may emit blue light. However, the present disclosure is not necessarily limited thereto.

In an embodiment, the display device DD may include a first unit light-emitting area UEA1 and a second unit light-emitting area UEA2. The first unit light-emitting area UEA1 and the second unit light-emitting area UEA2 may be arranged in a matrix form along the first direction DR1 and the second direction DR2. Although four unit light-emitting areas are shown in FIG. 3, this is not a limitation of the disclosure and more unit light-emitting areas may be arranged in a matrix form along the first direction DR1 and the second direction DR2 in the display area DA (see FIGS. 1A and 1B).

The first to third light-emitting elements LEDa, LEDb, and LEDc may be disposed adjacent to each other in each of the first unit light-emitting area UEA1 and the second unit light-emitting area UEA2. For example, first to third light-emitting areas EAa, EAb, and EAc adjacent to each other may be defined within each of the first unit light-emitting area UEA1 and the second unit light-emitting area UEA2, and the first to third light-emitting elements LEDa, LEDb, and LEDc may be disposed in the first to third light-emitting areas EAa, EAb, and EAc, respectively.

The first to third light-emitting areas EAa, EAb, and EAc may be defined by a pixel opening of a pixel defining layer PDL (see FIG. 5), which will be described later. That is, the first to third light-emitting areas EAa, EAb, and EAc may be areas where light is emitted by the light-emitting element. For example, the first light-emitting element LEDa may be disposed in the first light-emitting area EAa, and the first light-emitting area EAa may be an area where light is emitted by the first light-emitting element LEDa. In addition, the second light-emitting element LEDb may be disposed in the second light-emitting area EAb, and the second light-emitting area EAb may be an area where light is emitted by the second light-emitting element LEDb. In addition, the third light-emitting element LEDc may be disposed in the third light-emitting area EAc, and the third light-emitting area EAc may be an area where light is emitted by the third light-emitting element LEDc.

In an embodiment, the first unit light-emitting area UEA1 and the second unit light-emitting area UEA2 may be distinguished based on the arrangement of the first to third light-emitting elements LEDa, LEDb, and LEDc (or, arrangement of the first to third light-emitting areas EAa, EAb, and EAc). That is, the positions of the first to third light-emitting elements LEDa, LEDb, and LEDc (or the first to third light-emitting areas EAa, EAb, and EAc) relative to one another may be same in each first unit light emitting area UEA1, and the positions of the first to third light-emitting elements LEDa, LEDb, and LEDc (or the first to third light-emitting areas EAa, EAb, and EAc) relative to one another may be same in each second unit light emitting area UEA2.

As shown in FIG. 3, in an embodiment, the first unit light-emitting area UEA1 and the second unit light-emitting area UEA2 may be alternately arranged along the first direction DR1 (i.e., a row direction) and the second direction DR2 (i.e, a column direction). However, the present disclosure is not necessarily limited to this, and the number of different unit light-emitting areas included in the display device DD or the arrangement relationship between the unit light-emitting areas may vary depending on the embodiments.

Meanwhile, in FIGS. 3 and 4, the first to third light emitting areas EAa, EAb, and EAc are shown as arranged in an S-stripe type. However, the present disclosure is not necessarily limited to this, and the arrangement of the first to third light-emitting areas EAa, EAb, and EAc may vary depending on the embodiments.

The first to third light-emitting elements LEDa, LEDb, and LEDc may be connected to the first to third pixel driving circuit parts PCa, PCb, and PCc, respectively. For example, the first light-emitting element LEDa may be connected to the first pixel driving circuit part PCa, the second light-emitting element LEDb may be connected to the second pixel driving circuit part PCb, and the third light-emitting element LEDc may be connected to the third pixel driving circuit part PCc. Accordingly, the first pixel driving circuit part PCa and the first light-emitting element LEDa may form one pixel, the second pixel driving circuit part PCb and the second light-emitting element LEDb may form one pixel, and the third pixel driving circuit part PCc and the third light-emitting element LEDc may form one pixel.

Hereinafter, the connection relationship between the first to third light-emitting elements LEDa, LEDb, and LEDc and the first to third pixel driving circuit parts PCa, PCb, and PCc will be described in more detail, focusing on the first unit light-emitting area UEA1 of FIG. 4. The following description of the connection relationship between the first to third light-emitting elements LEDa, LEDb, and LEDc and the first to third pixel driving circuit parts PCa, PCb, and PCc may be applied to all unit light-emitting areas.

electrodes CEa, CEb, and CEc and the first to third connection patterns CNPa, CNPb, and CNPc. The first connection electrode CEa and the first connection pattern CNPa may connect the first light-emitting element LEDa and the first pixel driving circuit part PCa, the second connection electrode CEb and the second connection pattern CNPb may connect the second light-emitting element LEDb and the second pixel driving circuit part PCb, and the third connection electrode CEc and the third connection pattern CNPc may connect the third light-emitting element LEDc to the third pixel driving circuit part PCc.

The first to third connection electrodes CEa, CEb, and CEc may include a conductive material such as a metal, alloy, conductive metal oxide, conductive metal nitride, transparent conductive oxide, and the like. Examples of the conductive material that can be used for the first to third connection electrodes CEa, CEb, and CEc may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloys containing aluminum (Al), alloys containing silver (Ag), alloys containing copper (Cu), alloys containing molybdenum (Mo), aluminum nitride (AlN), tungsten nitride (WN), titanium nitride (TiN), chromium nitride (CrN), tantalum nitride (TaN), tin oxide (SnO), gallium oxide (GaO), indium gallium zinc oxide (IGZO), indium tin zinc oxide (ITZO), indium tin oxide (ITO), indium zinc oxide (IZO), indium gallium oxide (IGO), zinc oxide (ZnO), indium oxide (InO), aluminum zinc oxide (AZO), and the like. These can be used alone or in combination with each other. In an embodiment, the first to third connection electrodes CEa, CEb, and CEc may have a single-layer structure or a multi-layer structure in which a plurality of conductive layers are stacked.

In an embodiment, the first to third connection patterns CNPa, CNPb, and CNPc may include transparent conductive oxide. Examples of the transparent conductive oxide that can be used as the first to third connection patterns CNPa, CNPb, and CNPc may include indium gallium zinc oxide (IGZO), indium tin zinc oxide (ITZO), indium tin oxide (ITO), indium zinc oxide (IZO), indium gallium oxide (IGO), zinc oxide (ZnO), indium oxide (InO), tin oxide (SnO), gallium oxide (GaO), aluminum zinc oxide (AZO), and the like. These can be used alone or in combination with each other.

However, the present disclosure is not necessarily limited thereto, and the first to third connection patterns CNPa, CNPb, and CNPc may include a conductive material such as a metal, alloy, conductive metal nitride, and the like. Examples of the conductive material that can be used for the first to third connection patterns CNPa, CNPb, and CNPc may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloys containing aluminum (Al), alloys containing silver (Ag), alloys containing copper (Cu), alloys containing molybdenum (Mo), aluminum nitride (AlN), tungsten nitride (WN), titanium nitride (TiN), chromium nitride (CrN), tantalum nitride (TaN), and the like. These can be used alone or in combination with each other.

In an embodiment, the first to third connection patterns CNPa, CNPb, and CNPc may have a single-layer structure or a multi-layer structure in which a plurality of conductive layers are stacked.

The first connection electrode CEa may include a first circuit connection portion CPa and a first light-emitting connection portion CNa.

The first circuit connection portion CPa may be a portion of the first connection electrode CEa connected to the first pixel driving circuit part PCa. Specifically, the first circuit connection portion CPa may be a portion of the first connection electrode CEa connected to the first transistor TR1 (see FIG. 5) of the first pixel driving circuit part PCa. Accordingly, the position of the first circuit connection part CPa may correspond to the position of the first transistor TR1 of the first pixel driving circuit part PCa. Specifically, the position of the first circuit connection part CPa may correspond to the position of a contact hole that extends through an insulating layer (fifth insulating layer IL5 of FIG. 5) to allow the first connection electrode CEa to contact the first transistor TR1 of the first pixel driving circuit part PCa.

The first light-emitting connection portion CNa may be a portion of the first connection electrode CEa connected to the first connection pattern CNPa. Specifically, the first light-emitting connection portion CNa may be a portion of the first connection electrode CEa exposed from a sixth insulating layer IL6 (see FIG. 5) and the pixel defining layer PDL (see FIG. 5) to be connected to the first connection pattern CNPa. Accordingly, the position of the first light-emitting connection portion CNa may correspond to the position of an opening in the sixth insulating layer IL6 that is aligned with an opening in the pixel defining layer PDL. In a plan view, the first light-emitting connection portion CNa may not overlap the first light-emitting area EAa. For example, in plan view, the first light-emitting connection portion CNa may be disposed between the first light-emitting area EAa and the separator SPR (e.g., see FIG. 4).

The first connection pattern CNPa may be connected to the first connection electrode CEa. For example, the first connection pattern CNPa may contact the first light-emitting connection portion CNa of the first connection electrode CEa. However, the present disclosure is not necessarily limited to this exact structure, and the first connection pattern CNPa may not directly contact the first connection electrode CEa. For example, the first connection pattern CNPa may contact a capping layer which contacts the first light-emitting connection portion CNa of the first connection electrode CEa, and may be connected to the first light-emitting connection portion CNa of the first connection electrode CEa through the capping layer. The capping layer may include a conductive material. For example, the capping layer may be formed simultaneously with the first electrode layer E1 (see FIG. 5), which will be described later, and may include the same material.

The first connection pattern CNPa may not overlap the first light-emitting area EAa in plan view. In an embodiment, the first connection pattern CNPa may surround at least a portion of the first light-emitting area EAa in plan view. For example, the first connection pattern CNPa may have a closed ring shape entirely surrounding the first light-emitting area EAa in plan view. However, the present disclosure is not necessarily limited thereto.

The second electrode E2a of the first light-emitting element LEDa may be connected to the first connection pattern CNPa. Specifically, the second electrode E2a of the first light-emitting element LEDa may contact the first connection pattern CNPa. Accordingly, the first connection pattern CNPa may connect the first connection electrode CEa and the second electrode E2a of the first light-emitting element LEDa. As a result, the second electrode E2a of the first light-emitting element LEDa may be connected to the first pixel driving circuit part PCa through the first connection electrode CEa and the first connection pattern CNPa.

In an embodiment, the planar profile of an area where the second electrode E2a of the first light-emitting element LEDa and the first connection pattern CNPa are in contact may be substantially the same as or similar to the planar profile of the edge of the first connection pattern CNPa. For example, if the first connection pattern CNPa has a closed shape entirely surrounding the first light-emitting area EAa in plan view, the area where the second electrode E2a of the first light-emitting element LEDa and the first connection pattern CNPa are in contact may have a closed shape in plan view. That is, the second electrode E2a of the first light-emitting element LEDa and the first connection pattern CNPa may contact each other at a position that does not overlap the first light-emitting area EAa. Therefore, without reducing the light-emitting area of the first light-emitting area EAa, the second electrode E2a of the first light-emitting element LEDa and the first pixel driving circuit part PCa may be connected through the first connection pattern CNPa and the first connection electrode CEa. The second connection electrode CEb may include a second circuit connection portion CPb and a second light-emitting connection portion CNb.

The second circuit connection portion CPb may be a portion of the second connection electrode CEb connected to the second pixel driving circuit part PCb. Specifically, the second circuit connection portion CPb may be a portion of the second connection electrode CEb connected to the first transistor TR1 (see FIG. 5) of the second pixel driving circuit part PCb. Accordingly, the position of the second circuit connection portion CPb may correspond to the position of the first transistor TR1 of the second pixel driving circuit part PCb. Specifically, the position of the second circuit connection portion CPb may correspond to the position of a contact hole that extends through an insulating layer (fifth insulating layer IL5 of FIG. 5) for the second connection electrode CEb to contact the first transistor TR1 of the second pixel driving circuit part PCb.

The second light-emitting connection portion CNb may be a portion of the second connection electrode CEb connected to the second connection pattern CNPb. Specifically, the second light-emitting connection portion CNb may be a portion of the second connection electrode CEb exposed from a sixth insulating layer IL6 (see FIG. 5) and the pixel defining layer PDL (see FIG. 5) to be connected to the second connection pattern CNPb. Accordingly, the position of the second light-emitting connection portion CNb may correspond to the position of an opening in the sixth insulating layer IL6 that is aligned with an opening in the pixel defining layer PDL. In plan view, the second light-emitting connection portion CNb may not overlap the second light-emitting area EAb. For example, in plan view, the second light-emitting connection portion CNb may be disposed between the second light-emitting area EAb and the separator SPR.

In an embodiment, the second connection electrode CEb may be spaced apart from the first connection electrode CEa in plan view. In other words, the first connection electrode CEa and the second connection electrode CEb may be distinct electrodes.

The second connection pattern CNPb may be connected to the second connection electrode CEb. For example, the second connection pattern CNPb may contact the second light-emitting connection portion CNb of the second connection electrode CEb. However, the present disclosure is not necessarily limited to this exact structure, and the second connection pattern CNPb may not directly contact the second connection electrode CEb. For example, the second connection pattern CNPb may contact a capping layer which contacts the second light-emitting connection portion CNb of the second connection electrode CEb, and may be connected to the second light-emitting connection portion CNb of the second connection electrode CEb through the capping layer. The capping layer may include a conductive material. For example, the capping layer may be formed simultaneously with the first electrode layer E1 (see FIG. 5), which will be described later, and may include the same material.

The second connection pattern CNPb may not overlap the second light-emitting area EAb in plan view. In an embodiment, the second connection pattern CNPb may surround at least a portion of the second light-emitting area EAb in plan view. For example, the second connection pattern CNPb may have a closed ring shape entirely surrounding the second light-emitting area EAb in plan view. However, the present disclosure is not necessarily limited thereto.

In an embodiment, the second connection pattern CNPb may be spaced apart from the first connection pattern CNPa. In other words, the first connection pattern CNPa and the second connection pattern CNPb may be distinct patterns.

The second electrode E2b of the second light-emitting element LEDb may be connected to the second connection pattern CNPb. Specifically, the second electrode E2b of the second light-emitting element LEDb may contact the second connection pattern CNPb.

Accordingly, the second connection pattern CNPb may connect the second connection electrode CEb and the second electrode E2b of the second light-emitting element LEDb. As a result, the second electrode E2b of the second light-emitting element LEDb may be connected to the second pixel driving circuit part PCb through the second connection electrode CEb and the second connection pattern CNPb.

In an embodiment, the planar profile of an area where the second electrode E2b of the second light-emitting element LEDb and the second connection pattern CNPb are in contact may be substantially the same as or similar to the planar profile of the edge of the second connection pattern CNPb. For example, if the second connection pattern CNPb has a closed shape entirely surrounding the second light-emitting area EAb in plan view, the area where the second electrode E2b of the second light-emitting element LEDb and the second connection pattern CNPb are in contact may have a closed shape in plan view. That is, the second electrode E2b of the second light-emitting element LEDb and the second connection pattern CNPb may contact each other at a position that does not overlap the second light-emitting area EAb. Therefore, without reducing the light-emitting area of the second light-emitting area EAb, the second electrode E2b of the second light-emitting element LEDb and the second pixel driving circuit part PCb may be connected through the second connection pattern CNPb and the second connection electrode CEb.

The third connection electrode CEc may include a third circuit connection portion CPc and a third light-emitting connection portion CNc.

The third circuit connection portion CPc may be a portion of the third connection electrode CEc connected to the third pixel driving circuit part PCc. Specifically, the third circuit connection portion CPc may be a portion of the third connection electrode CEc connected to the first transistor TR1 (see FIG. 5) of the third pixel driving circuit part PCc. Accordingly, the position of the third circuit connection portion CPc may correspond to the position of the first transistor TR1 of the third pixel driving circuit part PCc. Specifically, the position of the third circuit connection portion CPc may correspond to the position of a contact hole that extends through an insulating layer (fifth insulating layer IL5 of FIG. 5) to allow the third connection electrode CEc to contact the first transistor TR1 of the third pixel driving circuit part PCc.

The third light-emitting connection portion CNc may be a portion of the third connection electrode CEc connected to the third connection pattern CNPc. Specifically, the third light-emitting connection portion CNc may be a portion of the third connection electrode CEc exposed from a sixth insulating layer IL6 (see FIG. 5) and the pixel defining layer PDL (see FIG. 5) to be connected to the third connection pattern CNPc. Accordingly, the position of the third light-emitting connection portion CNc may correspond to the position of an opening in the sixth insulating layer IL6 that is aligned with an opening in the pixel defining layer PDL. In plan view, the third light-emitting connection portion CNc may not overlap the third light-emitting area EAc. For example, in plan view, the third light-emitting connection portion CNc may be disposed between the third light-emitting area EAc and the separator SPR.

In an embodiment, the third connection electrode CEc may be spaced apart from the first connection electrode CEa and the second connection electrode CEb in plan view. In other words, the first connection electrode CEa, the second connection electrode CEb, and the third connection electrode CEc may be different electrodes.

The third connection pattern CNPc may be connected to the third connection electrode CEc. For example, the third connection pattern CNPc may contact the third light-emitting connection portion CNc of the third connection electrode CEc. However, the present disclosure is not necessarily limited to this exact structure, and the third connection pattern CNPc may not directly contact the third connection electrode CEc. For example, the third connection pattern CNPc may contact a capping layer which contacts the third light-emitting connection portion CNc of the third connection electrode CEc, and may be connected to the third light-emitting connection portion CNc of the third connection electrode CEc through the capping layer. The capping layer may include a conductive material. For example, the capping layer may be formed simultaneously with the first electrode layer E1 (see FIG. 5), which will be described later, and may include the same material.

The third connection pattern CNPc may not overlap the third light-emitting area EAc in plan view. In an embodiment, the third connection pattern CNPc may surround at least a portion of the third light-emitting area EAc in plan view. For example, the third connection pattern CNPc may have a closed shape entirely surrounding the third light-emitting area EAc in plan view. However, the present disclosure is not necessarily limited thereto.

In an embodiment, the third connection pattern CNPc may be spaced apart from the first connection pattern CNPa and the second connection pattern CNPb. In other words, the first connection pattern CNPa, the second connection pattern CNPb, and the third connection pattern CNPc may be distinct patterns.

The second electrode E2c of the third light-emitting element LEDc may be connected to the third connection pattern CNPc. Specifically, the second electrode E2c of the third light-emitting element LEDc may contact the third connection pattern CNPc. Accordingly, the third connection pattern CNPc may connect the third connection electrode CEc and the second electrode E2c of the third light-emitting element LEDc. As a result, the second electrode E2c of the third light-emitting element LEDc may be connected to the third pixel driving circuit part PCc through the third connection electrode CEc and the third connection pattern CNPc.

In an embodiment, the planar profile of an area where the second electrode E2c of the third light-emitting element LEDc and the third connection pattern CNPc are in contact may be substantially the same as or similar to the planar profile of the edge of the third connection pattern CNPc. For example, if the third connection pattern CNPc has a closed shape entirely surrounding the third light-emitting area EAc in plan view, the area where the second electrode E2c of the third light-emitting element LEDc and the third connection pattern CNPc are in contact may have a closed shape in plan view. That is, the second electrode E2c of the third light-emitting element LEDc and the third connection pattern CNPc may contact each other at a position that does not overlap the third light-emitting area EAc. Therefore, without reducing the light-emitting area of the third light-emitting area EAc, the second electrode E2c of the third light-emitting element LEDc and the third pixel driving circuit part PCc may be connected through the third connection pattern CNPc and the third connection electrode CEc.

According to an embodiment of the present disclosure, the second electrodes E2a, E2b, and E2c may be connected respectively the first to third connection patterns CNPa, CNPb, and CNPc at positions that do not overlap the first to third light-emitting areas EAa, EAb, and EAc. Accordingly, the second electrodes E2a, E2b, and E2c may contact the first to third connection patterns CNPa, CNPb, and CNPc without reducing the light-emitting area.

In addition, according to an embodiment of the present disclosure, the second electrodes E2a, E2b, and E2c may be respectively connected to the first to third pixel driving circuit parts PCa, PCb, and PCc through the first to third connection electrodes CEa, CEb, and CEc and the first to third connection patterns CNPa, CNPb, and CNPc. Accordingly, restrictions due to the position, shape, and size of the first to third light-emitting areas EAa, EAb, and EAc may be reduced in the design of the first to third pixel driving circuit parts PCa, PCb, and PCc. For example, even if at least some of the first to third circuit connections CPa, CPb, and CPc overlap the first to third light-emitting areas EAa, EAb, EAc, the second electrodes E2a, E2b, and E2c may be easily connected to the first to third pixel driving circuit parts PCa, PCb, and PCc through the first to third connection electrodes CEa, CEb, and CEc and the first to third connection patterns CNPa, CNPb, and CNPc. Therefore, the shape and arrangement of the first to third pixel driving circuit part PCa, PCb, and PCc may be designed independently from the position, shape, and size of the first to third light-emitting areas EAa, EAb, and EAc. Accordingly, the degree of freedom in designing the first to third pixel driving circuit unit parts PCa, PCb, and PCc may be higher.

In an embodiment, the first to third pixel driving circuit unit parts PCa, PCb, and PCc may be designed to be same as each other regardless of the position, shape, size, and the like of the first to third light-emitting areas EAa, EAb, and EAc. In addition, as described above, the position of the first circuit connection portion CPa may correspond to the position of the first transistor TR1 (see FIG. 5) of the first pixel driving circuit portion PCa, the second circuit connection portion CPb may correspond to the position of the first transistor TR1 of the second pixel driving circuit part PCb, and the position of the third circuit connection portion CPc may correspond to the position of the first transistor TR1 of the third pixel driving circuit portion PCc. Therefore, if the first to third pixel driving circuit parts PCa, PCb, and PCc are formed to have substantially the same size and are disposed along the first direction DR1, the position of the first circuit connection portion CPa, the position of the second circuit connection portion CPb, and the position of the third circuit connection portion CPc may be disposed along the first direction DR1.

Meanwhile, as shown in FIG. 3, the shape or arrangement of each of the first to third connection electrodes CEa, CEb, and CEc and the positions of the first to third connection electrodes CEa, CEb, and CEc relative to one another may be the same for each first unit light-emitting area UEA1. In addition, the shape or arrangement of each of the first to third connection electrodes CEa, CEb, and CEc and the positions of the first to third connection electrodes CEa, CEb, and CEc relative to one another may be the same for each second unit light-emitting area UEA2.

As described above, the display device DD may include the separator SPR.

The separator SPR may be disposed on the pixel defining layer PDL (see FIG. 5) and the first to third connection patterns CNPa, CNPb, and CNPc. In an embodiment, the separator SPR may include an organic insulating material. For example, the separator SPR may include a photosensitive resin (e.g., photoresist). However, the present disclosure is not necessarily limited thereto.

The separator SPR may overlap the first to third connection patterns CNPa, CNPb, and CNPc in plan view. Specifically, the separator SPR may cover a portion of the first to third connection patterns CNPa, CNPb, and CNPc and adjacent connection patterns. That is, at least a portion of the separator SPR may extend along the edges of the first to third connection patterns CNPa, CNPb, and CNPc in plan view. Accordingly, areas where the second electrodes E2a, E2b, and E2c and the first to third connection patterns CNPa, CNPb, and CNPc contact each other may be adjacent to or overlap the separator SPR in plan view.

The second electrode layer E2 may be separated (or disconnected) into the second electrodes E2a, E2b, and E2c by the separator SPR. That is, the second electrode E2a of the first light-emitting element LEDa, the second electrode E2b of the second light-emitting element LEDb, the second electrode E2c of the third light-emitting element LEDc may be electrically independent from each other by the separator SPR.

The separator SPR may define first to third open areas OA1, OA2, and OA3 respectively corresponding to the second electrodes E2a, E2b, and E2c. For example, the separator SPR may have a mesh structure surrounding the second electrodes E2a, E2b, and E2c in plan view. The second electrode E2a of the first light-emitting element LEDa may be disposed in the first open area OA1 of the separator SPR, the second electrode E2b of the second light-emitting element LEDb may be disposed in the second open area OA2 of the separator SPR, and the second electrode E2c of the third light-emitting element LEDc may be disposed in the third open area OA3 of the separator SPR.

In an embodiment, the outline of the first open area OA1 may be substantially the same shape as the outline of the second electrode E2a of the first light-emitting element LEDa in plan view, the outline of the second open area OA2 may be substantially the same as the outline of the second electrode E2b of the second light-emitting element LEDb in plan view, and the outline of the third open area OA3 may be substantially the same as the outline of the second electrode E2c of the third light-emitting element LEDc in plan view.

The first to third open areas OA1, OA2, and OA3 of the separator SPR may respectively correspond to the first to third connection patterns CNPa, CNPb, and CNPc. For example, the first connection pattern CNPa may overlap the first open area OA1, the second connection pattern CNPb may overlap the second open area OA2, and the third connection pattern CNPc may overlap the third open area OA3.

Hereinafter, the cross-sectional structure of the display device DD will be described in more detail with reference to FIG. 5 based on the first light-emitting area EAa. The following description of the cross-sectional structure of the display device DD may be applied to all light-emitting areas.

Referring further to FIG. 5, in an embodiment, the display device DD may include a substrate SUB, a first lower conductive layer BML1, a second lower conductive layer BML2, the first transistor TR1, the second transistor TR2, the first capacitor CAP1, the second capacitor CAP2, the first connection electrode CEa, first to sixth insulating layers IL1, IL2, IL3, IL4, IL5, and IL6, the pixel defining layer PDL, the first connection pattern CNPa, the first light-emitting element LEDa, the separator SPR, a first dummy layer DP1, a second dummy layer DP2, and an encapsulation layer ENC.

The first transistor TR1 may include a first active pattern AP1, a first gate electrode GE1, a first contact electrode SE1, and a second contact electrode DE1. The second transistor TR2 may include a second active pattern AP2, a second gate electrode GE2, a third contact electrode SE2, and a fourth contact electrode DE2. The first capacitor CAP1 may include a first capacitor electrode CPE1 and a second capacitor electrode CPE2. The second capacitor CAP2 may include the first capacitor electrode CPE1 and a third capacitor electrode CPE3. The first light-emitting element LEDa may include the first electrode E1a, the intermediate layer ML, and the second electrode E2a.

As described above, the first transistor TR1, the second transistor TR2, the first capacitor CAP1, and the second capacitor CAP2 may be components included in the first pixel driving circuit part PCa.

The substrate SUB may form the basis of the display device DD. In an embodiment, examples of materials that can be used as a substrate SUB may include glass, quartz, silicon, polymer, or the like. These can be used alone or in combination with each other. In addition, the substrate SUB may have a single-layer structure or a multi-layer structure in which a plurality of layers containing different materials are stacked.

The first lower conductive layer BML1, the second lower conductive layer BML2, and the third capacitor electrode CPE3 may be disposed on the substrate SUB. The first lower conductive layer BML1, the second lower conductive layer BML2, and the third capacitor electrode CPE3 may include a conductive material such as a metal, alloy, conductive metal oxide, conductive metal nitride, transparent conductive oxide, and the like.

The first insulating layer IL1 may cover the first lower conductive layer BML1, the second lower conductive layer BML2, and the third capacitor electrode CPE3 and may be disposed on the substrate SUB. The first insulating layer IL1 may prevent metal atoms or impurities from diffusing from the substrate SUB into the first active pattern AP1 and/or the second active pattern AP2. The first insulating layer IL1 may include an insulating material. Examples of the insulating material that can be used as the first insulating layer IL1 may include silicon oxide, silicon nitride, silicon nitride, and the like. These can be used alone or in combination with each other.

The first active pattern AP1 may be disposed on the first insulating layer IL1. In an embodiment, the first active pattern AP1 may overlap the first lower conductive layer BML1. The first active pattern AP1 may include an oxide semiconductor material, a silicon semiconductor material, and/or an organic semiconductor material. The first active pattern AP1 may include a first contact region S1, a second contact region D1, and a first channel region CH1 between the first contact region S1 and the second contact region D1. The first contact region S1 and the second contact region D1 may have higher conductivity than the first channel region CH1.

The second active pattern AP2 may be disposed on the first insulating layer IL1. In an embodiment, the second active pattern AP2 may overlap the second lower conductive layer BML2. The second active pattern AP2 may include an oxide semiconductor material, a silicon semiconductor material, and/or an organic semiconductor material. The second active pattern AP2 may include a third contact region S2, a fourth contact region D2, and a second channel region CH2 between the third contact region S2 and the fourth contact region D2. The third contact region S2 and the fourth contact region D2 may have higher conductivity than the second channel region CH2.

In an embodiment, the first active pattern AP1 and the second active pattern AP2 may include an oxide semiconductor material. Examples of the oxide semiconductor material that can be used as the first active pattern AP1 and the second active pattern AP2 may include indium gallium zinc oxide (IGZO), zinc tin oxide (ZTO), indium tin zinc oxide (ITZO), and the like. There may be this. These can be used alone or in combination with each other. However, the present disclosure is not necessarily limited thereto, and the first active pattern AP1 and the second active pattern AP2 may include different materials.

Meanwhile, in FIG. 5, the first active pattern AP1 and the second active pattern AP2 are shown as being disposed in the same layer. However, the present disclosure is not necessarily limited to this, and the first active pattern AP1 and the second active pattern AP2 may be disposed in different layers.

The second insulating layer IL2 may cover the first active pattern AP1 and the second active pattern AP2, and may be disposed on the first insulating layer IL1. The second insulating layer ILD2 may include an insulating material. Examples of the insulating material that can be used as the second insulating layer IL2 may include silicon oxide, silicon nitride, silicon nitride, and the like. These can be used alone or in combination with each other.

The first gate electrode GE1 may be disposed on the second insulating layer IL2. The first gate electrode GE1 may overlap the first channel region CH1 of the first active pattern AP1. The first gate electrode GE1 may include a conductive material such as a metal, alloy, conductive metal oxide, conductive metal nitride, transparent conductive oxide, and the like. Although not shown, in an embodiment, the first gate electrode GE1 may contact the first lower conductive layer BML1.

The second gate electrode GE2 may be disposed on the second insulating layer IL2. The second gate electrode GE2 may overlap the second channel region CH2 of the second active pattern AP2. The second gate electrode GE2 may include a conductive material such as a metal, alloy, conductive metal oxide, conductive metal nitride, transparent conductive oxide, and the like. Although not shown, in an embodiment, the second gate electrode GE2 may contact the second lower conductive layer BML2.

The first capacitor electrode CPE1 may be disposed on the second insulating layer IL2. The first capacitor electrode CPE1 may overlap the third capacitor electrode CPE3. The first capacitor electrode CPE1 and the third capacitor electrode CPE3 may form a second capacitor CAP2. The first capacitor electrode CPE1 may include a conductive material such as a metal, alloy, conductive metal oxide, conductive metal nitride, transparent conductive oxide, and the like.

The third insulating layer IL3 may cover the first gate electrode GE1, the second gate electrode GE2, and the first capacitor electrode CPE1 and may be disposed on the second insulating layer IL2. The third insulating layer IL3 may include an insulating material. Examples of the insulating material that can be used as the third insulating layer IL3 may include silicon oxide, silicon nitride, silicon nitride, and the like. These can be used alone or in combination with each other.

The second capacitor electrode CPE2 may be disposed on the third insulating layer IL3. The second capacitor electrode CPE2 may overlap the first capacitor electrode CPE1. The first capacitor electrode CPE1 and the second capacitor electrode CPE2 may form the first capacitor CAP1. The second capacitor electrode CPE2 may include a conductive material such as a metal, alloy, conductive metal oxide, conductive metal nitride, transparent conductive oxide, and the like.

The fourth insulating layer IL4 may cover the second capacitor electrode CPE2 and may be disposed on the third insulating layer IL3. The fourth insulating layer IL4 may include an insulating material. Examples of the insulating material that can be used as the fourth insulating layer IL4 may include silicon oxide, silicon nitride, silicon nitride, and the like. These can be used alone or in combination with each other.

The first to fourth contact electrodes SE1, DE1, SE2, and DE2 may be disposed on the fourth insulating layer IL4. The first contact electrode SE1 may contact the first contact region S1 of the first active pattern AP1, the second contact electrode DE1 may contact the second contact region D1 of the first active pattern AP1, the third contact electrode SE2 may contact the third contact region S2 of the second active pattern AP2, and the fourth contact electrode DE2 may contact the fourth contact region D2 of the second active pattern AP2. The first to fourth contact electrodes SE1, DE1, SE2, and DE2 may include a conductive material such as metal, alloy, conductive metal oxide, conductive metal nitride, transparent conductive oxide, and the like.

In an embodiment, the first contact electrode SE1 may contact the first lower conductive layer BML1, and the third contact electrode SE2 may contact the second lower conductive layer BML2. However, the present disclosure is not necessarily limited thereto. For example, if the first gate electrode GE1 contacts the first lower conductive layer BML1, the first contact electrode SE1 may not contact the first lower conductive layer BML1. In addition, if the second gate electrode GE2 contacts the second lower conductive layer BML2, the third contact electrode SE2 may not contact the second lower conductive layer BML2.

The fifth insulating layer IL5 may cover the first to fourth contact electrodes SE1, DE1, SE2, and DE2 and may be disposed on the fourth insulating layer IL4. The fifth insulating layer IL5 may include an insulating material. For example, the fifth insulating layer IL5 may include an organic insulating material. Examples of the organic insulating material that can be used as the fifth insulating layer IL5 may include photoresist, polyacryl-based resin, polyimide-based resin, polyamide-based resin, siloxane-based resin, acryl-based resin, epoxy-based resin, and the like. These can be used alone or in combination with each other.

The first connection electrode CEa may be disposed on the fifth insulating layer IL5. As described above, the first connection electrode CEa may be connected to the first transistor TR1. Specifically, the first connection electrode CEa may contact the first transistor TR1 through a contact hole CNT extending through the fifth insulating layer IL5. Accordingly, the position of the first circuit connection portion CPa may correspond to the position of the contact hole CNT. The first connection electrode CEa may include a conductive material such as a metal, alloy, conductive metal oxide, conductive metal nitride, transparent conductive oxide, and the like. In an embodiment, the first connection electrode CEa may have a single-layer structure or a multi-layer structure in which a plurality of conductive layers are stacked.

As described above, the first transistor TR1 may be a transistor connected to the light-emitting element through a connection electrode and a connection pattern. For example, if the first pixel driving circuit part PCa is the pixel driving circuit part PC of FIG. 2A, the first transistor TR1 may be the first transistor T1 of FIG. 2A. In addition, if the first pixel driving circuit part PCa is the pixel driving circuit part PC′ of FIG. 2B, the first transistor TR1 may be the fifth transistor T5 of FIG. 2B. In addition, if the first pixel driving circuit part PCa is the pixel driving circuit part PC″ of FIG. 2C, the first transistor TR1 may be the fifth transistor T5 of FIG. 2C.

The sixth insulating layer IL6 may partially cover the first connection electrode CEa and may be disposed on the fifth insulating layer IL5. That is, the sixth insulating layer IL6 may define a first sub-opening SO1 above at least a portion of the first connection electrode CEa. The sixth insulating layer IL6 may include an insulating material. For example, the sixth insulating layer IL6 may include an organic insulating material. Examples of the organic insulating material that can be used as the sixth insulating layer IL6 may include photoresist, polyacryl-based resin, polyimide-based resin, polyamide-based resin, siloxane-based resin, acryl-based resin, epoxy-based resin, and the like. These can be used alone or in combination with each other.

The first electrode layer E1 may be disposed on the sixth insulating layer IL6. As described above, the first electrode layer E1 may include the first electrode E1a of the first light-emitting element LEDa. That is, the first electrode E1a may be disposed on the sixth insulating layer IL6. The first electrode layer E1 (i.e., the first electrode E1a) may include a conductive material such as a metal, alloy, conductive metal oxide, conductive metal nitride, transparent conductive oxide, and the like. The structure of the first electrode layer E1 will be described in more detail later.

The pixel defining layer PDL may be disposed on the sixth insulating layer IL6 and the first electrode layer E1 (i.e., the first electrode E1a). The pixel defining layer PDL may be formed of an insulating material. The pixel defining layer PDL may define a pixel opening exposing at least a portion of the first electrode layer (E1) (i.e., the first electrode E1a). The first light-emitting area EAa may be defined by the pixel opening. Meanwhile, the pixel defining layer PDL may further define a second sub-opening SO2 that is aligned with the first sub-opening SO1 of the sixth insulating layer IL6. The second sub-opening SO2 may be above the first sub-opening SO1 such that the first sub-opening SO1 and the second sub-opening SO2 may form a continuous, deeper opening by being connected to each other. That is, an opening OP in which the first sub-opening SO1 and the second sub-opening SO2 are connected may be defined, and at least a portion of the first connection electrode Cea is at the base of the opening.

The first connection pattern CNPa may be disposed on the first connection electrode CEa, the sixth insulating layer IL6, and the pixel defining layer PDL. As described above, the first connection pattern CNPa may be connected to the first connection electrode CEa. Specifically, the first connection pattern CNPa may be connected to the first connection electrode CEa through the opening OP extending through the sixth insulating layer IL6 and the pixel defining layer PDL. Accordingly, the position of the first light emitting connection part CNa may correspond to the position of the opening OP. In an embodiment, the first connection pattern CNPa may include transparent conductive oxide. However, the present disclosure is not necessarily limited thereto, and the first connection pattern CNPa may include a conductive material such as metal, alloy, conductive metal oxide, conductive metal nitride, and the like. In an embodiment, the first connection pattern CNPa may have a single-layer structure or a multi-layer structure in which a plurality of conductive layers are stacked.

The separator SPR may be disposed on the pixel defining layer PDL and the first connection pattern CNPa. The separator SPR may overlap the first connection pattern CNPa in plan view. For example, the separator SPR may cover a portion of the first connection pattern CNPa.

The separator SPR may have a cross-sectional shape where a width of an upper portion is larger than a width of a lower portion. That is, a side surface of the separator SPR connecting an upper surface of the separator SPR and a lower surface of the separator SPR may have a tapered or inclined surface. That is, a cross-section of at least a portion of the separator SPR may be trapezoidal.

In an embodiment, as shown in FIG. 5, the side surface of the separator SPR may have a plurality of inclined surfaces. That is, the separator SPR may have a tapered structure. Accordingly, separation (or disconnection) of the second electrode layer E2 by the separator SPR may be more easily implemented.

The intermediate layer ML may be disposed on the first electrode layer E1, the pixel defining layer PDL, and the first connection pattern CNPa. A portion of the intermediate layer ML may be disposed within the pixel opening of the pixel defining layer PDL. In an embodiment, the intermediate layer ML may include a first functional layer including an organic material, a light-emitting layer disposed on the first functional layer and including a light-emitting material, and a second functional layer on the light-emitting layer and including an organic material. For example, the first functional layer may include a hole injection layer, a hole transport layer, and the like and the second functional layer may include an electron transport layer, an electron injection layer, and the like.

The shadow area where it is difficult to deposit the intermediate layer ML may exist around the separator SPR having an inclined side surface. Accordingly, the intermediate layer ML in the shadow area and/or around the shadow area may have a structure that is disconnected by the separator SPR. For example, the first and second functional layers included in the intermediate layer ML may have a structure that is disconnected to accommodate the separator SPR. As the intermediate layer ML has the disconnected structure, the intermediate layer ML may not cover the entire first connection pattern CNPa. That is, the intermediate layer ML may expose a portion of the first connection pattern CNPa at a position adjacent to or overlapping the separator SPR. Accordingly, the second electrode E2a of the first light-emitting element LEDa may contact the first connection pattern CNPa.

Meanwhile, the first dummy layer DP1 may be disposed on the separator SPR. The first dummy layer DP1 may be formed by having a structure in which the intermediate layer ML is disconnected by the separator SPR. That is, the first dummy layer DP1 may be formed in the same process as the intermediate layer ML. In an embodiment, the first dummy layer DP1 may be omitted.

The second electrode layer E2 (i.e., the second electrodes E2a, E2b, and E2c) may be disposed on the intermediate layer ML. The second electrode layer E2 (i.e., the second electrodes E2a, E2b, and E2c) may include a conductive material such as a metal, alloy, conductive metal oxide, conductive metal nitride, transparent conductive oxide, and the like. In an embodiment, the second electrode layer E2 (i.e., the second electrodes E2a, E2b, and E2c) may have a single-layer structure. However, the present disclosure is not necessarily limited to this, and the second electrode layer E2 (i.e., the second electrodes E2a, E2b, and E2c) may have a multilayer structure in which a plurality of conductive layers are stacked. For example, the second electrode layer E2 (i.e., the second electrodes E2a, E2b, and E2c) may have a two-layer structure in which a first sub-electrode layer including a metal material and a second sub-electrode layer including a transparent conductive oxide disposed on the first sub-electrode layer are stacked.

There is a shadow area around the separator SPR where it is difficult to deposit the second electrode layer E2 due to the separator SPR having a tapered, inclined side surface. Accordingly, the second electrode layer E2 in the shadow area and/or around the shadow area may be discontinuous around the separator SPR. For example, as shown in FIG. 4, the second electrode layer E2 may be separated into the second electrode E2a of the first light-emitting element LEDa disposed in the first open area OA1 of the separator SPR, the second electrode E2b of the second light-emitting element LEDb disposed in the second open area OA2 of the separator SPR, and the second electrode E2c of the third light-emitting element LEDc disposed in the third open area OA3 of the separator SPR. That is, the second electrodes E2a, E2b, and E2c may be electrically independent from each other.

As shown in FIG. 5, the second electrode E2a of the first light-emitting element LEDa may be connected to the first connection pattern CNPa. Specifically, the second electrode E2a may contact the first connection pattern CNPa at a position adjacent to or overlapping the separator SPR. For example, if a deposition angle of the deposition process for forming the second electrode layer E2 is set to be larger than a deposition angle for the deposition process for forming the intermediate layer ML, the second electrode layer E2 (specifically, the second electrode E2a) may be formed to cover the side surface of the disconnected intermediate layer ML and contact the first connection pattern CNPa. As a result, the second electrode E2a may be connected to the first transistor TR1 through the first connection electrode CEa and the first connection pattern CNPa.

Meanwhile, the second dummy layer DP2 may be disposed on the separator SPR. Specifically, the second dummy layer DP2 may be disposed on the first dummy layer DP1. The second dummy layer DP2 may be formed by having a structure in which the second electrode layer E2 is separated (or disconnected) by the separator SPR. That is, the second dummy layer DP2 may be formed in the same process as the second electrode layer E2. In an embodiment, the second dummy layer DP2 may be omitted.

The encapsulation layer ENC may be disposed on the second electrode layer E2. The encapsulation layer ENC may entirely cover the second electrode layer E2, the connection patterns CNPa, CNPb, and CNPc, the separator SPR, the first dummy layer DP1, and the second dummy layer DP2. In an embodiment, the encapsulation layer ENC may include a first inorganic encapsulation layer IEL1 including an inorganic insulating material, an organic encapsulating layer OEL disposed on the first inorganic encapsulating layer IEL1 and including an organic insulating material, and a second inorganic encapsulation layer IEL2 disposed on the organic encapsulation layer OEL and including an inorganic insulating material.

Although not shown, in an embodiment, a touch sensing layer may be disposed on the encapsulation layer ENC. For example, the touch sensing layer may include a plurality of touch electrode arrays for detecting user processing in a capacitive manner, a touch pad part, and a plurality of touch lines electrically connecting the touch pad art and the touch electrode arrays. However, the present disclosure is not necessarily limited thereto. Meanwhile, in an embodiment, the touch sensing layer may be omitted.

According to an embodiment of the present disclosure, the display device DD may include the connection electrodes CEa, CEb, and CEc, the connection patterns CNPa, CNPb, and CNPc, and the separator SPR. Accordingly, the second electrode layer E2 (e.g., the cathode) disposed on the first electrode layer E1 (e.g., the anode) may be easily connected to the pixel driving circuit parts PCa, PCb, and PCc. The second electrode layer E2 disposed on the first electrode layer E1 may be connected to a drain of a driving transistor (e.g., the first transistors T1 (or T1′) of FIGS. 2A to 2C) of the pixel driving circuit parts PCa, PCb, and PCc through the connection electrodes CEa, CEb, and CEc and the connection patterns CNPa, CNPb, and CNPc. Accordingly, the gate-source voltage (Vgs) of the driving transistor may not change even when the light-emitting element deteriorates. Accordingly, the amount of change in driving current due to deterioration of the light-emitting element may be reduced. Accordingly, the after-image defect of the display device DD depending on an increase in the time of use may be reduced, and the lifespan of the display device may be improved.

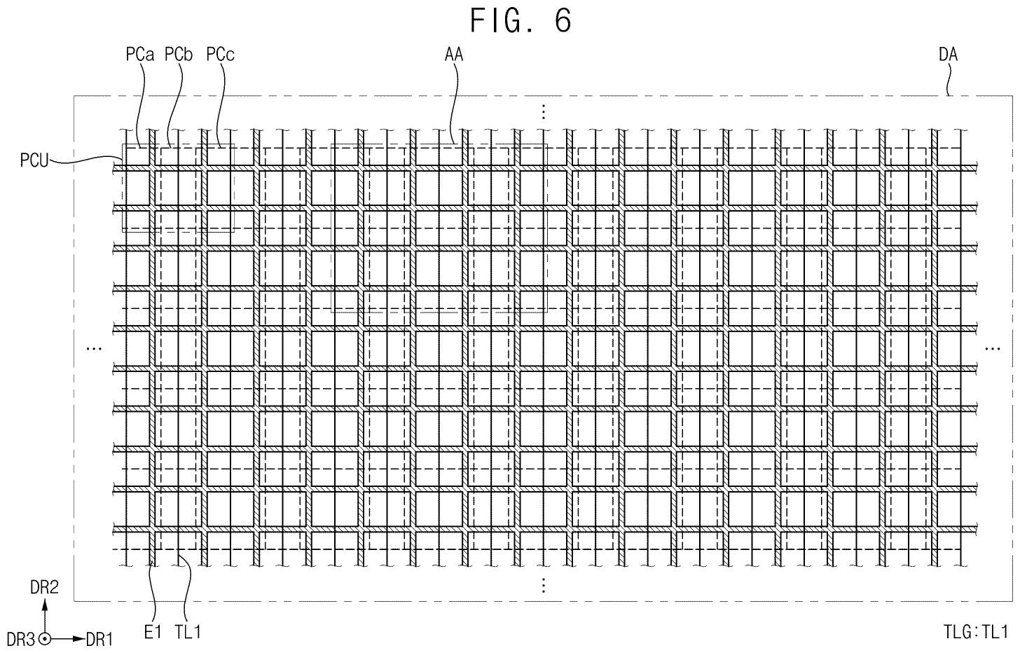

FIG. 6 is a plan view schematically showing a first embodiment of the arrangement relationship between a first electrode layer and a transmission line group disposed in a display area of FIGS. 1A and 1B. FIG. 7 is an enlarged view showing area AA of FIG. 6.

Referring to FIGS. 6 and 7, the display area DA may include unit circuit areas PCU. In an embodiment, the unit circuit areas PCU may be unit areas in which the first to third pixel driving circuit parts PCa, PCb, and PCc arranged in the first direction DR1 are disposed. In an embodiment, the unit circuit areas PCU may be repeatedly arranged along the first direction DR1 and the second direction DR2.

The display device DD may include the first electrode layer E1 and a transmission line group TLG.

In an embodiment, the first electrode layer E1 may be disposed in the display area DA. The first electrode layer E1 may receive the first power supply voltage ELVDD (see FIGS. 2A to 2C). For example, the first electrode layer E1 may be connected to the first voltage line VL1 (see FIGS. 2A to 2C), and may receive the first power supply voltage ELVDD through the first voltage line VL1. In an embodiment, the first power supply voltage ELVDD may be commonly provided to the first to third light-emitting elements LEDa, LEDb, and LEDc through the first electrode layer E1.

As shown in FIG. 7, the first electrode layer E1 may include the first electrodes E1a, E1b, and E1c. Specifically, the first electrode layer E1 may include the first electrode E1a of the first light-emitting element LEDa, the first electrode E1b of the second light-emitting element LEDb, and the first electrode E1c of the third light-emitting element LEDc. In an embodiment, the first electrodes E1a, E1b, and E1c may be arranged in a matrix along the first direction DR1 and the second direction DR2. For example, in an embodiment in which the first to third light-emitting areas EAa, EAb, and EAc (see FIGS. 3 and 4) are disposed in an S-stripe type, the first electrode E1a of the first light-emitting element LEDa and the first electrode E1b of the second light-emitting element LEDb may be arranged alternately in odd-numbered columns, and the first electrode E1c of the third light-emitting element LEDc may be arranged in even-numbered columns. In addition, the first electrode E1a of the first light-emitting element LEDa and the first electrode E1c of the third light-emitting element LEDc may be arranged alternately in odd-numbered rows, and the first electrode E1b of the second light-emitting element LEDb and the first electrode E1c of the third light-emitting element LEDc may be alternately arranged in even-numbered rows. However, the present disclosure is not necessarily limited thereto.

In an embodiment, the transmission line group TLG may be disposed in the display area DA. The transmission line group TLG may be disposed in a different layer from the first electrode layer E1. Specifically, the transmission line group TLG may be disposed in a layer that is closer to the substrate SUB than the first electrode layer E1.

The transmission line group TLG may receive the first power supply voltage ELVDD (see FIGS. 2A to 2C). For example, the transmission line group TLG may be connected to the first voltage line VL1 (see FIGS. 2A to 2C) and may receive the first power supply voltage ELVDD through the first voltage line VL1. In an embodiment, the transmission line group TLG may be directly connected to a power supply voltage supplier located in the peripheral area NDA and may receive the first power supply voltage ELVDD. In this case, the power supply voltage supplier may provide the first power supply voltage ELVDD, and the transmission line group TLG may extend to the peripheral area NDA. The transmission line group TLG may be connected to the first electrode layer E1. Accordingly, the first electrode layer E1 may receive the first power supply voltage ELVDD through the transmission line group TLG. For example, the first electrode layer E1 may receive the first power supply voltage ELVDD directly from the first voltage line VL1, and may additionally receive the first power supply voltage ELVDD through the transmission line group TLG.

The transmission line group TLG may include a plurality of transmission lines extending in one direction and arranged in another direction crossing the one direction. The transmission lines may be connected to the first electrode layer E1. Accordingly, the transmission line group TLG (i.e., the transmission lines) may form a mesh structure with the first electrode layer E1 in plan view.

In an embodiment, the first electrode layer E1 may have a mesh pattern in which the first electrodes E1a, E1b, and E1c are integrally connected. For example, all of the first electrodes E1a, E1b, and E1c may be integrally connected to each other through bridges BR1 and BR2. For example, the first electrode layer E1 may include first bridges BR1 connecting first electrodes adjacent to each other in the first direction DR1 among the first electrodes E1a, E1b, and E1c. In addition, the first electrode layer E1 may include second bridges BR2 connecting adjacent first electrodes E1a, E1b, and E1c in the second direction DR2. The first bridges BR1 and the second bridges BR2 may be integrated with the first electrodes E1a, E1b, and E1c. As the first electrode layer E1 has a mesh pattern, the transmission path of the first power supply voltage ELVDD may have mesh characteristics. Accordingly, the voltage drop of the first power supply voltage ELVDD may be reduced. Accordingly, power consumption of the display device DD may be improved and luminance uniformity may be improved. Accordingly, the display quality of the display device DD may be improved.

In an embodiment, the transmission line group TLG may include first transmission lines TL1. For example, the transmission line group TLG may be a set of the first transmission lines TL1.

The first transmission lines TL1 may include a conductive material such as metal, alloy, conductive metal oxide, conductive metal nitride, transparent conductive oxide, and the like. The first transmission lines TL1 may have a single-layer structure or a multi-layer structure in which a plurality of conductive layers are stacked.

The first transmission lines TL1 may receive the first power supply voltage ELVDD (see FIGS. 2A to 2C). For example, the first transmission lines TL1 may be connected to the first voltage line VL1 (see FIGS. 2A to 2C), and the first power supply voltage ELVDD may be applied through the first voltage line VL1. In an embodiment, the first transmission lines TL1 may be directly connected to the power supply voltage supplier located in the peripheral area NDA and may receive the first power supply voltage ELVDD. In this case, the first transmission lines TL1 may extend to the peripheral area NDA. The first transmission lines TL1 may be connected to the first electrode layer E1. For example, the first transmission lines TL1 may be electrically connected to the first electrode layer E1 through a first contact hole CNT1. Accordingly, the first electrode layer E1 may receive the first power supply voltage ELVDD through the first transmission lines TL1. For example, the first electrode layer E1 may receive the first power supply voltage ELVDD directly from the first voltage line VL1, and may additionally receive the first power supply voltage ELVDD through the first transmission lines TL1.

In an embodiment, the first transmission lines TL1 may extend in the second direction DR2 and be arranged in the first direction DR1. Accordingly, the first transmission lines TL1 and the first electrode layer E1 may form a mesh structure in plan view. That is, in addition to the first electrode layer E1 having a mesh pattern itself, the first electrode layer E1 may further form a mesh structure together with the first transmission lines TL1.

FIGS. 6 and 7 depict the first transmission lines TL1 arranged in the first direction DR1 so that three first transmission lines TL1 correspond to each unit circuit area PCU. However, the present disclosure is not limited thereto. For example, if the first transmission lines TL1 forms a mesh structure together with the first electrode layer E1, the interval at which the first transmission lines TL1 repeat may vary depending on the embodiment.

According to an embodiment of the present disclosure, the first transmission lines TL1 receiving the first power supply voltage ELVDD may be connected to the first electrode layer E1. Accordingly, the first transmission lines TL1 may provide the first power supply voltage ELVDD to the first electrode layer E1. In addition, the first transmission lines TL1 and the first electrode layer E1 may form a mesh structure in plan view. Accordingly, the mesh characteristics of the transmission path of the first power supply voltage ELVDD may be further strengthened. Accordingly, the voltage drop of the first power supply voltage ELVDD may be further reduced. Accordingly, power consumption of the display device DD may be improved and luminance uniformity may be improved. Accordingly, the display quality of the display device DD may be improved.

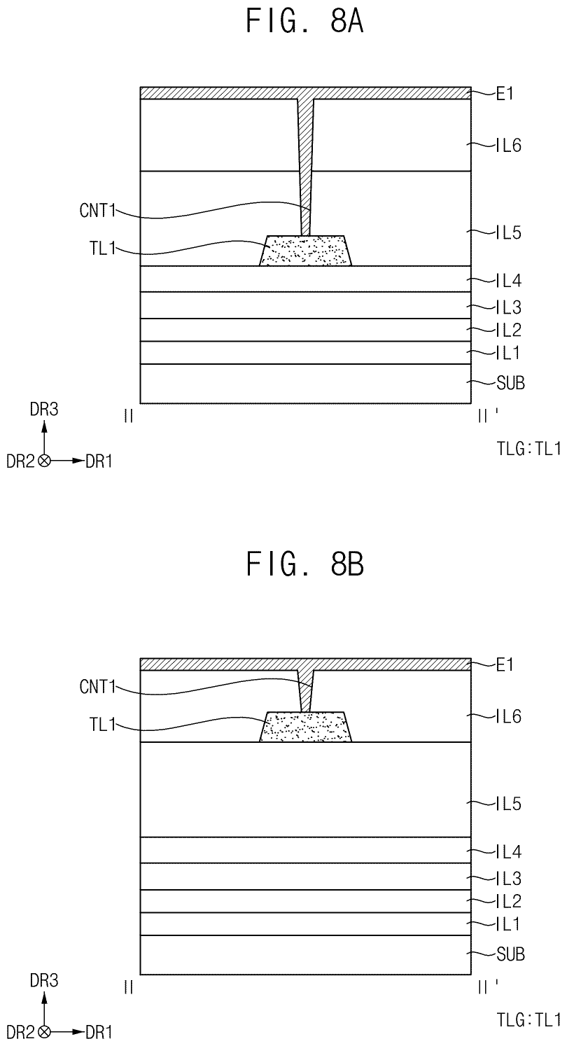

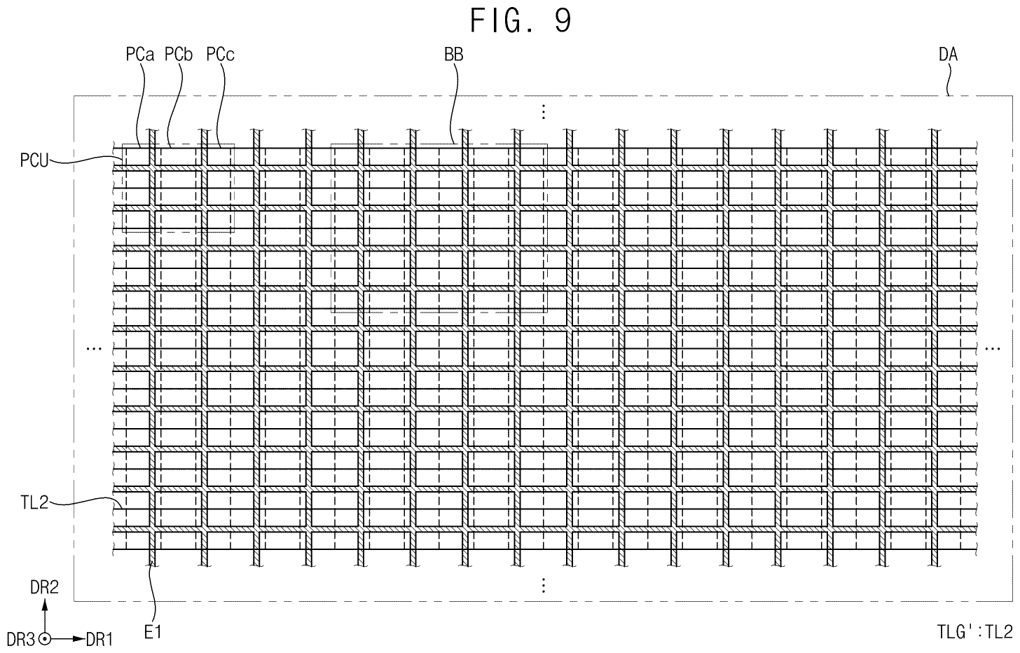

FIG. 8A is a cross-sectional view showing an example taken along line II-II′ of FIG. 7.

For convenience of explanation, FIG. 8A primarily shows the first transmission lines TL1 and the first electrode layer E1, with some of the components shown in FIGS. 3 to 5 omitted.

Referring further to FIG. 8A, in an embodiment, the first transfer lines TL1 may be disposed in the same layer as the first contact electrode SE1 (see FIG. 5) and the second contact electrode DE1 (see FIG. 5). For example, the first transmission lines TL1 may be disposed on the fourth insulating layer IL4 and at least partially covered by the fifth insulating layer IL5. In this case, the first contact hole CNT1 may extend through the fifth insulating layer IL5 and the sixth insulating layer IL6 to expose the first transmission lines TL1, and the first electrode layer E1 may be electrically connected to the first transmission lines TL1 through the first contact hole CNT1.

In an embodiment, the first transfer lines TL1 may be formed together with the first contact electrode SE1 (see FIG. 5) and the second contact electrode DE1 (see FIG. 5) in the same process, and may include the same material as the first contact electrode SE1 and the second contact electrode DE1. For example, a preliminary conductive layer may be formed on the fourth insulating layer IL4, and the preliminary conductive layer may be patterned to form the first transmission lines TL1, the first contact electrode SE1, and the second contact electrode DE1 together. However, the present disclosure is not necessarily limited thereto.

FIG. 8B is a cross-sectional view showing an example taken along line II-II′ of FIG. 7.

For convenience of explanation, FIG. 8B primarily shows the first transmission lines TL1 and the first electrode layer E1, with some of the components shown in FIGS. 3 to 5 omitted.

Referring to FIG. 8B, in an embodiment, the first transmission lines TL1 may be disposed in the same layer as the first to third connection electrodes CEa, CEb, and CEc (see FIGS. 3 to 5). For example, the first transmission lines TL1 may be disposed on the fifth insulating layer IL5 and at least partially covered by the sixth insulating layer IL6. In this case, the first contact hole CNT1 may extend through the sixth insulating layer IL6 to expose the first transmission lines TL1, and the first electrode layer E1 may be electrically connected to the first transmission lines TL1 through the first contact hole CNT1.

In an embodiment, the first transmission lines TL I may be formed together with the first to third connection electrodes CEa, CEb, and CEc (see FIGS. 3 to 5) in the same process, and may include the same material as the first to third connection electrodes CEa, CEb, and CEc (see FIGS. 3 to 5). For example, a preliminary conductive layer may be formed on the fifth insulating layer IL5, and the preliminary conductive layer may be patterned to form the first transmission lines TL1 and the first to third connection electrodes CEa, CEb, and CEc together. However, the present disclosure is not necessarily limited thereto.

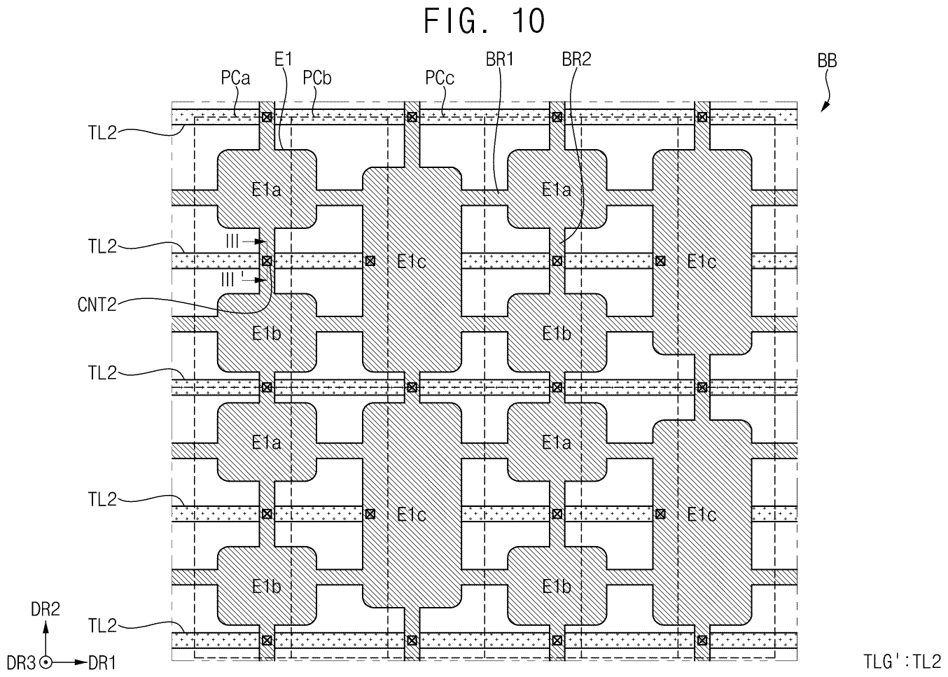

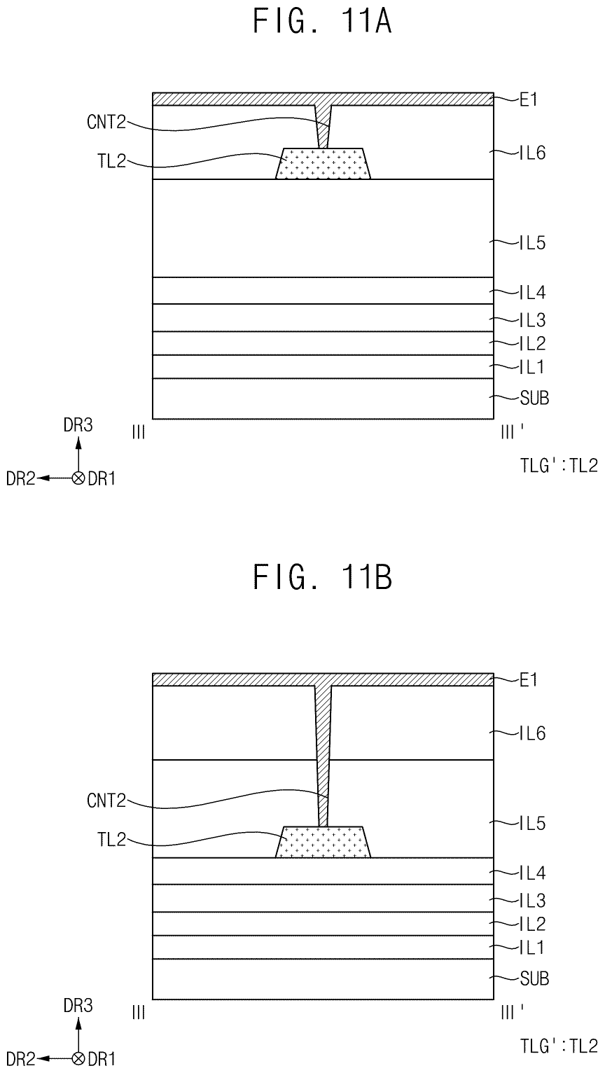

FIG. 9 is a plan view schematically showing a second embodiment of the arrangement relationship between a first electrode layer and a transmission line group disposed in a display area of FIGS. 1A and 1B. FIG. 10 is an enlarged view showing area BB of FIG. 9.

The embodiment of the display device DD described with reference to FIGS. 9 and 10 may be substantially the same as the embodiment of the display device DD described with reference to FIGS. 6 and 7, except for a transmission line group TLG′. Therefore, redundant descriptions are omitted or abbreviated.

Referring to FIGS. 9 and 10, the display device DD may include the first electrode layer E1 and a transmission line group TLG′. The description of the first electrode layer E1 with reference to FIGS. 6 and 7 may be applied to the first electrode layer E1 of FIGS. 9 and 10. Therefore, redundant descriptions are omitted or abbreviated.

In an embodiment, the transmission line group TLG′ may be disposed in the display area DA. The transmission line group TLG′ may be disposed in a layer different from the first electrode layer E1. Specifically, the transmission line group TLG′ may be disposed closer to the substrate SUB than the first electrode layer E1.

The transmission line group TLG′ may receive the first power supply voltage ELVDD (see FIGS. 2A to 2C). For example, the transmission line group TLG′ may be connected to the first voltage line VL1 (see FIGS. 2A to 2C), and may receive the first power supply voltage ELVDD through the first voltage line VL1. In an embodiment, the transmission line group TLG′ may be directly connected to the power supply voltage supplier located in the peripheral area NDA and may receive the first power supply voltage ELVDD. In this case, the transmission line group TLG′ may extend to the peripheral area NDA. The transmission line group TLG′ may be connected to the first electrode layer E1. Accordingly, the first electrode layer E1 may receive the first power supply voltage ELVDD through the transmission line group TLG′. For example, the first electrode layer E1 may receive the first power supply voltage ELVDD directly from the first voltage line VL1, and may additionally receive the first power supply voltage ELVDD through the transmission line group TLG′.

The transmission line group TLG′ may include a plurality of transmission lines extending in one direction and arranged in another direction crossing the one direction. The transmission lines may be connected to the first electrode layer E1. Accordingly, the transmission line group TLG′ (i.e., the transmission lines) may form a mesh structure with the first electrode layer E1 in plan view.

In an embodiment, the transmission line group TLG′ may include second transmission lines TL2. For example, the transmission line group TLG′ may be a set of the second transmission lines TL2.

The second transmission lines TL2 may include a conductive material such as metal, alloy, conductive metal oxide, conductive metal nitride, transparent conductive oxide, and the like. The second transmission lines TL2 may have a single-layer structure or a multi-layer structure in which a plurality of conductive layers are stacked.

The second transmission lines TL2 may receive the first power supply voltage ELVDD (see FIGS. 2A to 2C). For example, the second transmission lines TL2 may be connected to the first voltage line VL1 (see FIGS. 2A to 2C), and the first power supply voltage ELVDD may be applied through the first voltage line VL1. In an embodiment, the second transmission lines TL2 may be directly connected to the power supply voltage supplier located in the peripheral area NDA and may receive the first power supply voltage ELVDD. In this case, the second transmission lines TL2 may extend to the peripheral area NDA. The second transmission lines TL2 may be connected to the first electrode layer E1. For example, the second transmission lines TL2 may be electrically connected to the first electrode layer E1 through a second contact hole CNT2. Accordingly, the first electrode layer E1 may receive the first power supply voltage ELVDD through the second transmission lines TL2. For example, the first electrode layer E1 may receive the first power voltage ELVDD directly from the first voltage line VL1, and may additionally receive the first power voltage ELVDD through the second transmission lines TL2.

In an embodiment, the second transmission lines TL2 may extend in the first direction DR1 and be arranged in the second direction DR2. Accordingly, the second transmission lines TL2 and the first electrode layer E1 may form a mesh structure in plan view.

That is, in addition to the first electrode layer E1 having a mesh pattern itself, the first electrode layer E1 may form a mesh structure together with the second transmission lines TL2.

Meanwhile, in FIGS. 9 and 10, the second transmission lines TL2 are shown arranged in the second direction DR2 so that three second transmission lines TL2 correspond to each unit circuit area PCU. However, the present disclosure is not necessarily limited thereto.

For example, if the second transmission lines TL2 forms a mesh structure together with the first electrode layer E1, the interval at which the second transmission lines TL2 repeat may vary depending on the embodiment.

According to an embodiment of the present disclosure, the second transmission lines TL2 receiving the first power supply voltage ELVDD may be connected to the first electrode layer E1. Accordingly, the second transmission lines TL2 may provide the first power supply voltage ELVDD to the first electrode layer E1. In addition, the second transmission lines TL2 and the first electrode layer E1 may form a mesh structure in plan view. Accordingly, the mesh characteristics of the transmission path of the first power supply voltage ELVDD may be further strengthened. Accordingly, the voltage drop of the first power supply voltage ELVDD may be further reduced, power consumption of the display device DD may be improved, and luminance uniformity may be improved. Furthermore, the display quality of the display device DD may be improved.

FIG. 11A is a cross-sectional view showing an example taken along line III-III′ of FIG. 10.

For convenience of explanation, FIG. 11A primarily shows the second transmission lines TL2 and the first electrode layer E1, with some of the components shown in FIGS. 3 to 5 omitted.

Referring further to FIG. 11A, in an embodiment, the second transmission lines TL2 may be disposed in the same layer as the first to third connection electrodes CEa, CEb, and CEc (see FIGS. 3 to 5). For example, the second transmission lines TL2 may be disposed on the fifth insulating layer IL5 and at least partially covered by the sixth insulating layer IL6. In this case, the second contact hole CNT2 may extend through the sixth insulating layer IL6 to the second transmission lines TL2, and the first electrode layer E1 may be electrically connected to the second transmission lines TL2 through the second contact hole CNT2.

In an embodiment, the second transmission lines TL2 may be formed together with the first to third connection electrodes CEa, CEb, and CEc (see FIGS. 3 to 5) in the same process and may include the same material as the first to third connection electrodes CEa, CEb, and CEc. For example, a preliminary conductive layer may be formed on the fifth insulating layer IL5, and the preliminary conductive layer may be patterned to form the second transmission lines TL2 and the first to third connection electrodes CEa, CEb, and CEc together. However, the present disclosure is not necessarily limited thereto.

FIG. 11B is a cross-sectional view showing an example taken along line III-III′ of FIG. 10.

For convenience of explanation, FIG. 11B primarily shows the second transmission lines TL2 and the first electrode layer E1, with some of the components shown in FIGS. 3 to 5 omitted.

Referring further to FIG. 11B, in an embodiment, the second transmission lines TL2 may be disposed in the same layer the first contact electrode SE1 (see FIG. 5) and the second contact electrode DE1 (see FIG. 5).

For example, the second transmission lines TL2 may be disposed on the fourth insulating layer IL4 and at least partially covered by the fifth insulating layer IL5. In this case, the second contact hole CNT2 may extend through the fifth insulating layer IL5 and the sixth insulating layer IL6 to the second transmission lines TL2, and the first electrode layer E1 may be electrically connected to the second transmission lines TL2 through the second contact hole CNT2.

In an embodiment, the second transmission lines TL2 may be formed together with the first contact electrode SE1 (see FIG. 5) and the second contact electrode DE1 (see FIG. 5) in the same process, and may include the same material as the electrode SE1 and the second contact electrode DE1. For example, a preliminary conductive layer may be formed on the fourth insulating layer IL4, and the preliminary conductive layer may be patterned to form the second transmission lines TL2, the first contact electrode SE1, and the second contact electrode DE1 together. However, the present disclosure is not necessarily limited thereto.

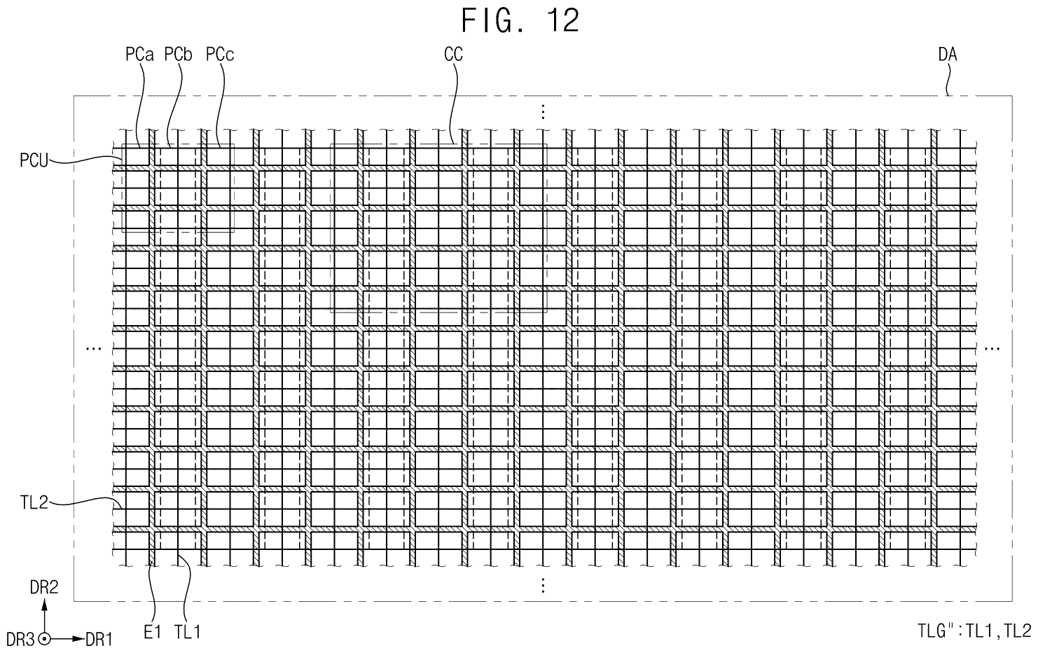

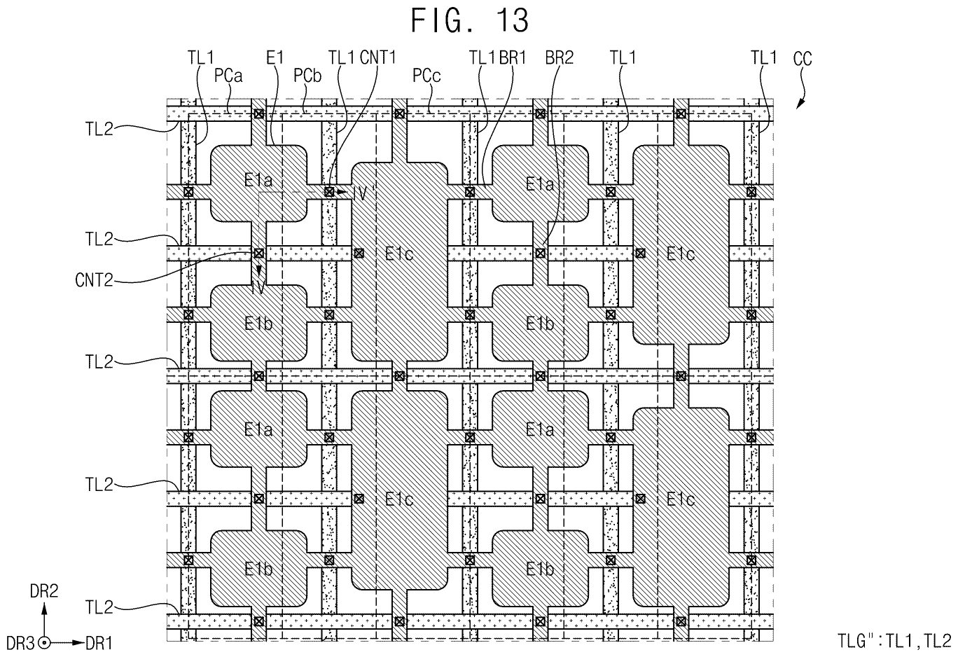

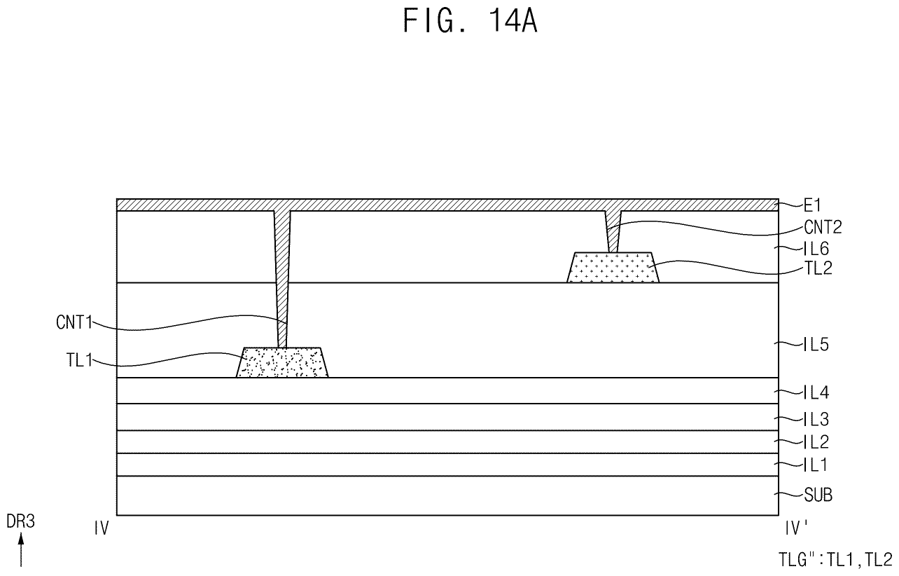

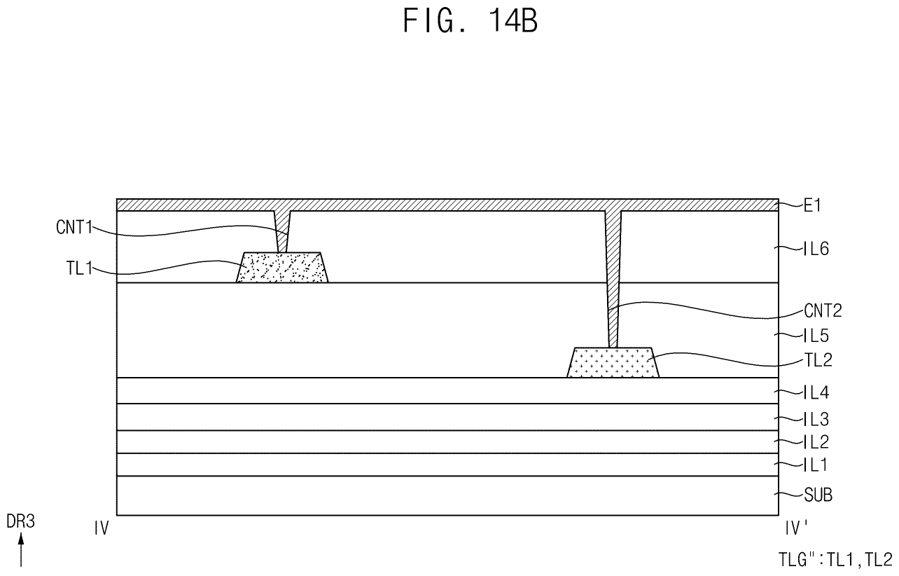

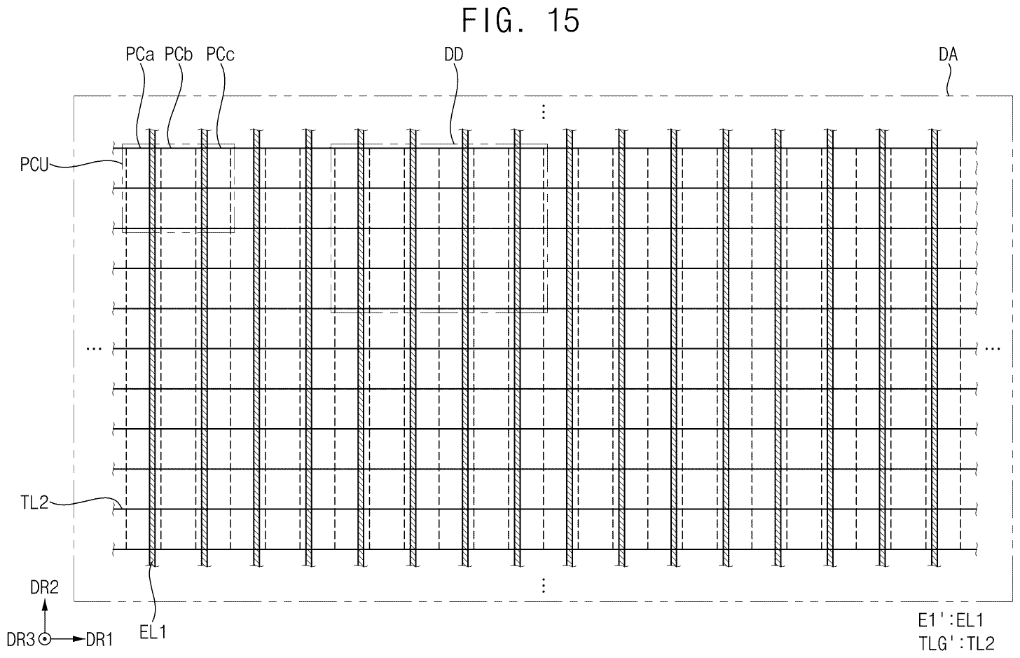

FIG. 12 is a plan view schematically showing a third embodiment of the arrangement relationship between a first electrode layer and a transmission line group disposed in a display area of FIGS. 1A and 1B. FIG. 13 is an enlarged view showing area CC of FIG. 12.

The embodiment of the display device DD described with reference to FIGS. 12 and 13 may be substantially the same as the embodiment of the display device DD described with reference to FIGS. 6 and 7, except for a transmission line group TLG″. Therefore, overlapping descriptions are omitted.

Referring to FIGS. 12 and 13, the display device DD may include the first electrode layer E1 and a transmission line group TLG″. The description of the first electrode layer E1 with reference to FIGS. 6 and 7 may be applied to the first electrode layer E1 of FIGS. 12 and 13. Therefore, overlapping descriptions are omitted.

In an embodiment, the transmission line group TLG″ may be disposed in the display area DA. The transmission line group TLG″ may be disposed in a different layer from the first electrode layer E1. Specifically, the transmission line group TLG″ may be disposed lower than the first electrode layer E1.

The transmission line group TLG″ may receive the first power supply voltage ELVDD (see FIGS. 2A to 2C). For example, the transmission line group TLG″ may be connected to the first voltage line VL1 (see FIGS. 2A to 2C), and the first power supply voltage ELVDD may receive power through the first voltage line VL1. In an embodiment, the transmission line group TLG″ may be directly connected to a power supply voltage supplier disposed in the peripheral area NDA and receive the first power supply voltage ELVDD. In this case, the transmission line group TLG″ may extend to the peripheral area NDA. The transmission line group TLG″ may be connected to the first electrode layer E1. Accordingly, the first electrode layer E1 may receive the first power supply voltage ELVDD through the transmission line group TLG″. For example, the first electrode layer E1 may receive the first power supply voltage ELVDD directly from the first voltage line VL1, and may additionally receive the first power supply voltage ELVDD through the transmission line group TLG″.

The transmission line group TLG″ may include a plurality of first transmission lines extending in one direction and arranged in another direction crossing the one direction. In addition, the transmission line group TLG″ may include a plurality of second transmission lines extending in the other direction and arranged in the one direction. The first transmission lines and the second transmission lines may be connected to the first electrode layer E1. Accordingly, the transmission line group TLG″ (e.g., the first transmission lines and the second transmission lines) may form a mesh structure with the first electrode layer E1 in plan view.

In an embodiment, the transmission line group TLG″ may include first transmission lines TL1 and second transmission lines TL2. For example, the transmission line group TLG″ may be a set of the first transmission lines TL1 and the second transmission lines TL2.

The description of the first transmission lines TL1 with reference to FIGS. 6 and 7 may be applied to the first transmission lines TL1 of FIGS. 12 and 13. Therefore, any redundant descriptions are omitted or abbreviated. In addition, the description of the second transmission lines TL2 with reference to FIGS. 9 and 10 may be applied to the second transmission lines TL2 of FIGS. 12 and 13. Therefore, any redundant descriptions are omitted or abbreviated.

As described above, the first transmission lines TL1 and the second transmission lines TL2 may receive the first power supply voltage ELVDD (see FIGS. 2A to 2C). The first transmission lines TL1 may be electrically connected to the first electrode layer E1 through a first contact hole CNT1, and the second transmission lines TL2 may be electrically connected to the first electrode layer E1 through a second contact hole CNT2. Accordingly, the first electrode layer E1 may receive the first power supply voltage ELVDD through the first and second transmission lines TL1 and TL2.

In an embodiment, the first transmission lines TL1 may extend in the second direction DR2 and be arranged in the first direction DR1. The second transmission lines TL2 may extend in the first direction DR1 and be arranged in the second direction DR2. Accordingly, the first transmission lines TL1, the second transmission lines TL2, and the first electrode layer E1 may form a mesh structure in plan view. That is, in addition to the first electrode layer E1 having a mesh pattern itself, the first electrode layer E1 may further form a mesh structure together with the first transmission lines TL1 and the second transmission lines TL2.

According to an embodiment of the present disclosure, the first transmission lines TL1 and the second transmission lines TL2 receiving the first power voltage ELVDD may be connected to the first electrode layer E1. Accordingly, the first transmission lines TL1 and the second transmission lines TL2 may provide the first power supply voltage ELVDD to the first electrode layer E1. In addition, the first transmission lines TL1, the second transmission lines TL2, and the first electrode layer E1 may form a mesh structure in plan view. Accordingly, the mesh characteristics of the transmission path of the first power supply voltage ELVDD may be further strengthened. As a result, the voltage drop of the first power supply voltage ELVDD may be further reduced, power consumption of the display device DD may go down, and luminance uniformity may be improved. Furthermore, the display quality of the display device DD may be improved.

FIG. 14A is a cross-sectional view showing an example taken along line IV-IV′ of FIG. 13.

For convenience of explanation, FIG. 14A primarily shows the first transmission lines TL1, the second transmission lines TL2, and the first electrode layer E1, with some of the components shown in FIGS. 3 to 5 omitted.

Referring to FIG. 14A, in an embodiment in which the display device DD may include the first electrode layer E1 and the transmission line group TLG″, the second transmission lines TL2 may be disposed on the first transmission lines TL1. In an embodiment, the first transmission lines TL1 may be disposed in the same layer as the first contact electrode SE1 (see FIG. 5) and the second contact electrode DE1 (see FIG. 5), and the second transmission lines TL2 may be disposed in the same layer as the first to third connection electrodes CEa, CEb, and CEc (see FIGS. 3 to 5). For example, the first transmission lines TL1 may be disposed on the fourth insulating layer IL4 and at least partially covered by the fifth insulating layer IL5. In addition, the second transmission lines TL2 may be disposed on the fifth insulating layer IL5 and at least partially covered by the sixth insulating layer IL6. In this case, the first contact hole CNT1 may extend through the fifth insulating layer IL5 and the sixth insulating layer IL6 to the first transmission lines TL1, and the first electrode layer E1 may be electrically connected to the first transmission lines TL1 through the first contact hole CNT1. In addition, the second contact hole CNT2 may extend through the sixth insulating layer IL6 to the second transmission lines TL2, and the first electrode layer E1 may be electrically connected to the second transmission lines TL2 through the second contact hole CNT2.

FIG. 14B is a cross-sectional view showing an example taken along line IV-IV′ of FIG. 13.

For convenience of explanation, FIG. 14B primarily shows the first transmission lines TL1, the second transmission lines TL2, and the first electrode layer E1, with some of the components shown in FIGS. 3 to 5 omitted.

Referring to FIG. 14B, in an embodiment in which the display device DD may include the first electrode layer E1 and the transmission line group TLG″, the first transmission lines TL1 may be disposed on the second transmission lines TL2. In an embodiment, the first transmission lines TL1 may be disposed in the same layer as the first to third connection electrodes CEa, CEb, and CEc (see FIGS. 3 to 5), and the second transmission lines TL2 may be disposed in the same layer as the first contact electrode SE1 (see FIG. 5) and the second contact electrode DE1 (see FIG. 5). For example, the first transmission lines TL1 may be disposed on the fifth insulating layer IL5 and at least partially covered by the sixth insulating layer IL6. In addition, the second transmission lines TL2 may be disposed on the fourth insulating layer IL4 and at least partially covered by the fifth insulating layer IL5. In this case, the first contact hole CNT1 may extend through the sixth insulating layer IL6 to the first transmission lines TL1, and the first electrode layer E1 may be electrically connected to the first transmission lines TL1 through the first contact hole CNT1. In addition, the second contact hole CNT2 may extend through the fifth and sixth insulating layers IL5 and IL6 to the second transmission lines TL2, and the first electrode layer E1 may be electrically connected to the second transmission lines TL2 through the second contact hole CNT2.

Meanwhile, in FIG. 13, the second transmission lines TL2 are shown to be disposed on the first transmission lines TL1. However, according to the embodiment shown in FIG. 14B, the illustration in FIG. 13 may be changed so that the first transmission lines TL1 are disposed on the second transmission lines TL2.

In addition, although not shown, in an embodiment, at least one of the first transmission lines TL1 may be connected to at least one of the second transmission lines TL2 through a contact hole. In this case, the voltage drop of the first power voltage ELVDD may be further reduced. However, the present disclosure is not necessarily limited to this, and contact between the first and second transmission lines TL1 and TL2 may be omitted.

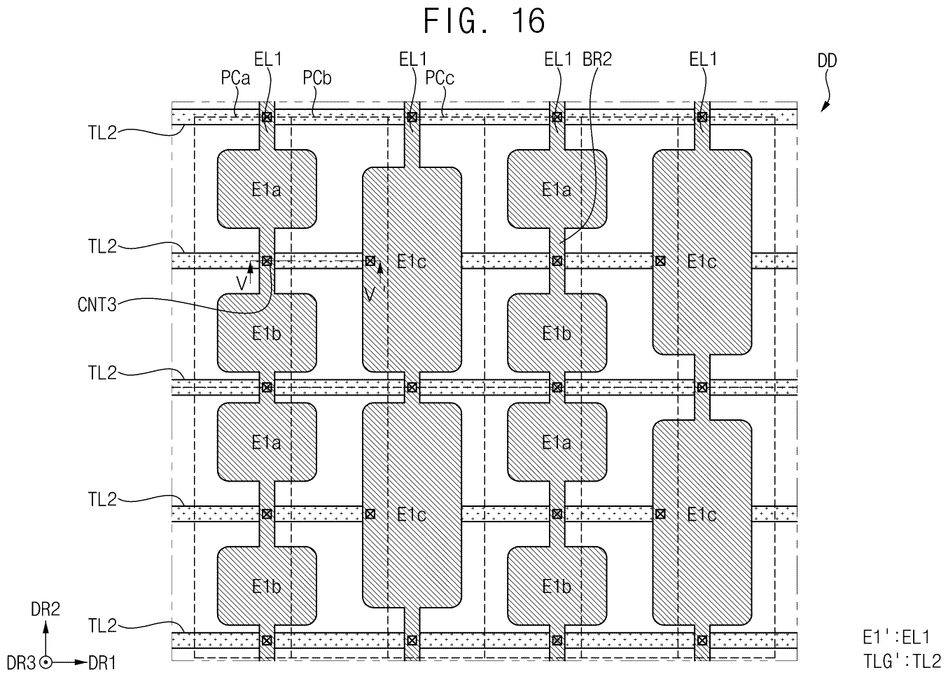

FIG. 15 is a plan view schematically showing a fourth embodiment of the arrangement relationship between a first electrode layer and a transmission line group disposed in a display area of FIGS. 1A and 1B. FIG. 16 is an enlarged view showing area DD of FIG. 15.

The embodiment of the display device DD described with reference to FIGS. 15 and 16 may be substantially the same as the embodiment of the display device DD described with reference to FIGS. 9 and 10, except for a first electrode layer E1′. In addition, the first electrode layer E1′ may be substantially the same as the first electrode layer E1 described above except that the first electrodes E1a, E1b, and E1c are not all integrally connected in a mesh pattern and include first electrode lines EL1 physically separated from each other. Therefore, redundant descriptions are omitted or abbreviated.

Referring to FIGS. 15 and 16, the display device DD may include the first electrode layer E1′ and the transmission line group TLG′. The description of the transmission line group TLG′ with reference to FIGS. 9 and 10 may be applied to the transmission line group TLG′ of FIGS. 15 and 16. Therefore, redundant descriptions are omitted or abbreviated.

In an embodiment, the first electrode layer E1′ may include the first electrode lines EL1. The first electrode lines EL1 may extend in one direction and be arranged in another direction crossing the one direction. For example, the first electrode lines EL1 may extend in the second direction DR2 and be arranged in the first direction DR1. Each of the first electrode lines EL1 may have a structure in which some of the first electrodes E1a, E1b, and E1c are integrally connected. In addition, the first electrode lines EL1 may be physically separated from each other.

For example, as shown in FIG. 16, all of the first electrodes arranged in column i (where, i is a natural number) may be integrally connected through the second bridges BR2 to form the first electrode lines EL1. The first electrode lines EL1 arranged in the first direction DR1 may be physically separated from each other. That is, in an embodiment, the shape of the first electrode layer E1′ may be substantially the same as the shape of the first electrode layer E1 (see FIG. 10) in plan view, with the first bridges BR1 omitted.

In an embodiment, the first electrode lines EL1 may be electrically connected to each other through the transmission line group TLG′. That is, the first electrode lines EL1 may be electrically connected to each other through the second transmission lines TL2. The second transmission lines TL2 may be electrically connected to the first electrode lines EL1 through a third contact hole CNT3. Accordingly, the first electrode lines EL1 may be electrically connected to each other and may receive the first power supply voltage ELVDD through the second transmission lines TL2. That is, the first electrode layer E1′ may receive the first power supply voltage ELVDD through the second transmission lines TL2. For example, the first electrode layer E1′ (i.e., the first electrode lines EL1) may receive the first power supply voltage ELVDD directly from the first voltage line VL1, and may additionally receive the first power supply voltage ELVDD through the second transmission lines TL2.

As described above, the second transmission lines TL2 may extend in the first direction DR1 and be arranged in the second direction DR2. Accordingly, the second transmission lines TL2 and the first electrode lines EL1 may form a mesh structure in plan view. That is, even if the first electrode layer E1′ itself does not have a mesh pattern and has another structure including the first electrode lines EL1, the first electrode layer E1′ may form a mesh structure together with the second transmission lines TL2. Accordingly, mesh characteristics of the transmission path of the first power voltage ELVDD may be implemented. Accordingly, while lowering the difficulty in designing the first electrode layer E1′, the voltage drop of the first power supply voltage ELVDD may be reduced.

Although not shown, in an embodiment in which the display device DD includes the first electrode layer E1′, the display device DD may include the transmission line group TLG″ described with reference to FIGS. 12 to 14 instead of the transmission line group TLG′. That is, in one embodiment, the display device DD may further include the first transmission lines TL1 (see FIGS. 12 to 14) connected to the first electrode layer E1′ (i.e., the first electrode lines EL1). In other words, the first electrode layer E1′ (i.e., the first electrode lines EL1) may receive the first power supply voltage ELVDD through the first transmission lines TL1 and the second transmission lines TL2.

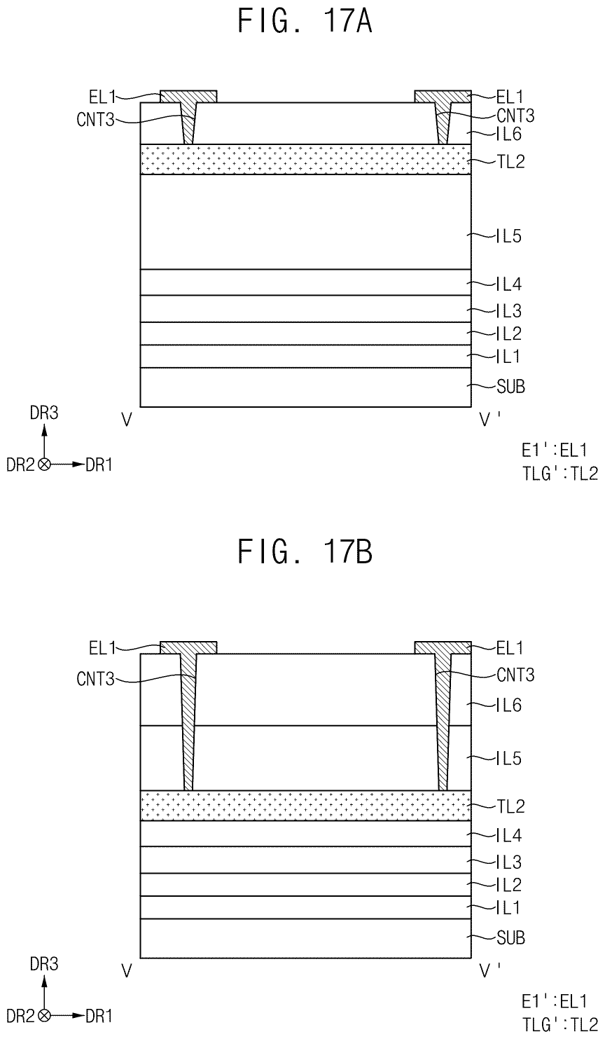

FIG. 17A is a cross-sectional view showing an example taken along line V-V′ of FIG. 16.

For convenience of explanation, FIG. 17A primarily shows the second transmission lines TL2 and the first electrode layer E1′, with some of the components shown in FIGS. 3 to 5 omitted.

Referring to FIG. 17A, in an embodiment in which the display device DD includes the first electrode layer E1′, the second transmission lines TL2 may be disposed in the same layer as the first to third connection electrodes CEa, CEb, and CEc (see FIGS. 3 to 5). For example, the second transmission lines TL2 may be disposed on the fifth insulating layer IL5 and at least partially covered by the sixth insulating layer IL6. In this case, the third contact hole CNT3 may extend through the sixth insulating layer IL6 to the second transmission lines TL2, and the first electrode layer E1 ‘(i.e., the first electrode lines EL1) may be electrically connected to the second transmission lines TL2 through the third contact hole CNT3.

FIG. 17B is a cross-sectional view showing an example taken along line V-V’ of FIG. 16.

For convenience of explanation, FIG. 17B primarily shows the second transmission lines TL2 and the first electrode layer E1′, with some of the components shown in FIGS. 3 to 5 omitted.

Referring to FIG. 17B, in an embodiment in which the display device DD includes the first electrode layer E1′, the second transmission lines TL2 may be disposed in the same layer as the first contact electrode SE1 (see FIG. 5) and the second contact electrode DE1 (see FIG. 5). For example, the second transmission lines TL2 may be disposed on the fourth insulating layer IL4 and at least partially covered by the fifth insulating layer IL5. For example, the second transmission lines TL2 may be disposed on the fourth insulating layer IL4 and at least partially covered by the fifth insulating layer IL5. In this case, the third contact hole CNT3 may extend through the fifth insulating layer IL5 and the sixth insulating layer IL6 to the second transmission lines TL2, and the first electrode layer E1′ (i.e., the first electrode lines EL1) may be electrically connected to the second transmission lines TL2 through the third contact hole CNT3.

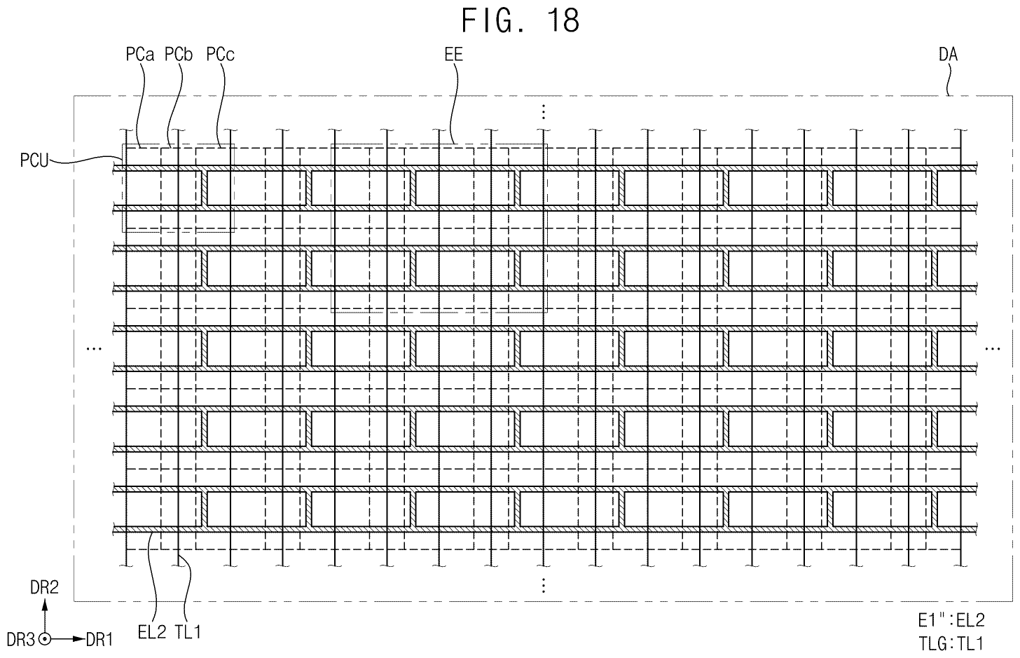

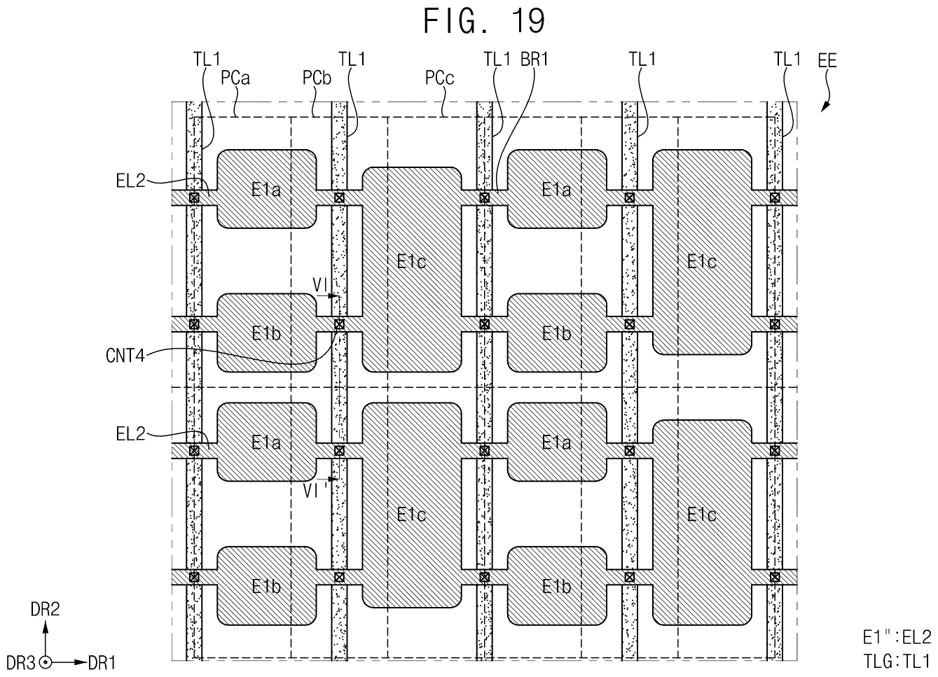

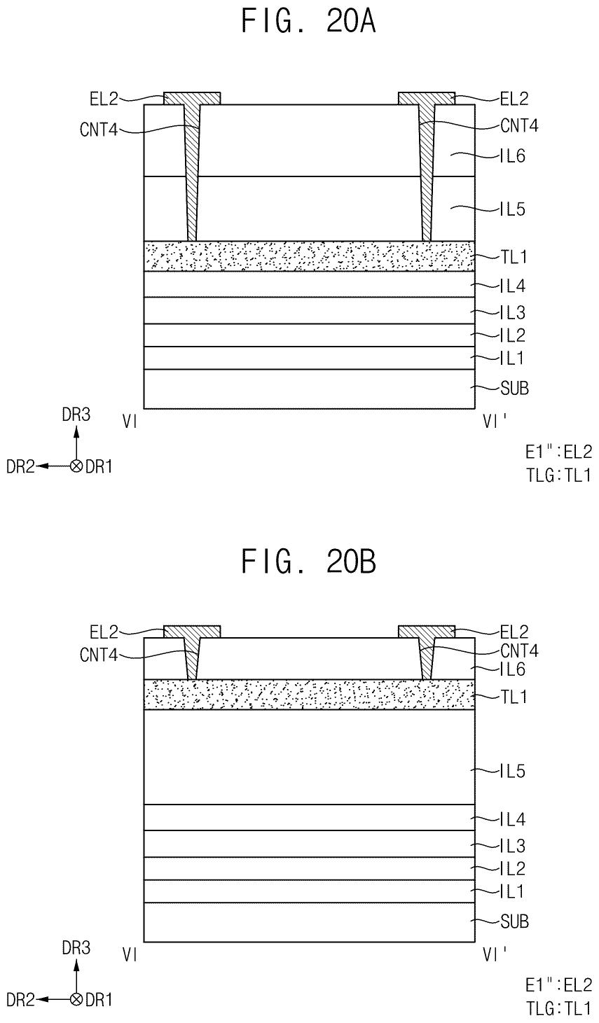

FIG. 18 is a plan view schematically showing a fifth embodiment of the arrangement of a first electrode layer and a transmission line group disposed in a display area of FIGS. 1A and 1B. FIG. 19 is an enlarged view showing area EE of FIG. 18.

The embodiment of the display device DD described with reference to FIGS. 18 and 19 may be substantially the same as the embodiment of the display device DD described with reference to FIGS. 6 and 7, except for a first electrode layer E1 “. In addition, the first electrode layer E1” may be substantially the same as the first electrode layer E1 described above except that the first electrodes E1a, E1b, and E1c are not integrally connected in a mesh pattern and include second electrode lines EL2 physically separated from each other. Therefore, redundant descriptions are omitted or abbreviated. Referring to FIGS. 18 and 19, the display device DD may include the first electrode layer E″ and the transmission line group TLG. The description of the transmission line group TLG with reference to FIGS. 6 and 7 may be applied to the transmission line group TLG of FIGS. 18 and 19. Therefore, redundant descriptions are omitted or abbreviated.

In an embodiment, the first electrode layer E1″ may include the second electrode lines EL2. The second electrode lines EL2 may extend in one direction and be arranged in another direction crossing the one direction. For example, the second electrode lines EL2 may extend in the first direction DR1 and be arranged in the second direction DR2. Each of the second electrode lines EL2 may have a structure in which some of the first electrodes E1a, E1b, and E1c are integrally connected. In addition, the second electrode lines EL2 may be physically separated from each other.

For example, as shown in FIGS. 18 and 19, all of the first electrodes arranged in row j and row j+1 (where j is an odd number of 1 or more) may be integrally connected through the first bridges BR1 to form second electrode lines EL2, and the second electrode lines EL2 arranged in the second direction DR2 may be physically separated from each other. That is, in an embodiment, the shape of the first electrode layer E1″ may be substantially the same as the shape of the first electrode layer E1 in plan view (see FIG. 7) with the second bridges BR2 omitted.

In an embodiment, the second electrode lines EL2 may be electrically connected to each other through the transmission line group TLG. That is, the second electrode lines EL2 may be electrically connected to each other through the first transmission lines TL1. The first transmission lines TL1 may be electrically connected to the second electrode lines EL2 through a fourth contact hole CNT4. Accordingly, the second electrode lines EL2 may be electrically connected to each other and may receive the first power supply voltage ELVDD through the first transmission lines TL1. That is, the first electrode layer E1″ may receive the first power supply voltage ELVDD through the first transmission lines TL1. For example, the first electrode layer E1″ (i.e., the second electrode lines EL2) may receive the first power supply voltage ELVDD directly from the first voltage line VL1, and may additionally receive the first power supply voltage ELVDD through the first transmission lines TL1.

As described above, the first transmission lines TL1 may extend in the second direction DR2 and be arranged in the first direction DR1. Accordingly, the first transmission lines TL1 and the second electrode lines EL2 may form a mesh structure in plan view. That is, even if the first electrode layer E1″ itself does not have a mesh pattern and has another structure including the second electrode lines EL2, the first electrode layer E1″ may form the mesh structure together with the first transmission lines TL1. Accordingly, mesh characteristics of the transmission path of the first power voltage ELVDD can be implemented. Accordingly, while lowering the difficulty in designing the first electrode layer E1 “, the voltage drop of the first power supply voltage ELVDD may be reduced.

Although not shown, in an embodiment in which the display device DD includes the first electrode layer E1”, the display device DD may include the transmission line group TLG″ described with reference to FIGS. 12 to 14 instead of the transmission line group TLG. That is, in an embodiment, the display device DD may further include the second transmission lines TL2 (see FIGS. 12 to 14) connected to the first electrode layer E1 “. In other words, the first electrode layer E1” (i.e., the second electrode lines EL2) may receive the first power supply voltage ELVDD through the first transmission lines TL1 and TL2.

FIG. 20A is a cross-sectional view showing an example taken along line VI-VI′ of FIG. 19.

For convenience of explanation, FIG. 20A primarily shows the first transmission lines TL1 and the first electrode layer E1 “, with some of the components shown in FIGS. 3 to 5 omitted.

Referring to FIG. 20A, in an embodiment in which the display device DD includes the first electrode layer E1”, the first transmission lines TL1 may be disposed in the same layer as the first contact electrode SE1 (see FIG. 5) and the second contact electrode DE1 (see FIG. 5). For example, the first transmission lines TL1 may be disposed on the fourth insulating layer IL4 and at least partially covered by the fifth insulating layer IL5. In this case, the fourth contact hole CNT4 may extend through the fifth insulating layer IL5 and the sixth insulating layer IL6 to the first transmission lines TL1, and the first electrode layer E1″ (i.e., the second electrode lines EL2) may be electrically connected to the first transmission lines TL1 through the fourth contact hole CNT4.

FIG. 20B is a cross-sectional view showing an example taken along line VI-VI′ of FIG. 19.

For convenience of explanation, FIG. 20B primarily shows the first transmission lines TL1 and the first electrode layer E1 “, with some of the components shown in FIGS. 3 to 5 omitted.

Referring to FIG. 20B, in an embodiment in which the display device DD includes the first electrode layer E1”, the first transmission lines TL1 may be disposed in the same layer as the first to third connection electrodes CEa, CEb, and CEc (see FIGS. 3 to 5). For example, the first transmission lines TL1 may be disposed on the fifth insulating layer IL5 and at least partially covered by the sixth insulating layer IL6. In this case, the fourth contact hole CNT4 may extend through the sixth insulating layer IL6 to the first transmission lines TL1, and the first electrode layer E1″ (i.e., the second electrode lines EL2) may be electrically connected to the first transmission lines TL1 through the fourth contact hole CNT4.

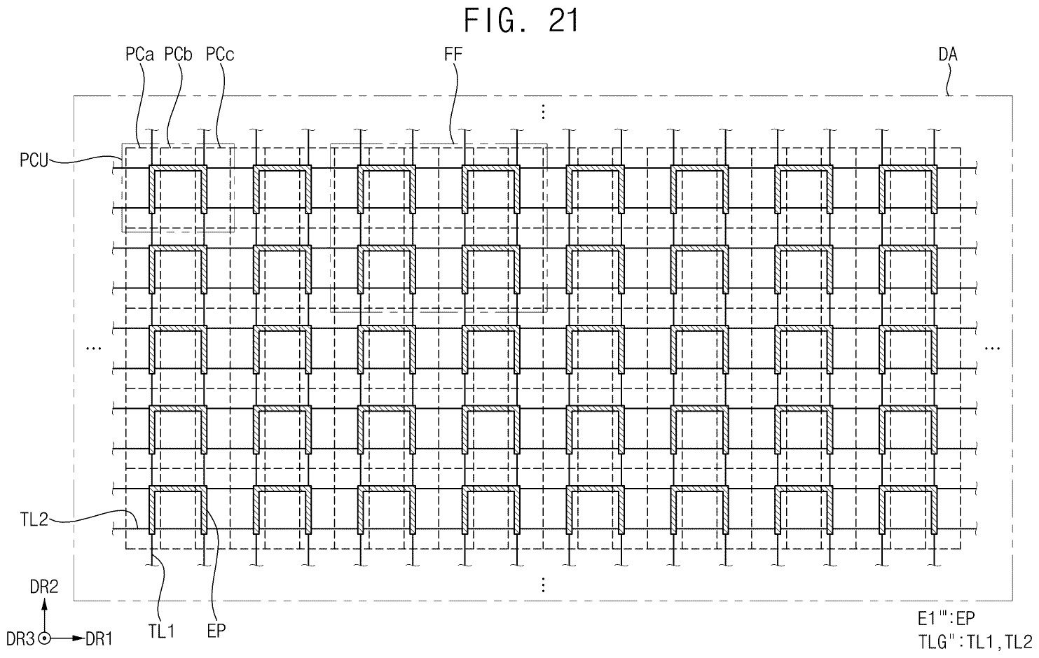

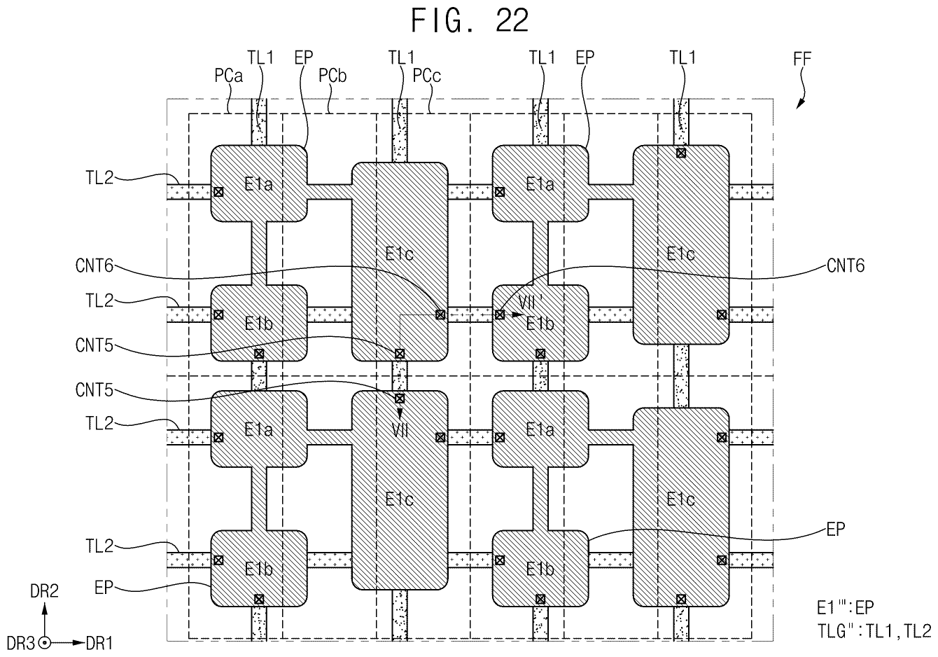

FIG. 21 is a plan view schematically showing a sixth embodiment of the arrangement of a first electrode layer and a transmission line group disposed in a display area of FIGS. 1A and 1B. FIG. 22 is an enlarged view showing area FF of FIG. 21.

The embodiment of the display device DD described with reference to FIGS. 21 and 22 may be substantially the same as the display device DD described with reference to FIGS. 12 and 13 except for a first electrode layer E1″. In addition, the first electrode layer E1′″ may be substantially the same as the first electrode layer E1 described above except that the first electrodes E1a, E1b, and E1c are not integrally connected in a mesh pattern and include electrode patterns EP physically separated from each other. Therefore, redundant descriptions are omitted or abbreviated.

Referring to FIGS. 21 and 22, the display device DD may include the first electrode layer E1” and the transmission line group TLG″. For the transmission line group TLG″ shown in FIGS. 18 and 19, the description of the transmission line group TLG″ with reference to FIGS. 12 and 13 may be applied except that the interval at which the transmission lines repeat is changed so that there are two first transmission lines TL1 and two second transmission lines TL2 for each unit circuit area PCU. Therefore, redundant descriptions are omitted or abbreviated.

In an embodiment, the first electrode layer E1′″ may include the electrode patterns EP. Each of the electrode patterns EP may have a structure in which the first electrodes E1a, E1b, and E1c corresponding to one of the unit circuit areas PCU are integrally connected. The electrode patterns EP may be arranged in one direction and in another direction crossing the one direction. For example, the electrode patterns EP may be arranged in the first direction DR1 and the second direction DR2. That is, the electrode patterns EP may be arranged in a matrix form. In addition, the electrode patterns EP may be physically separated from each other.

The electrode patterns EP may be electrically connected to each other through the transmission line group TLG. That is, the electrode patterns EP may be electrically connected to each other through the first transmission lines TL1 and the second transmission lines TL2. The first transmission lines TL1 may be electrically connected to the electrode patterns EP through a fifth contact hole CNT5. The second transmission lines TL2 may be electrically connected to the electrode patterns EP through a sixth contact hole CNT6. Accordingly, the electrode patterns EP may be electrically connected to each other and may receive the first power supply voltage ELVDD through the first and second transmission lines TL1 and TL2. That is, the first electrode layer E1″ may receive the first power supply voltage ELVDD through the first and second transmission lines TL1 and TL2. For example, the first electrode layer E1′″ (i.e., the electrode patterns EP) may receive the first power supply voltage ELVDD directly from the first voltage line VL1, and may additionally receive the first power supply voltage ELVDD through the first and second transmission lines TL1 and TL2.

As described above, the first transmission lines TL1 may extend in the second direction DR2 and be arranged in the first direction DR1. In addition, the second transmission lines TL2 may extend in the first direction DR1 and be arranged in the second direction DR2. Accordingly, the first transmission lines TL1, the second transmission lines TL2, and the electrode patterns EP may form a mesh structure in plan view. That is, even if the first electrode layer E1” itself does not have a mesh pattern and has another structure including the electrode patterns EP, the first electrode layer E1″ may form a mesh structure together with the first transmission lines TL1 and the second transmission lines TL2. Accordingly, mesh characteristics of the transmission path of the first power supply voltage ELVDD may be implemented. Accordingly, the difficulty in designing the first electrode layer E1′″ is lowered, and the voltage drop of the first power supply voltage ELVDD may be reduced.

FIG. 23A is a cross-sectional view showing an example taken along line VII-VII′ of FIG. 22.

For convenience of explanation, FIG. 23A primarily shows the first transmission lines TL1, the second transmission lines TL2, and the first electrode layer E1”′, with some of the components shown in FIGS. 3 to 5 omitted.

Referring to FIG. 23A, in an embodiment in which the display device DD includes the first electrode layer E1″ and the transmission line group TLG″, the second transmission lines TL2 may be disposed on the first transmission lines TL1. In an embodiment, the first transmission lines TL1 may be disposed in the same layer as the first contact electrode SE1 (see FIG. 5) and the second contact electrode DE1 (see FIG. 5), and the second transmission lines TL2 may be disposed in the same layer as the first to third connection electrodes CEa, CEb, and CEc (see FIGS. 3 to 5). For example, the first transmission lines TL1 may be disposed on the fourth insulating layer IL4 and at least partially covered by the fifth insulating layer IL5. In addition, the second transmission lines TL2 may be disposed on the fifth insulating layer IL5 and at least partially covered by the sixth insulating layer IL6. In this case, the fifth contact hole CNT5 may extend through the fifth insulating layer IL5 and the sixth insulating layer IL6 to the first transmission lines TL1, and the first electrode layer E1′″ (i.e., the electrode patterns EP) may be electrically connected to the first transmission lines TL1 through the fifth contact hole CNT5. In addition, the sixth contact hole CNT6 may extend through the sixth insulating layer IL6 to the second transmission lines TL2, and the first electrode layer E1”′ (i.e., the electrode patterns EP) may be electrically connected to the second transmission lines TL2 through the sixth contact hole CNT6.

FIG. 23B is a cross-sectional view showing an example taken along line VII-VII′ of FIG. 22.

For convenience of explanation, FIG. 23B primarily shows the first transmission lines TL1, the second transmission lines TL2, and the first electrode layer E1′″, with some of the components shown in FIGS. 3 to 5 omitted.

Referring to FIG. 23B, in an embodiment in which the display device DD includes the first electrode layer E1” and the transmission line group TLG″, the first transmission lines TL1 may be disposed on the second transmission lines TL2. In an embodiment, the first transmission lines TL1 may be disposed in the same layer as the first to third connection electrodes CEa, CEb, and CEc (see FIGS. 3 to 5), and the second transmission lines TL2 may be disposed in the same layer as the first contact electrode SE1 (see FIG. 5) and the second contact electrode DE1 (see FIG. 5). For example, the first transmission lines TL1 may be disposed on the fifth insulating layer IL5 and at least partially covered by the sixth insulating layer IL6. In addition, the second transmission lines TL2 may be disposed on the fourth insulating layer IL4 and at least partially covered by the fifth insulating layer IL5. In this case, the fifth contact hole CNT5 may extend through the sixth insulating layer IL6 to the first transmission lines TL1, and the first electrode layer E1′″ (i.e., the electrode patterns EP) may be electrically connected to the first transmission lines TL1 through the fifth contact hole CNT5. In addition, the sixth contact hole CNT6 may extend through the fifth insulating layer IL5 and IL6 to expose the second transmission lines TL2, and the first electrode layer E1”′ (i.e., the electrode patterns EP) may be electrically connected to the second transmission lines TL2 through the sixth contact hole CNT6.

FIG. 24 is a plan view schematically showing a seventh embodiment of the arrangement of a first electrode layer and a transmission line group disposed in a display area of FIGS. 1A and 1B. FIG. 25 is an enlarged view showing area GG of FIG. 24.

The embodiment of the display device DD described with reference to FIGS. 24 and 25 may be substantially the same as the display device DD described with reference to FIGS. 12 and 13, except for a first electrode layer E1 ′″. In addition, the first electrode layer E1 ′″ may be substantially the same as the first electrode layer E1 described above except that the first electrodes E1a, E1b, and E1c are not integrally connected in a mesh pattern and include the first electrodes E1a, E1b, and E1c physically separated from each other. Therefore, any redundant descriptions are omitted or abbreviated.

Referring to FIGS. 24 and 25, the display device DD may include the first electrode layer E1 ′″ and the transmission line group TLG″. For the transmission line group TLG″ shown in FIGS. 18 and 19, the description of the transmission line group TLG″ with reference to FIGS. 12 and 13 may be applied except that the interval at which the transmission lines repeat is changed so that there are two first transmission lines TL1 and two second transmission lines TL2 for each unit circuit area PCU. Therefore, redundant descriptions are omitted or abbreviated.

In an embodiment, all of the first electrodes E1a, E1b, and E1c included in the first electrode layer E1′″ may be physically separated from each other. In addition, all of the first electrodes E1a, E1b, and E1c included in the first electrode layer E1′″ may be electrically connected to each other through the transmission line group TLG″. That is, all of the first electrodes E1a, E1b, and E1c may be electrically connected to each other through the first transmission lines TL1 and the second transmission lines TL2. The first transmission lines TL1 may be electrically connected to the first electrodes E1a, E1b, and E1c through a seventh contact hole CNT7. The second transmission lines TL2 may be electrically connected to the first electrodes E1a, E1b, and E1c through an eighth contact hole CNT8. Accordingly, all of the first electrodes E1a, E1b, and E1c may be electrically connected to each other, and may receive the first power supply voltage ELVDD through the first and second transmission lines TL1 and TL2. That is, the first electrode layer E1′″ may receive the first power voltage ELVDD through the first and second transmission lines TL1 and TL2. For example, the first electrode layer E1′″ (i.e., the first electrodes E1a, E1b, and E1c) may receive the first power supply voltage ELVDD directly from the first voltage line VL1, and may additionally receive the first power supply voltage ELVDD through the first transmission lines TL1 and the second transmission lines TL2.

As described above, the first transmission lines TL1 may extend in the second direction DR2 and be arranged in the first direction DR1. In addition, the second transmission lines TL2 may extend in the first direction DR1 and be arranged in the second direction DR2. Accordingly, the first transmission lines TL1, the second transmission lines TL2, and the first electrodes E1a, E1b, and E1c may form a mesh structure in plan view. That is, even if the first electrode layer E1′″ itself does not have a mesh pattern and has another structure including first electrodes E1a, E1b, and E1c physically separated from each other, the first electrode layer E1″ may form a mesh structure together with the first transmission lines TL1 and the second transmission lines TL2. Accordingly, mesh characteristics of the transmission path of the first power supply voltage ELVDD may be implemented. Accordingly, while lowering the difficulty in designing the first electrode layer E1′″, the voltage drop of the first power supply voltage ELVDD may be reduced.

FIG. 26A is a cross-sectional view showing an example taken along line VIII-VIII′ of FIG. 25.

For convenience of explanation, FIG. 26A primarily shows the first transmission lines TL1, the second transmission lines TL2, and the first electrode layer E1′″, with some of the components shown in FIGS. 3 to 5 omitted.

Referring to FIG. 26A, in an embodiment in which the display device DD includes the first electrode layer E1′″ and the transmission line group TLG″, the second transmission lines TL2 may be disposed on the first transmission lines TL1. In an embodiment, the first transmission lines TL1 may be disposed in the same layer as the first contact electrode SE1 (see FIG. 5) and the second contact electrode DE1 (see FIG. 5), and the second transmission line TL2 may be disposed in the same layer as the first to third connection electrodes CEa, CEb, and CEc (see FIGS. 3 to 5). For example, the first transmission lines TL1 may be disposed on the fourth insulating layer IL4 and at least partially covered by the fifth insulating layer IL5. In addition, the second transmission lines TL2 may be disposed on the fifth insulating layer IL5 and at least partially covered by the sixth insulating layer IL6. In this case, the seventh contact hole CNT7 may extend through the fifth insulating layer IL5 and the sixth insulating layer IL6 to the first transmission lines TL1, and the first electrode layer E1′″ (i.e., the first electrodes E1a, E1b, and E1c) may be electrically connected to the first transmission lines TL1 through the seventh contact hole CNT7. In addition, the eighth contact hole CNT8 may extend through the sixth insulating layer IL6 to the second transmission lines TL2, and the first electrode layer E1′″ (i.e., the first electrode E1a, E1b, and E1c) may be electrically connected to the second transmission lines TL2 through the eighth contact hole CNT8.

FIG. 26B is a cross-sectional view showing an example taken along line VIII-VIII′ of FIG. 25.

For convenience of explanation, FIG. 26B primarily shows the first transmission lines TL1, the second transmission lines TL2, and the first electrode layer E1′″, with some of the components shown in FIGS. 3 to 5 omitted.

Referring to FIG. 26B, in an embodiment in which the display device DD includes the first electrode layer E1′″ and the transmission line group TLG″, the first transmission line TL1 may be disposed on the second transmission lines TL2. In an embodiment, the first transmission lines TL1 may be disposed in the same layer as the first to third connection electrodes CEa, CEb, and CEc (see FIGS. 3 to 5), and the second transmission line TL2 may be disposed in the same layer as the first contact electrode SE1 (see FIG. 5) and the second contact electrode DE1 (see FIG. 5). For example, the first transmission lines TL1 may be disposed on the fifth insulating layer IL5 and at least partially covered by the sixth insulating layer IL6. In addition, the second transmission lines TL2 may be disposed on the fourth insulating layer IL4 and at least partially covered by the fifth insulating layer IL5. In this case, the seventh contact hole CNT7 may extend through the sixth insulating layer IL6 to the first transmission lines TL1, and the first electrode layer E1′″ (i.e., the first electrodes E1a, E1b, and E1c) may be electrically connected to the first transmission lines TL1 through the seventh contact hole CNT7. In addition, the eighth contact hole CNT8 may extend through the fifth and sixth insulating layers IL5 and IL6 to the second transmission lines TL2, and the first electrode layer E1′″ (i.e., the first electrodes E1a, E1b, and E1c) may be electrically connected to the second transmission lines TL2 through the eighth contact hole CNT8.

According to embodiments of the present disclosure, the display device DD may include a first electrode layer forming a light-emitting element and which receives the first power supply voltage ELVDD, and transmission lines disposed in a layer different from the first electrode layer and which receives the first power supply voltage ELVDD. Accordingly, the transmission lines may provide the first power supply voltage ELVDD to the first electrode layer, and the first electrode layer and the transmission lines may form a mesh structure in plan view. For example, if the first electrode layer itself has a mesh pattern, the mesh characteristics of the transmission path of the first power supply voltage ELVDD may be further strengthened by the mesh structure formed by the first electrode layer and the transmission lines. In addition, even if the first electrode layer itself does not have a mesh pattern, the mesh characteristics of the transmission path of the first power supply voltage ELVDD may be implemented by the mesh structure formed by the first electrode layer and the transmission lines. Accordingly, the voltage drop of the first power supply voltage ELVDD may be reduced, power consumption of the display device DD may be lowered, and luminance uniformity may be improved.

Furthermore, the display quality of the display device DD may be improved.

FIG. 27 is a plan view schematically showing an example of a partial area of the display device of FIGS. 1A and 1B. FIG. 28 is an enlarged view of one unit light-emitting areas among unit light-emitting areas of FIG. 27. FIG. 29 is a cross-sectional view taken along line IX-IX′ of FIG. 28.

FIG. 27 depicts an area including four unit light-emitting areas UEA1 and UEA2 arranged in a matrix of 2 rows and 2 columns. FIG. 28 depicts one first unit light-emitting areas UEA1 of the unit light-emitting areas UEA1 and UEA2. For convenience of explanation, some of the components shown in FIG. 29 are omitted or emphasized in FIGS. 27 and 28. In addition, in FIG. 27, second electrodes E2a′, E2b′, and E2c′ of the components shown in FIG. 28 are omitted.

The embodiment of the display device DD described with reference to FIGS. 27 to 29 may be substantially the same as the embodiment of the display device DD described with reference to FIGS. 3 to 5, except for the first to third light emitting elements LEDa′, LEDb′, and LEDc′, first to third connection electrodes CEa′, CEb′, and CEc′, and a separator SPR′. Hereinafter, the description will focus on differences from the embodiment of the display device DD described with reference to FIGS. 3 to 5, and any redundant descriptions will be omitted or abbreviated.

Referring to FISGS. 27 to 29, the display device DD may include the first to third pixel driving circuit parts PCa, PCb, and PCc, the first to third light-emitting elements LEDa′, LEDb′, and LEDc′, the first to third connection electrodes CEa′, CEb′, and CEc′, and the separator SPR′.

The description of the first to third pixel driving circuit parts PCa, PCb, and PCc of FIGS. 3 to 5 may be applied to the first to third pixel driving circuit parts PCa, PCb, and PCc of FIGS. 27 and 28. Therefore, overlapping descriptions are omitted.

In addition, the description of the first to third light-emitting elements LEDa′, LEDb′, and LEDc′ with reference to FIGS. 3 to 5 may be applied to the first to third light-emitting elements LEDa′, LEDb′, and LEDc′ of FIGS. 27 to 29, except for an intermediate layer ML′ and a second electrode layer E2′. Therefore, overlapping descriptions are omitted.

In particular, the description of the first electrode layers E1, E1′, E1″, E1″′, and E1′″ described above may be applied to the first electrode layer E1 of FIG. 29. That is, various embodiments of the first electrode layer described above may be applied to the first electrode layer E1 of FIG. 29. Therefore, overlapping descriptions are omitted.

Each of the first to third light-emitting elements LEDa′, LEDb′, and LEDc′ may correspond to the light-emitting element LED described with reference to FIGS. 2A to 2C. For example, each of the first to third light-emitting elements LEDa′, LEDb′, and LEDc′ may be include a first electrode layer (e.g., the first electrode layer E1 of FIG. 29), an intermediate layer (e.g., the intermediate layer ML′ of FIG. 29) disposed on the first electrode layer, and a second electrode layer E2′ disposed on the intermediate layer. In an embodiment, the first electrode layer may function as the anode of FIGS. 2A to 2C, and the second electrode layer E2′ may function as the cathode of FIGS. 2A to 2C.

In an embodiment, the second electrode layer E2′ may be separated (or disconnected) into second electrodes E2a′, E2b′, and E2c′ by the separator SPR′. Specifically, the second electrode layer E2′ may be separated (or disconnected) into the second electrode E2a′ of the first light-emitting element LEDa′, the second electrode E2b′ of the second light-emitting element LEDb′, and the second electrode E2c′ of the third light-emitting element LEDc′, and the second electrodes E2a′, E2b′, and E2c′ may be electrically independent from each other. This will be described in more detail later.

The first light-emitting element LEDa′ may include the first electrode E1a (see FIG. 7) functioning as the anode and the second electrode E2a′ functioning as the cathode, the second light-emitting element LEDb′ may include the first electrode E1b (see FIG. 7) functioning as the anode and the second electrode E2b′ functioning as the cathode, and the third light-emitting element LEDc′ may include the first electrode E1c (see FIG. 7) functioning as the anode and the second electrode E2c′ functioning as the cathode.

As described above, the display device DD may include the first to third connection electrodes CEa′, CEb′, and CEc′. The first connection electrode CEa′ may connect the first light-emitting element LEDa′ and the first pixel driving circuit part PCa, the second connection electrode CEb′ may connect the second light-emitting element LEDb′ and the second pixel driving circuit part PCb, and the third connection electrode CEc′ may connect the third light-emitting element LEDc′ and the third pixel driving circuit part PCc.

The first to third connection electrodes CEa′, CEb′, and CEc′ may include a conductive material such as metal, alloy, conductive metal nitride, transparent conductive oxide, and the like. Examples of the conductive material that can be used for the first to third connection electrodes CEa′, CEb′, and CEc′ may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloys containing aluminum (Al), alloys containing silver (Ag), alloys containing copper (Cu), alloys containing molybdenum (Mo), aluminum nitride (AlN), tungsten nitride (WN), titanium nitride (TiN), chromium nitride (CrN), tantalum nitride (TaN), tin oxide (SnO), gallium oxide (GaO), indium gallium zinc oxide (IGZO), indium tin zinc oxide (ITZO), indium tin oxide (ITO), indium zinc oxide (IZO), indium gallium oxide (IGO), zinc oxide (ZnO), indium oxide (InO), aluminum zinc oxide (AZO), and the like. These can be used alone or in combination with each other. In an embodiment, the first to third connection electrodes CEa′, CEb′, and CEc′ may have a single-layer structure or a multi-layer structure in which a plurality of conductive layers are stacked. This will be described in more detail below with reference to FIG. 29.

The first connection electrode CEa′ may include a first circuit connection portion CPa′ and a first light-emitting connection portion CNa′.

The first circuit connection portion CPa′ may be a portion of the first connection electrode CEa′ connected to the first pixel driving circuit part PCa. Specifically, the first circuit connection part CPa′ may be a portion of the first connection electrode CEa′ connected to the first transistor TR1 (see FIG. 8) of the first pixel driving circuit part PCa. Accordingly, the position of the first circuit connection portion CPa′ may correspond to the position of the first transistor TR1 of the first pixel driving circuit part PCa. Specifically, the position of the first circuit connection portion CPa′ may be correspond to the position of a contact hole that extends to the first transistor TR1 of the first pixel driving circuit part PCa and extends through the fifth insulating layer IL5 (see FIG. 29).

The first light-emitting connection portion CNa may be a portion of the first connection electrode CEa′ connected to the second electrode E2a′ of the first light-emitting element LEDa′. Specifically, the first light-emitting connection portion CNa′ may be a portion of the first connection electrode CEa′ in an opening in the sixth insulating layer IL6 (see FIG. 29) and in an opening in the pixel defining layer PDL (see FIG. 29) to contact the second electrode E2a′. Accordingly, the position of the first light-emitting connection portion CNa may correspond to the position of an opening that exposes the first connection electrode CEa and extends through the pixel defining layer PDL and the sixth insulating layer IL6.

The second electrode E2a′ of the first light-emitting element LEDa′ may be connected to the first connection electrode CEa′. For example, the second electrode E2a′ of the first light-emitting element LEDa′ may contact the first connection electrode CEa′. As a result, the second electrode E2a′ of the first light-emitting element LEDa′ may be connected to the first pixel driving circuit part PCa through the first connection electrode CEa “.

In an embodiment, the first light-emitting connection portion CNa′ may be disposed at a position which does not overlap the first light-emitting area EAa. For example, in plan view, the first light-emitting connection portion CNa may be disposed between the first light-emitting area EAa and the separator SPR′. For example, the second electrode E2a′ of the first light-emitting element LEDa′ may have a protruding portion protruding from the first light-emitting area EAa to a position which does not overlap the first light-emitting area EAa in plan view, and the second electrode E2a′ and the first connection electrode CEa′ of the first light-emitting element LEDa′ may contact each other at a position that does not overlap the first light-emitting area EAa. Therefore, without reducing the light-emitting area of the first light-emitting area EAa, the second electrode E2a′ of the first light-emitting element LEDa′ and the first pixel driving circuit part PCa may be connected to through the first connection electrode CEa′.

The second connection electrode CEb′ may include a second circuit connection portion CPb′ and a second light-emitting connection portion CNb.

The second circuit connection portion CPb′ may be a portion of the second connection electrode CEb′ connected to the second pixel driving circuit part PCb. Specifically, the second circuit connection portion CPb′ may be a portion of the second connection electrode CEb′ connected to the first transistor TR1 (see FIG. 29) of the second pixel driving circuit part PCb. Accordingly, the position of the second circuit connection portion CPb′ may correspond to the position of the first transistor TR1 of the second pixel driving circuit part PCb. Specifically, the position of the second circuit connection portion CPb′ may correspond to the position of a contact hole that extends to the first transistor TR1 of the second pixel driving circuit part PCb through the fifth insulating layer IL5 (see FIG. 29).

The second light-emitting connection portion CNb′ may be a portion of the second connection electrode CEb′ connected to the second electrode E2b′ of the second light-emitting element LEDb′. Specifically, the second light-emitting connection portion CNb′ may be a portion of the second connection electrode CEb′ that is in the openings of the sixth insulating layer IL6 (see FIG. 29) and the pixel defining layer PDL (see FIG. 29) and contacting the second electrode E2b′. Accordingly, the position of the second light-emitting connection portion CNb′ may correspond to the position of an opening that extends to the second connection electrode CEb′ through the pixel defining layer PDL and the sixth insulating layer IL6.

In an embodiment, the second connection electrode CEb′ may be spaced apart from the first connection electrode CEa′ int plan view. In other words, the first connection electrode CEa′ and the second connection electrode CEb′ may be distinct electrodes.

The second electrode E2b′ of the second light-emitting element LEDb′ may be connected to the second connection electrode CEb′. For example, the second electrode E2b′ of the second light-emitting element LEDb′ may contact the second connection electrode CEb. As a result, the second electrode E2b′ of the second light-emitting element LEDb′ may be connected to the second pixel driving circuit part PCb through the second connection electrode CEb′.

In an embodiment, the second light-emitting connection portion CNb′ may be disposed at a position that does not overlap the second light-emitting area EAb. For example, in plan view, the second light-emitting connection portion CNb′ may be disposed between the second light-emitting area EAb and the separator SPR′. For example, the second electrode E2b′ of the second light-emitting element LEDb′ may have a protruding portion protruding from the second light-emitting area EAb to a position which does not overlap the second light-emitting area EAb in plan view, and the second electrode E2b′ and the second connection electrode CEb′ of the second light-emitting element LEDb′ may contact each other at a position that does not overlap the second light-emitting area EAb. Therefore, without reducing the light-emitting area of the second light-emitting area EAb, the second electrode E2b′ of the second light-emitting element LEDb′ and the second pixel driving circuit part PCb may be connected to through the second connection electrode CEb″.

The third connection electrode CEc′ may include a third circuit connection portion CPc′ and a third light-emitting connection portion CNc.

The third circuit connection portion CPc′ may be a portion of the third connection electrode CEc′ connected to the third pixel driving circuit part PCc. Specifically, the third circuit connection portion CPc′ may be a portion of the third connection electrode CEc′ connected to the first transistor TR1 (see FIG. 29) of the third pixel driving circuit part PCc. Accordingly, the position of the third circuit connection portion CPc′ may correspond to the position of the first transistor TR1 of the third pixel driving circuit part PCc. Specifically, the position of the third circuit connection portion CPc′ may correspond to the position of a contact hole that extends to the first transistor TR1 of the third pixel driving circuit part PCc through the fifth insulating layer IL5 (see FIG. 29).

The third light-emitting connection portion CNc′ may be a portion of the third connection electrode CEc′ connected to the second electrode E2c′ of the third light-emitting element LEDc′. Specifically, the third light-emitting connection portion CNc′ may be a portion of the third connection electrode CEc′ that is in the openings of the sixth insulating layer IL6 (see FIG. 29) and the pixel defining layer PDL (see FIG. 29) and contacting the second electrode E2c′. Accordingly, the position of the third light-emitting connection portion CNc′ may correspond to the position of an opening that extends to the third connection electrode CEc′ through the pixel defining layer PDL and the sixth insulating layer IL6.

In an embodiment, the third connection electrode CEc′ may be spaced apart from the first connection electrode CEa′ and the second connection electrode CEb′ in plan view. In other words, the first connection electrode CEa′, the second connection electrode CEb′, and the third connection electrode CEc′ may be different electrodes.

The second electrode E2c′ of the third light-emitting element LEDc′ may be connected to the third connection electrode CEc′. For example, the second electrode E2c′ of the third light-emitting element LEDc′ may contact the third connection electrode CEc′. As a result, the second electrode E2c′ of the third light-emitting element LEDc′ may be connected to the third pixel driving circuit part PCc through the third connection electrode CEc′.

In an embodiment, the third light-emitting connection portion CNc′ may be disposed at a position which does not overlap the third light-emitting area EAc. For example, in plan view, the third light-emitting connection portion CNc′ may be disposed between the third light-emitting area EAc and the separator SPR′. For example, the second electrode E2c′ of the third light-emitting element LEDc′ may have a protruding portion protruding from the third light-emitting area EAc to a position which does not overlap the third light-emitting area EAc in plan view, and the second electrode E2c′ and the third connection electrode CEc′ of the third light-emitting element LEDc′ may contact each other at a position that does not overlap the third light-emitting area EAc. Therefore, without reducing the light-emitting area of the third light-emitting area EAc, the second electrode E2c′ of the third light-emitting element LEDc′ and the third pixel driving circuit part PCc may be connected to through the third connection electrode CEc′.

According to an embodiment of the present disclosure, the second electrodes E2a′, E2b′, and E2c′ may be connected to the connection electrodes CEa′, CEb′, and CEc′ at positions that do not overlap the first to third light-emitting areas EAa, EAb, and EAc, respectively. Accordingly, without reducing the light-emitting area, the second electrodes E2a′, E2b′, and E2c′ may be connected to the first to third connection electrodes CEa′, CEb, and CEc′.

In addition, according to an embodiment of the present disclosure, the second electrodes E2a, E2b, and E2c may be respectively connected to the first to third pixel driving circuit parts PCa, PCb, and PCc through the first to third connection electrodes CEa, CEb′, and CEc′. Accordingly, restrictions due to the position, shape, and size of the first to third light-emitting areas EAa, EAb, and EAc may be reduced in the design of the first to third pixel driving circuit parts PCa, PCb, and PCc. For example, even if at least some of the first to third circuit connections CPa′, CPb′, and CPc′ overlap the first to third light-emitting areas EAa, EAb, EAc, the second electrodes E2a′, E2b′, and E2c′ may be easily connected to the first to third pixel driving circuit parts PCa, PCb, and PCc through the first to third connection electrodes CEa′, CEb′, and CEc′. Therefore, the shape and arrangement of the first to third pixel driving circuit part PCa, PCb, and PCc may be designed independently from the position, shape, and size of the first to third light-emitting areas EAa, EAb, and EAc. Accordingly, the degree of freedom in designing the first to third pixel driving circuit unit parts PCa, PCb, and PCc may be higher.

As shown in FIG. 27, the shape or arrangement of each of corresponding the first to third connection electrodes CEa′, CEb′, and CEc′ and the arrangement relationship between the first to third connection electrodes CEa′, CEb′, and CEc′ may be the same for each first unit light-emitting area UEA1. In addition, the shape or arrangement of each of corresponding the first to third connection electrodes CEa′, CEb′, and CEc′ and the arrangement relationship between the first to third connection electrodes CEa′, CEb′, and CEc′ may be the same for each second unit light-emitting area UEA2.

As described above, the display device DD may include the separator SPR′.

The separator SPR′ may be disposed on the pixel defining layer PDL (see FIG. 29). In an embodiment, the separator SPR′ may include an organic insulating material. For example, the separator SPR′ may include a photosensitive resin (e.g., photoresist). However, the present disclosure is not necessarily limited thereto.

The second electrode layer E2′ may be separated (or disconnected) into the second electrodes E2a′, E2b′, and E2c′ by the separator SPR′. That is, the second electrode E2a′ of the first light-emitting element LEDa′, the second electrode E2b′ of the second light-emitting element LEDb′, and the second electrode E2c′ of the third light-emitting element LEDc′ may be electrically independent from each other by the separator SPR″.

The separator SPR′ may define first to third open areas OA1, OA2, and OA3 corresponding to the second electrodes E2a′, E2b′, and E2c′, respectively. For example, the separator SPR′ may have a mesh pattern surrounding the second electrodes E2a′, E2b′, and E2c′ in plan view. The second electrode E2a′ of the first light-emitting element LEDa′ may be disposed in the first open area OA1 of the separator SPR′, the second electrode E2b′ of the second light-emitting element LEDb′ may be disposed in the second open area OA2 of the separator SPR′, and the second electrode E2c′ of the third light-emitting element LEDc′ may be disposed in the third open area OA3 of the separator SPR′.

In an embodiment, the outline of the first open area OA1 may be substantially the same shape as the outline of the second electrode E2a′ of the first light-emitting element LEDa′ in plan view, the outline of the second open area OA2 may be substantially the same shape as the outline of the second electrode E2b′ of the second light-emitting element LEDb′ in plan view, and the outline of the third open area OA3 may be substantially the same shape as the outline of the second electrode E2c′ of the third light-emitting element LEDc′ in plan view.

Hereinafter, with reference to FIG. 29, the cross-sectional structure of the display device DD according to the embodiments of FIGS. 27 to 29 will be described in more detail, based on the first light-emitting area EAa. The following description regarding the cross-sectional structure of the display device DD may be applied to other light-emitting areas.

The following description will focus on differences from the cross-sectional structure of the display device DD according to the embodiment described with reference to FIG. 5, and redundant descriptions will be omitted or abbreviated.

In an embodiment, the display device DD may include the substrate SUB, the first lower conductive layer BML1, the second lower conductive layer BML2, the first transistor TR1, the second transistor TR2, the first capacitor CAP1, the second capacitor CAP2, the first connection electrode CEa′, the first to sixth insulating layers IL1, IL2, IL3, IL4, IL5, and IL6, the pixel defining layer PDL, the first light-emitting element LEDa′, the separator SPR′, the first dummy layer DP1, the second dummy layer DP2, and the encapsulation layer ENC.

The first connection electrode CEa′ may be disposed on the fifth insulating layer IL5. As described above, the first connection electrode CEa′ may be connected to the first transistor TR1. Specifically, the first connection electrode CEa′ may contact the first transistor TR1 through the contact hole CNT extending through the fifth insulating layer IL5. Accordingly, the position of the first circuit connection portion CPa′ may correspond to the position of the contact hole CNT.

The first connection electrode CEa′ may include a conductive material such as a metal, alloy, conductive metal oxide, conductive metal nitride, transparent conductive oxide, and the like. In an embodiment, the first connection electrode CEa′ may have a multilayer structure in which a plurality of conductive layers are stacked. For example, the first connection electrode CEa′ may include a first conductive layer CL1, a second conductive layer CL2, and a third conductive layer CL3 sequentially stacked.

In an embodiment, the first conductive layer CL1 may include metal and/or transparent conductive oxide. Examples of the metal that can be used as the first conductive layer CL1 may include titanium (Ti), molybdenum (Mo), and the like. Examples of the transparent conductive oxide that can be used as the first conductive layer CL1 may include indium tin oxide (ITO), indium zinc oxide (IZO), zinc oxide (ZnO), indium oxide (InO), indium gallium oxide (IGO), aluminum zinc oxide (AZO), and the like. The first conductive layer CL1 may have a relatively thin thickness compared to the second conductive layer CL2.

The second conductive layer CL2 may include a different material from the first conductive layer CL1. For example, the second conductive layer CL2 may include a different metal from the first conductive layer CL1. Examples of the metal that can be used as the second conductive layer CL2 may include aluminum (Al), copper (Cu), and the like. The second conductive layer CL2 may have a relatively thick thickness compared to the first conductive layer CL1.

The third conductive layer CL3 may include a different material from the second conductive layer CL2. For example, the third conductive layer CL3 may include a different metal and/or transparent conductive oxide than the second conductive layer CL2. Examples of the metal that can be used as the third conductive layer CL3 may include titanium (Ti), molybdenum (Mo), and the like. Examples of the transparent conductive oxide that can be used as the third conductive layer CL3 may include indium tin oxide (ITO), indium zinc oxide (IZO), zinc oxide (ZnO), indium oxide (InO), and indium gallium oxide (IGO), aluminum zinc oxide (AZO), and the like. The third conductive layer CL3 may have a relatively thin thickness compared to the second conductive layer CL2.

In an embodiment, the first conductive layer CL1 and the third conductive layer CL3 may include the same material. However, the present disclosure is not necessarily limited thereto.

A side surface CL1-S of the first conductive layer CL1 and a side surface CL3-S of the third conductive layer CL3 may extend beyond a side surface CL2-S of the second conductive layer CL2. Accordingly, the first connection electrode CEa′ may have a tip structure due to a portion of the third conductive layer CL3 protruding beyond the second conductive layer CL2. For example, based on the same etching process, when etching the second conductive layer CL2 using an etching material having a high etch rate for the second conductive layer CL2 compared to the first conductive layer CL1 and the third conductive layer CL3, the first connection electrode CEa′ may be formed to have the tip structure.

Meanwhile, in FIG. 29, the first connection electrode CEa′ is shown to have a three-layer structure in which first to third conductive layers CL1, CL2, and CL3 are stacked. However, the present disclosure is not limited to this structure, and the first connection electrode CEa′ may have a two-layer structure in which the second conductive layer CL2 and the third conductive layer CL3 are stacked. That is, the first conductive layer CL1 may be omitted.

The sixth insulating layer IL6 may partially cover the first connection electrode CEa′ and may be disposed on the fifth insulating layer IL5. That is, the sixth insulating layer IL6 may define a first sub-opening SO1′ exposing at least a portion of the first connection electrode CEa′. Specifically, the first sub-opening SO1′ may expose the tip structure of the first connection electrode CEa.

The pixel defining layer PDL may further define a second sub-opening SO2′ corresponding to the first sub-opening SO1′ of the sixth insulating layer IL6. The second sub-opening SO2′ may overlap the first sub-opening SO1′ in plan view, and the first sub-opening SO1′ and the second sub-opening SO2′ may be spatially connected to each other. That is, an opening OP′ formed by the first sub-opening SO1′ and the second sub-opening SO2′ may be defined, with at least a portion of the first connection electrode CEa′ at the base of the opening OP′. Specifically, the tip structure of the first connection electrode CEa′ may be positioned in the opening OP′.

The separator SPR′ may be disposed on the pixel defining layer PDL. The separator SPR′ may have a shape where a width of an upper portion is larger than a width of a lower portion. That is, the separator SPR′ connecting an upper surface of the separator SPR′ and a lower surface of the separator SPR′ may have a tapered cross-section with an inclined side surface. That is, a cross-section of at least a portion of the separator SPR′ may be trapezoidal.

FIG. 29 depicts the side surface of the separator SPR′ having a tapered cross section with an inclined side surface. However, the present disclosure is not necessarily limited to this structure, and the separator SPR′ may have a plurality of inclined side surfaces. For example, the separator SPR′ may have a double tapered structure.

The intermediate layer ML′ may be disposed on the first electrode layer E1, and the pixel defining layer PDL. A portion of the intermediate layer ML′ may be disposed within the pixel opening of the pixel defining layer PDL. In an embodiment, the intermediate layer ML may include a first functional layer including an organic material, a light-emitting layer disposed on the first functional layer and including a light-emitting material, and a second functional layer disposed on the light-emitting layer and including an organic material. For example, the first functional layer may include a hole injection layer, a hole transport layer, and the like and the second functional layer may include an electron transport layer, an electron injection layer, and the like.

The shadow area where it is difficult to deposit the intermediate layer ML′ may exist around the separator SPR′ having a tapered inclined surface. Accordingly, the intermediate layer ML′ in the shadow area and/or around the shadow area may have a structure separated by the separator SPR′. For example, the first and second functional layers included in the intermediate layer ML′ may have a structure separated by the separator SPR″.

The first dummy layer DP1 may be disposed on the separator SPR′. The first dummy layer DP1 may be formed by having a structure in which the intermediate layer ML′ is separated by the separator SPR′. That is, the first dummy layer DP1 may be formed in the same process as the intermediate layer ML′. In an embodiment, the first dummy layer DP1 may be omitted.

The intermediate layer ML′ may also be separated (or disconnected) by the tip structure of the first connection electrode CEa′. As the intermediate layer ML′ is separated (or cut off) by the tip structure of the first connection electrode CEa′, the intermediate layer ML′ may expose at least a portion of the side surface CL2-S of the second conductive layer CL2. Accordingly, the second electrode E2a′ of the first light-emitting element LEDa′ may be electrically connected to the second conductive layer CL2.

The second electrode layer E2′ (i.e., the second electrodes E2a′, E2b, and E2c′) may be disposed on the intermediate layer ML′. The second electrode layer E2′ (i.e., the second electrodes E2a′, E2b′, and E2c′) may include a conductive material such as a metal, alloy, conductive metal oxide, conductive metal nitride, transparent conductive oxide, and the like. In an embodiment, the second electrode layer E2′ (i.e., the second electrodes E2a′, E2b′, and E2c′) may have a single-layer structure. However, the present disclosure is not necessarily limited to this, and the second electrode layer E2′ (i.e., the second electrodes E2a′, E2b′, and E2c′) may have a multilayer structure in which a plurality of conductive layers are stacked. For example, the second electrode layer E2′ (i.e., the second electrodes E2a′, E2b′, and E2c′) may have a two-layer structure in which a first sub-electrode layer including a metal material and a second sub-electrode layer disposed on the first sub-electrode layer and including a transparent conductive oxide are stacked.

The shadow area where it is difficult to deposit the second electrode layer E2′ may exist around the separator SPR ‘having a tapered, inclined side surface. Accordingly, the second electrode layer E2’ in the shadow area and/or around the shadow area may have a structure that is disconnected by the separator SPR′. For example, as shown in FIG. 28, the second electrode layer E2′ may be disconnected into the second electrode E2a′ of the first light-emitting element LEDa′ disposed in the first open area OA1 of the separator SPR′, the second electrode E2b′ of the second light-emitting element LEDb′ disposed in the second open area OA2 of the separator SPR′, and the second electrode E2c′ of the third light-emitting element LEDc′ disposed in the third open area OA3 of the separator SPR′. That is, the second electrodes E2a′, E2b′, and E2c′ may be electrically independent from each other.

As shown in FIG. 29, the second electrode E2a′ of the first light-emitting element LEDa′ may be connected to the first connection electrode CEa′. For example, the second electrode E2a′ may contact the side surface CL2-S of the second conductive layer CL2. For example, when a deposition angle of the deposition process for forming the second electrode layer E2′ is set to be larger than a deposition angle for the deposition process for forming the intermediate layer ML′, The second electrode layer E2′ (specifically, the second electrode E2a) may cover the intermediate layer ML′ disconnected by the tip structure and may be formed to be connected to the side surface CL2-S of the second conductive layer CL2. As a result, the second electrode E2a′ may be connected to the first transistor TR1 through the first connection electrode CEa′.

Meanwhile, the second dummy layer DP2 may be disposed on the separator SPR″. Specifically, the second dummy layer DP2 may be disposed on the first dummy layer DP1. The second dummy layer DP2 may be formed by having a structure in which the second electrode layer E2′ is disconnected by the separator SPR′. That is, the second dummy layer DP2 may be formed in the same process as the second electrode layer E2′. In an embodiment, the second dummy layer DP2 may be omitted.

According to an embodiment of the present disclosure, the display device DD may include the connection electrodes CEa′, CEb′, and CEc′ having a tip structure and the separator SPR′. Accordingly, the second electrode layer E2′ (e.g., the cathode) disposed on the first electrode layer E1 (e.g., the anode) may be easily connected to the pixel driving circuit parts PCa, PCb, and PCc. Specifically, the second electrode layer E2′ disposed on the first electrode layer E1 may be connected to the drain of the driving transistor (e.g., the first transistor T1 of FIGS. 2A to 2C) of each of the pixel driving circuit parts PCa, PCb, and PCc through the connection electrodes CEa′, CEb′, and CEc′. Accordingly, the gate-source voltage (Vgs) of the driving transistor may not change even when a light-emitting element deteriorates. Accordingly, the amount of change in driving current due to deterioration of the light-emitting element may be reduced. Accordingly, the after-image defect of the display device DD depending on an increase in the time of use may be reduced, and the lifespan of the display device DD may be improved.

FIG. 30 is a block diagram showing an electronic device according to embodiments of the present disclosure.

Referring to FIG. 30, an electronic device 10 may include a display module 11, a processor 12, a memory 13, and a power module 14.

A display device according to embodiments (e.g., the display device DD (or DDa) of FIGS. 1 to 29) may be applied to various electronic devices 10. The electronic device 10 may include the display device described above, and may further include modules or devices with additional functions other than the display device.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes the application stored in the memory 13, an image data signal and/or an input control signal may be transmitted to the display module 11, and the display module 11 may process the received signal and output image information through a display screen.

The power module 14 may include a power supply module, such as a power adapter or a battery device, and a power supply conversion module which converts the power supplied by the power supply module to generate power supply required for the operation of the electronic device 10. Specifically, the power module 14 may supply a power supply (e.g., ELVSS and ELVDD of FIGS. 2A to 2C) to the display device.

At least one of each component of the electronic device 10 described above may be included in the display device according to the above-described embodiments. In addition, some of the individual modules functionally included in one module may be included in the display device, and other portions may be provided separately from the display device. For example, the display device may include the display module 11, and the processor 12, the memory 13, and the power module 14 may be provided in the form of other devices within the electronic device 10 other than the display device. In other words, the processor 12 may provide the image data signal and the input control signal to the display device to control the display device.

FIG. 31 is a schematic diagram showing an electronic device according to various embodiments.

Referring to FIG. 31, various electronic devices 10 to which display devices according to the embodiments (e.g., the display device DD (or DDa) of FIGS. 1 to 29) are applied may include not only image display electronic devices such as a smartphone 10_1a, a tablet PC 10_1b, a laptop 10_1c, a TV 10_1d, and a desktop monitor 10_1e, but also wearable electronic devices including display modules, such as smart glasses 10_2a, a head-mounted display 10_2b, and a smart watch 10_2c, automotive electronic devices 10_3 including display modules, such as a dashboard of a car, a center fascia, a Center Information Display (CID) disposed on a dashboard, and a room mirror display, or the like.

Although embodiments and implementations have been described herein, other embodiments and modifications will be apparent from this description. Accordingly, the disclosure is not limited to such embodiments, but rather to the broader scope of the appended claims and various obvious modifications and equivalent arrangements as would be apparent to a person of ordinary skill in the art.

The present disclosure can be applied to display devices and electronic devices including the same. For example, the present disclosure can be applied to high-resolution smartphones, mobile phones, smart pads, smartwatches, tablet PCs, vehicle navigation systems, televisions, computer monitors, laptops, and the like.

What is claimed is:

1. A display device comprising:
a pixel driving circuit part including a transistor;
a connection electrode located on the pixel driving circuit part and electrically connected to the transistor of the pixel driving circuit part;
a first electrode layer located on the connection electrode, the first electrode layer receiving a power supply voltage and including a plurality of first electrodes;
a transmission line group located in a different layer from the first electrode layer, electrically connected to the first electrode layer, and forming a mesh structure with the first electrode layer in plan view;
a separator located on the first electrode layer; and
a second electrode layer located on the first electrode layer and separated into a plurality of second electrodes by the separator.

2. The display device of claim 1, wherein the first electrode layer is connected to receive the power supply voltage through the transmission line group.

3. The display device of claim 1, wherein the first electrode layer has a mesh pattern in which the plurality of first electrodes that extend in different directions are integrally connected.

4. The display device of claim 3, wherein the transmission line group includes a plurality of transmission lines extending in one direction and arranged in a crossing direction that is non-parallel to the one direction.

5. The display device of claim 4, wherein the transistor includes:
an active pattern including a semiconductor material;
a gate electrode located on the active pattern; and
a contact electrode located on the gate electrode and contacting the active pattern, and
the plurality of transmission lines are located in a same layer as the contact electrode.

6. The display device of claim 4, wherein the plurality of transmission lines are located in a same layer as the connection electrode.

7. The display device of claim 3, wherein the transmission line group includes:
a plurality of first transmission lines extending in one direction and arranged in a crossing direction that is non-parallel to the one direction; and
a plurality of second transmission lines extending in the crossing direction and arranged in the one direction.

8. The display device of claim 7, wherein the transistor includes:
an active pattern including a semiconductor material;
a gate electrode located on the active pattern; and
a contact electrode located on the gate electrode and contacting the active pattern,
the plurality of first transmission lines are located in a same layer as the contact electrode, and
the plurality of second transmission lines are located in a same layer as the connection electrode.

9. The display device of claim 1, wherein the first electrode layer includes a plurality of electrode lines extending in one direction and arranged in a crossing direction that is non-parallel to the one direction,
the plurality of electrode lines are physically separated from each other, and
each of the plurality of electrode lines has a structure in which some of the plurality of first electrodes that extend in different directions are integrally connected.

10. The display device of claim 1, wherein the first electrode layer includes a plurality of electrode patterns arranged in one direction and a crossing direction crossing that is non-parallel to the one direction,
the plurality of electrode patterns are physically separated from each other, and
each of the plurality of electrode patterns haas a structure in which some of the plurality of first electrodes are integrally connected.

11. The display device of claim 10, wherein the transmission line group includes:
a plurality of first transmission lines extending in the one direction and arranged in the crossing direction; and
a plurality of second transmission lines extending in the crossing direction and arranged in the one direction.

12. The display device of claim 11, wherein the plurality of first transmission lines and the plurality of second transmission lines are connected to at least one of the plurality of electrode patterns, and
the plurality of first transmission lines, the plurality of second transmission lines, and the electrode patterns form the mesh structure.

13. The display device of claim 11, wherein the plurality of electrode patterns are electrically connected to each other through the plurality of first transmission lines and the plurality of second transmission lines.

14. The display device of claim 12, wherein the transistor includes:
an active pattern including a semiconductor material;
a gate electrode located on the active pattern; and
a contact electrode located on the gate electrode and contacting the active pattern,
the plurality of first transmission lines are located in a same layer as the contact electrode, and
the plurality of second transmission lines are located in a same layer as the connection electrode.

15. The display device of claim 1, wherein the plurality of first electrodes are arranged in one direction and a crossing direction that is non-parallel to the one direction, and the plurality of first electrodes are physically separated from each other.

16. The display device of claim 1, further comprising:
an intermediate layer located between the first electrode layer and the second electrode layer, and including a light-emitting material.

17. The display device of claim 1, wherein at least one of the plurality of second electrodes is electrically connected to the connection electrode, and is electrically connected to the transistor of the pixel driving circuit part through the connection electrode.

18. A display device comprising:
a pixel driving circuit part including a transistor;
a connection electrode located on the pixel driving circuit part and electrically connected to the transistor of the pixel driving circuit part;
a first electrode layer located on the connection electrode, the first electrode layer receiving a power supply voltage and including a plurality of first electrodes;
a transmission line group located in a different layer from the first electrode layer, electrically connected to the first electrode layer, and forming a mesh structure with the first electrode layer in plan view;
a pixel defining layer located on the first electrode layer and defining a light-emitting area;
a connection pattern electrically connected to the connection electrode and surrounding the light-emitting area in plan view;
a separator located on the pixel defining layer and the connection pattern, and covering at least a portion of the connection pattern; and
a second electrode layer located on the first electrode layer and separated into a plurality of second electrodes by the separator.

19. The display device of claim 18, wherein at least one of the plurality of second electrodes contacts the connection pattern at a position adjacent to or overlapping the separator, and is electrically connected to the transistor of the pixel driving circuit part through the connection electrode and the connection pattern.

20. An electronic device comprising:
a display device including:
a pixel driving circuit part including a transistor;
a connection electrode located on the pixel driving circuit part and electrically connected to the transistor of the pixel driving circuit part;
a first electrode layer located on the connection electrode, the first electrode layer receiving a power supply voltage and including a plurality of first electrodes;
a transmission line group located in a different layer from the first electrode layer, electrically connected to the first electrode layer, and forming a mesh structure with the first electrode layer in plan view;
a separator located on the first electrode layer, and
a second electrode layer located on the first electrode layer and separated into a plurality of second electrodes by the separator, and
a power module which supplies the power supply voltage to the display device.
